(19) United States
(12) Patent Application Publication
(10) Pub. No.: US 2012/0100487 A1
(43) Pub. Date: Apr. 26, 2012

(54) RESIST COMPOSITION, METHOD OF FORMING RESIST PATTERN, AND POLYMERIC COMPOUND

(75) Inventors: Tomoyuki Hirano, Kawasaki-shi (JP); Daichi Takaki, Kawasaki-shi (JP); Daiju Shiono, Kawasaki-shi (JP); Kenri Konno, Kawasaki-shi (JP); Kensuke Matsuzawa, Kawasaki-shi (JP); Jun Iwashita, Kawasaki-shi (JP)

(73) Assignee: Tokyo Ohka Kogyo Co., Ltd., Kawasaki-shi (JP)

(21) Appl. No.: 13/277,061

(22) Filed: Oct. 19, 2011

(30) Foreign Application Priority Data
Oct. 22, 2010 (JP) 2010-237537

(51) Int. Cl. G03F 7/20; C08F 228/02; C08F 228/06

(52) U.S. Cl. 430/325; 526/243

(57) ABSTRACT

A resist composition including a base component that generates acid upon exposure and also exhibits increased polarity by action of acid, the base component including a polymeric compound having a structural unit that generates acid upon exposure; a structural unit derived from an acrylate ester, in which a hydrogen atom bonded to a carbon atom on the α-position may be substituted with a substituent, and also includes an acid decomposable group that exhibits increased polarity by action of acid; and a structural unit represented by a particular general formula.

### BACKGROUND OF THE INVENTION

1. Field of the Invention

The present invention relates to a polymeric compound that generates acid upon exposure and also exhibits increased polarity by the action of acid, a resist composition that contains the polymeric compound; and a method of forming a resist pattern using the resist composition.

Priority is claimed on Japanese Patent Application No. 2010-237537, filed Oct. 22, 2010, the content of which is incorporated herein by reference.

2. Description of Related Art

In lithography techniques, a resist film composed of a resist material is formed on a substrate, and the resist film is subjected to selective exposure of radial rays such as light or electron beam, followed by development, thereby forming a resist pattern having a predetermined shape on the resist film.

A resist material in which the exposed portions become soluble in a developing solution is called a positive-type, and a resist material in which the exposed portions become insoluble in a developing solution is called a negative-type.

In recent years, advances in lithography techniques have led to rapid progress in the field of pattern miniaturization. Typically, these miniaturization techniques involve increasing the energy (shortening the wavelength) of the exposure light source. Conventionally, ultraviolet radiation typified by g-line and i-line radiation has been used, but nowadays KrF excimer lasers and ArF excimer lasers are now starting to be introduced in mass production. Furthermore, research is also being conducted into lithography techniques that use an exposure light source having higher energy than these excimer lasers, such as electron beam, extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources. As a resist material which satisfies these conditions, a chemically amplified resist composition containing an acid generator that generates acid upon exposure is used.

A chemically amplified resist composition typically contains an acid generator, and a base component for forming a film.

Examples of these acid generators usable in a resist composition are numerous, and include onium salt-based acid generators, oxime sulfonate-based acid generators, diazomethane-based acid generators, nitrobenzylsulfonate-based acid generators, iminosulfonate-based acid generators, and disulfone-based acid generators.

Further, as a base component, a base component that exhibits a changed solubility in a developing solution under the action of acid generated from the acid generator is typically used. For example, in the case of alkali developing processes where an alkali developing solution is used as a developing solution, as the base component, a base component that exhibits a changed solubility in an alkali developing solution by the action of acid is used. If the resist film formed using such a chemically amplified resist composition is selectively exposed, then within the exposed portions, acid is generated from the acid generator component, and the action of this acid causes an increase in the solubility of the base component in an alkali developing solution, making the exposed portions soluble in the alkali developing solution. Therefore, by developing using an alkali developing solution, the exposed portions are dissolved and removed whereas the unexposed portions remain as a pattern, and hence, a positive resist pattern can be formed.

The base component used for forming a positive resist pattern in the alkali developing processes typically includes an acid decomposable group that exhibits increased polarity by the action of acid. In the base component, polarity is increased by the action of acid, thereby increasing the solubility in an alkali developing solution. On the other hand, the solubility in an organic solvent is reduced. Accordingly, by taking advantage of this, a process (hereafter, sometimes referred to as a “solvent developing process” or “negative developing process”) using a developing solution containing an organic solvent (organic developing solution) instead of alkali developing solution has also been proposed. If the resist film formed using the aforementioned chemically amplified resist composition that includes a base component having an acid decomposable group is selectively exposed, then within the exposed portions, the solubility in an organic developing solution is relatively reduced. Therefore, by developing using an organic developing solution, the unexposed portions are dissolved and removed by the organic developing solution whereas the exposed portions remain as a pattern, and hence, a negative resist pattern can be formed. For example, a negative developing process has been proposed in Patent Document 1.

Currently, resins (base resins) are commonly used as a base component for chemically amplified resist compositions. For example, resins that contain structural units derived from (meth)acrylate esters within the main chain (acrylic resins) are typically used as base resins for chemically amplified resist compositions that use ArF excimer laser lithography, as they exhibit excellent transparency in the vicinity of 193 nm (for example, refer to Patent Document 2). Here, the term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position. The term “(meth)acrylic acid” is a generic term that includes either or both of acrylic acid having a hydrogen atom bonded to the α-position and methacrylic acid having a methyl group bonded to the α-position.

A chemically amplified resist composition containing a resin component having, within the structure thereof, an acid generating group that generates acid upon exposure and an acid decomposable group that exhibits increased polarity by the action of acid has also been proposed (for example, refer to Patent Documents 3 to 5).

These resin components are provided with both a function as an acid generator and a function as a base component, and may solely constitute a chemically amplified resist composition on its own. That is, when exposure of these resin components is conducted, acid is generated from the acid generating group within the structure, and the acid decomposable group is broken down by the action of this acid, thereby generating polar groups such as carboxyl groups to increase the polarity. Therefore, by conducting selective exposure of a resin film (resist film) formed by using the resin component, the polarity of the exposed portions is increased. Hence, by developing using an alkali developing solution, the exposed portions are dissolved and removed so that a positive resist pattern can be formed.

### DOCUMENTS OF RELATED ART

### Patent Documents

[Patent Document 1] Japanese Unexamined Patent Application, First Publication No. 2008-292975
[Patent Document 2] Japanese Unexamined Patent Application, First Publication No. 2003-241385
[Patent Document 3] Japanese Unexamined Patent Application, First Publication No. Hei 10-221852
[Patent Document 4] Japanese Unexamined Patent Application, First Publication No. 2006-045311
[Patent Document 5] Japanese Unexamined Patent Application, First Publication No. 2006-215526

### SUMMARY OF THE INVENTION

According to a resin component having, within the structure thereof, an acid generating group that generates acid upon exposure and an acid decomposable group that exhibits increased polarity by the action of acid as described above, it is said that the resolution improves compared to the cases where an acid generator and a base component are added as separate components. Possible reasons for the resolution improvement include the improvement in distribution uniformity of acid generating groups within the resist film by including the acid generating group in the resin component serving as a base component.

However, such resin components tend to exhibit low sensitivity during formation of a resist pattern, and the roughness of the formed resist pattern was also still unsatisfactory, although improvements have been made. The term “roughness” refers to “surface roughness within the resist pattern”, which causes unsatisfactory resist pattern shapes. For example, unevenness on the side wall of a pattern (line edge roughness (LER)) can cause various defects such as non-uniformity of the line width of line and space patterns, or distortions around the holes in hole patterns. Such defects may adversely affect formation of fine semiconductor devices and the like, and the improvements therefor become more important as the miniaturization of pattern progresses.

In the aforementioned Patent Document 3, in order to improve LER or the like, structural units containing a polar group-containing aliphatic polycyclic group, such as structural units derived from 3-hydroxyadamantyl (meth)acrylate, are further combined, in addition to structural units having a specific structure that includes an acid generating group and structural units containing an acid dissociable, dissolution inhibiting group.

The inventors of the present invention have conducted intensive and extensive studies on the mechanism of action for improving the resolution and LER through the introduction of a polar group-containing aliphatic polycyclic group. As a result, they have discovered that one of the causes therefor was an increase in the softening point of the formed resist film, thereby suppressing the diffusion of acid within the resist film following exposure.

However, the increase in the softening point of resist films through the introduction of polar group-containing aliphatic polycyclic group as described above usually involves sensitivity reduction. Accordingly, there is a demand for techniques that can achieve both increase in the softening point of resist films and high sensitivity.

The present invention takes the above circumstances into consideration, with an object of providing a resist composition and a method of forming a resist pattern that can achieve both increase in the softening point of resist films and high sensitivity, and a polymeric compound useful for the resist composition.

A first aspect of the present invention for solving the above problems is a resist composition including a base component (A) that generates acid upon exposure and also exhibits increased polarity by action of acid, the resist composition characterized in that the base component (A) includes a polymeric compound (A1) having a structural unit (a0) that generates acid upon exposure; a structural unit (a1) derived from an acrylate ester, in which a hydrogen atom bonded to the carbon atom on the α-position may be substituted with a substituent, and also includes an acid decomposable group that exhibits increased polarity by action of acid; and a structural unit (a3) represented by general formula (a3-0) shown below.

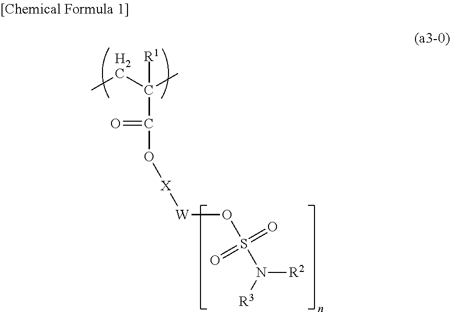

In the formula, R¹ represents a hydrogen atom, an alkyl group of 1 to 5 carbon atoms or a halogenated alkyl group of 1 to 5 carbon atoms; X represents a single bond or a divalent linking group; W represents a cyclic saturated hydrocarbon group that may include an oxygen atom at an arbitrary position; each of R² and R³ independently represents a hydrogen atom or an alkyl group that may include an oxygen atom at an arbitrary position, or R² and R³ may be mutually bonded to form a ring together with the nitrogen atom in the formula; and n represents an integer of 1 to 3.

A second aspect of the present invention is a method of forming a resist pattern, including: applying a resist composition of the first aspect to a substrate to form a resist film on the substrate; conducting exposure of the resist film; and developing the resist film to form a resist pattern.

A third aspect of the present invention is a polymeric compound including a structural unit (a0) that generates acid upon exposure; a structural unit (a1) derived from an acrylate ester, in which a hydrogen atom bonded to the carbon atom on the α-position may be substituted with a substituent, and also includes an acid decomposable group that exhibits increased polarity by action of acid; and a structural unit (a3) represented by general formula (a3-0) shown below.

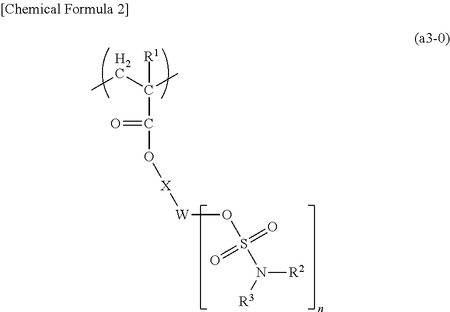

In the formula, R¹ represents a hydrogen atom, an alkyl group of 1 to 5 carbon atoms or a halogenated alkyl group of 1 to 5 carbon atoms; X represents a single bond or a divalent linking group; W represents a cyclic saturated hydrocarbon group that may include an oxygen atom at an arbitrary position; each of R² and R³ independently represents a hydrogen atom or an alkyl group that may include an oxygen atom at an arbitrary position, or R² and R³ may be mutually bonded to form a ring together with the nitrogen atom in the formula; and n represents an integer of 1 to 3.

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic divalent saturated hydrocarbon, unless otherwise specified.

A “halogenated alkyl group” is a group in which part or all of the hydrogen atoms of an alkyl group are substituted with a halogen atom, and a “halogenated alkylene group” is a group in which part or all of the hydrogen atoms of an alkylene group are substituted with a halogen atom. Examples of the halogen atom include a fluorine atom, a chlorine atom, a bromine atom and an iodine atom.

A “hydroxyalkyl group” is a group in which part or all of the hydrogen atoms within an alkyl group have been substituted with a hydroxyl group.

The term “structural unit” refers to a repeating unit (a monomer unit) that contributes to the formation of a polymeric compound (namely, a resin, polymer or copolymer).

The term “exposure” is used as a general concept that includes irradiation with any form of radiation, including an ArF excimer laser, KrF excimer laser, F₂ excimer laser, extreme ultraviolet rays (EUV), vacuum ultraviolet rays (VUV), electron beam (EB), X-rays or soft X-rays.

According to the present invention, there are provided a resist composition and a method of forming a resist pattern that can achieve both increase in the softening point of resist films and high sensitivity, and a polymeric compound useful for the resist composition.

### DETAILED DESCRIPTION OF THE INVENTION

### <<Resist Composition>>

The resist composition of the present invention includes a base component (A) (hereafter, referred to as “component (A)”) that generates acid upon exposure and also exhibits increased polarity by the action of acid.

If the resist film formed using a resist composition that includes the component (A) is selectively exposed, acid is generated from the component (A) within the exposed portions, and the action of this acid causes an increase in the polarity of the component (A), whereas the polarity of the component (A) remains unchanged in the unexposed portions. Accordingly, the difference in polarity is developed between the exposed portions and the unexposed portions. Therefore, by developing this resist film using an alkali developing solution, the exposed portions are dissolved and removed, and hence, a positive resist pattern can be formed. Alternatively, by developing this resist film using an organic developing solution that contains an organic solvent, the unexposed portions are dissolved and removed, and hence, a negative resist pattern can be formed.

In the present description, a resist composition for forming a positive resist pattern will be referred to as a positive resist composition, and a resist composition for forming a negative resist pattern will be referred to as a negative resist composition.

The resist composition of the present invention is a positive resist composition in the alkali-developing process that uses an alkali developing solution for developing during resist pattern formation, and a negative resist composition in the solvent developing process (also referred to as “negative developing process”) using a developing solution containing an organic solvent (organic developing solution) for the developing.

The resist composition of the present invention may be a resist composition for alkali-developing process (i.e., a positive resist composition), or may be a resist composition for solvent developing process (i.e., a negative resist composition).

### <Component (A)>

In the present invention, the term “base component” refers to an organic compound capable of forming a film.

As the base component of a resist composition, an organic compound having a molecular weight of 500 or more is typically used. When the organic compound has a molecular weight of 500 or more, the organic compound exhibits a satisfactory film-forming ability, and a resist pattern of nano level can be easily formed.

The “organic compound having a molecular weight of 500 or more” is broadly classified into non-polymers and polymers.

In general, as a non-polymer, any of those which have a molecular weight in the range of 500 to less than 4,000 is used. Hereafter, a “low molecular weight compound” refers to a non-polymer having a molecular weight in the range of 500 to less than 4,000.

As a polymer, any of those which have a molecular weight of 1,000 or more is generally used. In the present description and claims, the term “polymeric compound” or the term “resin” refers to a polymer having a molecular weight of 1,000 or more.

With respect to a polymeric compound, the “molecular weight” is the weight average molecular weight in terms of the polystyrene equivalent value determined by gel permeation chromatography (GPC).

The component (A) includes a polymeric compound (A1) (hereafter, referred to as “component (A1)”) having a structural unit (a0) that generates acid upon exposure; a structural unit (a1) derived from an acrylate ester, in which a hydrogen atom bonded to the carbon atom on the α-position may be substituted with a substituent, and also includes an acid decompsable group that exhibits increased polarity by the action of acid; and a structural unit (a3) represented by the above general formula (a3-0).

By virtue of the component (A1) including the structural unit (a0), the component (A1) may generate acid upon exposure. Further, by virtue of the component (A1) including the structural unit (a1), the component (A1) exhibits increased polarity by the action of acid (including the acid generated from the structural unit (a0)).

[Structural Unit (a0)]

The structural unit (a0) is a structural unit that generates acid upon exposure.

There are no particular limitations on the structural unit (a0), as long as it is a structural unit that generates acid upon exposure. For example, those in which an acid generator proposed for conventional chemically amplified resists has been introduced as a substituent to a structural unit that is known to be copolymerizable with other structural units such as the structural units (a1) and (a3) described later can be used.

Preferred examples of the structural units that are copolymerizable with the structural units (a1), (a3), and the like include structural units derived from acrylate esters in which a hydrogen atom bonded to the carbon atom on the α-position may be substituted with a substituent, and structural units derived from hydroxystyrene in which a hydrogen atom bonded to the carbon atom on the α-position may be substituted with a substituent.

Preferred examples of the acid generators proposed for conventional chemically amplified resists include the component (B) described later.

As the structural unit (a0), those having a group represented by general formula (I) or (II) shown below are preferred in view of acid strength, sensitivity, resolution, roughness, and the like.

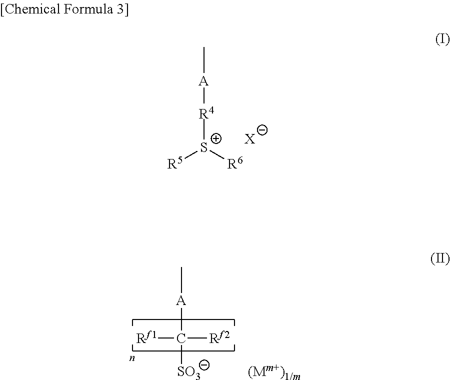

In the formulas, A represents a single bond or a divalent linking group; R⁴ represents an arylene group which may have a substituent; each of R⁵ and R⁶ independently represents an organic group, wherein R⁵ and R⁶ may be mutually bonded to form a ring together with the sulfur atom in the formula; X⁻ represents a counter anion; each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group; n represents an integer of 1 to 8; M^{m+} represents a counter cation; and m represents an integer of 1 to 3.

In formula (I), A represents a single bond or a divalent linking group.

Preferred examples of the divalent linking group for A include divalent hydrocarbon groups which may have a substituent, and divalent linking groups containing a hetero atom.

A hydrocarbon “has a substituent” means that part or all of the hydrogen atoms within the hydrocarbon group is substituted with a substituent (a group or an atom other than hydrogen).

The hydrocarbon group may be either an aliphatic hydrocarbon group or an aromatic hydrocarbon group.

An “aliphatic hydrocarbon group” refers to a hydrocarbon group that has no aromaticity.

The aliphatic hydrocarbon group as the divalent hydrocarbon group for A may be either saturated or unsaturated. In general, the aliphatic hydrocarbon group is preferably saturated.

Specific examples of the aliphatic hydrocarbon group include linear and branched aliphatic hydrocarbon groups, and aliphatic hydrocarbon groups containing a ring in the structure thereof.

The linear or branched aliphatic hydrocarbon group preferably has 1 to 10 carbon atoms, more preferably 1 to 8 carbon atoms, still more preferably 1 to 5 carbon atoms, and most preferably 1 or 2 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms, and an oxygen atom (═O).

Examples of the aliphatic hydrocarbon group containing a ring in the structure thereof include alicyclic hydrocarbon groups (groups in which two hydrogen atoms have been removed from an aliphatic hydrocarbon ring), groups in which this type of alicyclic hydrocarbon group is bonded to the terminal of a linear or branched aliphatic hydrocarbon group, or groups in which this type of alicyclic hydrocarbon group is interposed within the chain of a linear or branched aliphatic hydrocarbon group. Examples of the linear or branched aliphatic hydrocarbon group include the same aliphatic hydrocarbon groups as those described above.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic alicyclic hydrocarbon group, a group in which two hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which two hydrogen atoms have been removed from a polycycloalkane is preferable, and the polycycloalkane preferably has 7 to 12 carbon atoms. Specific examples of the polycycloalkane include adamantane, norbornane, isobornane, tricyclodecane and tetracyclododecane.

The alicyclic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

The aromatic hydrocarbon group is a hydrocarbon group having an aromatic ring.

The aromatic hydrocarbon group as the divalent hydrocarbon group for A preferably has 3 to 30 carbon atoms, more preferably 5 to 30 carbon atoms, still more preferably 5 to 20 carbon atoms, still more preferably 6 to 15 carbon atoms, and most preferably 6 to 10 carbon atoms. Here, the number of carbon atoms within a substituent(s) is not included in the number of carbon atoms of the aromatic hydrocarbon group.

Specific examples of the aromatic rings included in the aromatic hydrocarbon groups, include aromatic hydrocarbon rings such as benzene, biphenyl, fluorene, naphthalene, anthracene and phenanthrene; and aromatic heterocycles in which part of the carbon atoms constituting the aforementioned aromatic hydrocarbon ring has been substituted with a hetero atom. Examples of the hetero atoms within aromatic heterocycles include an oxygen atom, a sulfur atom and a nitrogen atom.

Specific examples of the aromatic hydrocarbon groups include groups in which two hydrogen atoms have been removed from the aforementioned aromatic hydrocarbon ring (arylene groups); and groups in which one of the hydrogen atoms of a group (i.e., an aryl) group in which one hydrogen atom has been removed from the aforementioned aromatic hydrocarbon ring has been substituted with an alkylene group (for example, groups in which one hydrogen atom has been further removed from the aryl group within an arylalkyl group, such as a benzyl group, a phenethyl group, a 1-naphthylmethyl group, a 2-naphthylmethyl group, a 1-naphthylethyl group or a 2-naphthylethyl group). The alkylene group (alkyl chain within the arylalkyl group) preferably has 1 to 4 carbon atoms, more preferably 1 or 2 carbon atoms, and most preferably 1 carbon atom.

The aromatic hydrocarbon group may or may not have a substituent. For example, a hydrogen atom bonded to the aromatic hydrocarbon ring within the aromatic hydrocarbon group may be substituted with a substituent. Examples of substituents include an alkyl group, an alkoxy group, a halogen atom, a halogenated alkyl group, a hydroxyl group and an oxygen atom (═O).

The alkyl group as the substituent is preferably an alkyl group of 1 to 5 carbon atoms, and a methyl group, an ethyl group, a propyl group, an n-butyl group or a tert-butyl group is particularly desirable.

The aforementioned alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Examples of the halogenated alkyl group as the substituent include groups in which part or all of the hydrogen atoms within the aforementioned alkyl groups has been substituted with the aforementioned halogen atoms.

With respect to a “divalent linking group containing a hetero atom”, a hetero atom is an atom other than carbon and hydrogen, and examples thereof include an oxygen atom, a nitrogen atom, a sulfur atom and a halogen atom.

Specific examples of the divalent linking group containing a hetero atom include non-hydrocarbon-based linking groups such as —O—, —C(═O)—, —C(═O)—O—, a carbonate bond (—O—C(═O)—O—)—S— —S(═O)₂—O—, —NH—, —NR⁰⁴— (R⁰⁴ represents a substituent such as an alkyl group of 1 to 5 carbon atoms or an acyl group), —NH—C(═O)— and ═N—; and a combination of at least one of these non-hydrocarbon groups with a divalent hydrocarbon group. As examples of the divalent hydrocarbon group, the same groups as those described above for the divalent hydrocarbon group which may have a substituent can be given, and a linear or branched aliphatic hydrocarbon group is preferable.

The divalent linking group for A may or may not have an acid decomposable portion in the structure thereof. The term “acid decomposable portion” refers to a portion having a bond which may be cleaved during the action of acid generated upon exposure (for example, acid generated from the structural unit (a0)). Examples of the acid decomposable portion include those having a carbonyloxy group and a tertiary carbon atom bonded to the oxygen atom (—O—) at the terminal thereof. In this acid decomposable portion, the action of acid causes cleavage of the bond between the oxygen atom and the tertiary carbon atom.

Of the various possibilities described above, as A, an alkylene group, an ester bond [—C(═O)—O—], an ether bond (—O—) or a combination of these, or a single bond is particularly desirable.

As the alkylene group, a linear or branched alkylene group is preferable, a linear alkylene group of 1 to 5 carbon atoms is more preferable, and a methylene group or an ethylene group is particularly desirable.

Preferred examples of the aforementioned combinations include -A¹¹-C(═O)—O-A¹²- and -A¹¹-C—O-A¹²-. In the formulas, A¹¹ represents an alkylene group, and A¹² represents a single bond or an alkylene group. As the alkylene group for A¹¹ and A¹², a linear or branched alkylene group is preferable, a linear alkylene group of 1 to 5 carbon atoms is more preferable, and a methylene group or an ethylene group is particularly desirable.

In formula (I), R⁴ represents an arylene group which may have a substituent.

The arylene group for R⁴ is not particularly limited and includes, for example, an arylene group having 6 to 20 carbon atoms. Examples of the arylene group include the same arylene groups as those described above in connection with A. Of these, because they can be synthesized at a low cost, arylene groups of 6 to 10 carbon atoms are preferable, a phenylene group or a naphthylene group is more preferable, and a phenylene group is particularly desirable.

The arylene group may have a substituent. The expression “have a substituent” means that part of or all of the hydrogen atoms within the arylene group is substituted with a substituent, and examples of the substituent include an alkyl group, an alkoxy group, a halogen atom and a hydroxyl group.

The alkyl group, with which hydrogen atoms of the arylene group may be substituted, is preferably an alkyl group having 1 to 5 carbon atoms, more preferably a methyl group, an ethyl group, a propyl group, an n-butyl group, or a tert-butyl group, and most preferably a methyl group.

The alkoxy group, with which hydrogen atoms of the arylene group may be substituted, is preferably an alkoxy group having 1 to 5 carbon atoms, more preferably a methoxy group, an ethoxy group, an n-propoxy group, an iso-propoxy group, an n-butoxy group or a tert-butoxy group.

Examples of the halogen atom, with which hydrogen atoms of the arylene group may be substituted, include a fluorine atom and a chlorine atom, and a fluorine atom is preferable.

When the arylene group has a substituent, the arylene group may have one substituent or several substituents.

In formula (I), each of R⁵ and R⁶ independently represents an organic group.

The organic group for R⁵ and R⁶ refers to a group containing a carbon atom, and may include atoms other than carbon atoms (e.g., a hydrogen atom, an oxygen atom, a nitrogen atom, a sulfur atom, a halogen atom (such as a fluorine atom or a chlorine atom) and the like).

The organic group for R⁵ and R⁶ is preferably a hydrocarbon group which may have a substituent. Examples of the hydrocarbon group include monovalent groups formed by adding one hydrogen atom to the same divalent hydrocarbon groups which may have a substituent as those described above in connection with the divalent linking group for A.

The organic group for R⁵ and R⁶ is most preferably an aryl group or an alkyl group.

The aryl group for R⁵ and R⁶ is not particularly limited, and examples thereof include groups in which one hydrogen atom has been removed from the aromatic hydrocarbon rings described above in connection with A. Of these, because they can be synthesized at a low cost, an aryl group of 6 to 10 carbon atoms is preferable, a phenyl group or a naphthyl group is more preferable, and a phenyl group is particularly desirable.

The aryl group may have a substituent. The expression “have a substituent” means that part of or all of the hydrogen atoms within the aryl group is substituted with a substituent, and examples of the substituent include an alkyl group, an alkoxy group, a halogen atom and a hydroxyl group. Of these, as examples of the alkyl group, alkoxy group and halogen atom, the same alkyl groups, alkoxy groups and halogen atoms as those described above as the substituent which the arylene group for R⁴ may have can be used.

The alkyl group for R⁵ and R⁶ is not particularly limited and may be any of linear, branched or cyclic. The alkyl group preferably has 1 to 10 carbon atoms, more preferably 1 to 8 carbon atoms, and still more preferably 1 to 5 carbon atoms. Specific examples of the alkyl group include a methyl group, an ethyl group, an n-propyl group, an isopropyl group, an n-butyl group, an isobutyl group, an n-pentyl group, a cyclopentyl group, a hexyl group, a cyclohexyl group, a nonyl group and a decanyl group. Among these, a methyl group is preferable because it is excellent in resolution and can be synthesized at a low cost.

The alkyl group may have a substituent. The expression “have a substituent” means that part of or all of the hydrogen atoms within the alkyl group is substituted with a substituent, and examples of the substituent include an alkoxy group, a halogen atom, a hydroxyl group and an oxygen atom (═O). Of these, as examples of the alkoxy group and halogen atom, the same alkoxy groups and halogen atoms as those described above as the substituent which the arylene group for R⁴ may have can be used.

In formula (I), R⁵ and R⁶ may be mutually bonded to form a ring together with the sulfur atom in the formula. Such a ring including the sulfur atom is preferably a 3- to 10-membered ring, and most preferably a 5- to 7-membered ring.

Such a ring may include another hetero atom as an atom to constitute the ring skeleton, in addition to the sulfur atom to which R⁵ and R⁶ are bonded. Examples of the hetero atom include a sulfur atom, an oxygen atom and a nitrogen atom.

Specific examples of the ring formed include a thiophene ring, a thiazole ring, a benzothiophene ring and a thianthrene ring.

In formula (I), X⁻ represents a counter anion.

The counter anion for X⁻ is not particularly limited, and examples thereof include an anion moiety of the onium salt-based acid generator listed in connection with the component (B) described later. Specific examples thereof include an anion moiety (R^{4″}SO₃⁻) of the onium salt-based acid generator represented by general formula (b-1) or (b-2) described later; and an anion moiety represented by general formula (b-3) or (b-4) described later. Of these, R^{4″}SO₃⁻ is preferable, and a fluorinated alkylsulfonate ion of 1 to 8 carbon atoms (and preferably 1 to 4 carbon atoms) or at least one member selected from those represented by general formulas (b1) to (b8) to be described later is more preferable.

In formula (II), A represents a single bond or a divalent linking group, and examples thereof include the same as those described above for A in formula (I).

Each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group.

The alkyl group for R^{fl} and R^{f2} preferably an alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The fluorinated alkyl group for R^{fl} and R^{f2} is preferably a group in which part or all of the hydrogen atoms within the aforementioned alkyl group for R^{f1} and R^{f2} have been substituted with a fluorine atom.

At least one of R^{f1} and R^{f2} represents a fluorine atom or a fluorinated alkyl group. It is particularly desirable that both of R^{f1} and R^{f2} bonded to the carbon atom that is directly bonded to the sulfur atom of —SO₃— at the side chain terminal in formula (II) is a fluorine atom.

It is particularly desirable that R^{fl} and R^{f2} be fluorine atoms.

n represents an integer of 1 to 8, preferably an integer of 1 to 4, and more preferably 1 or 2.

M^{m+} represents a counter cation, and m represents an integer of 1 to 3.

Examples of the counter cation for M^{m+} include a metal ion and an onium ion, and the onium ion is preferable.

Examples of the metal ion for M^{m+} include alkali metal ions such as sodium, potassium and lithium; alkaline earth metal ions such as magnesium and calcium; an iron ion; and an aluminum ion.

Examples of the onium ion for M^{m+} include a sulfonium ion, an iodonium ion, a phosphonium ion, a diazonium ion, an ammonium ion and a pyridinium ion. Among these, the cation moieties of an onium salt-based acid generator listed in connection with the component (B) described later are preferred, and specific examples thereof include the same cation moieties (sulfonium ions represented by S⁺(R^{1″})(R^{2″})(R^{3″}) or iodonium ions represented by I⁺(R^{5″})(R^{6″})) of the onium salt-based acid generator represented by general formula (b-1) or (b-2) described later. Of these, the sulfonium ions represented by S⁺(R^{1″})(R^{2″})(R^{3″}) are preferred, those in which at least one of R^{1″} to R^{3″} represents an aryl group which may have a substituent are more preferred, and those in which all of R^{1″} to R^{3″} represents an aryl group which may have a substituent are most preferred.

Specific examples of the group represented by formula (I) or (II) are shown below.

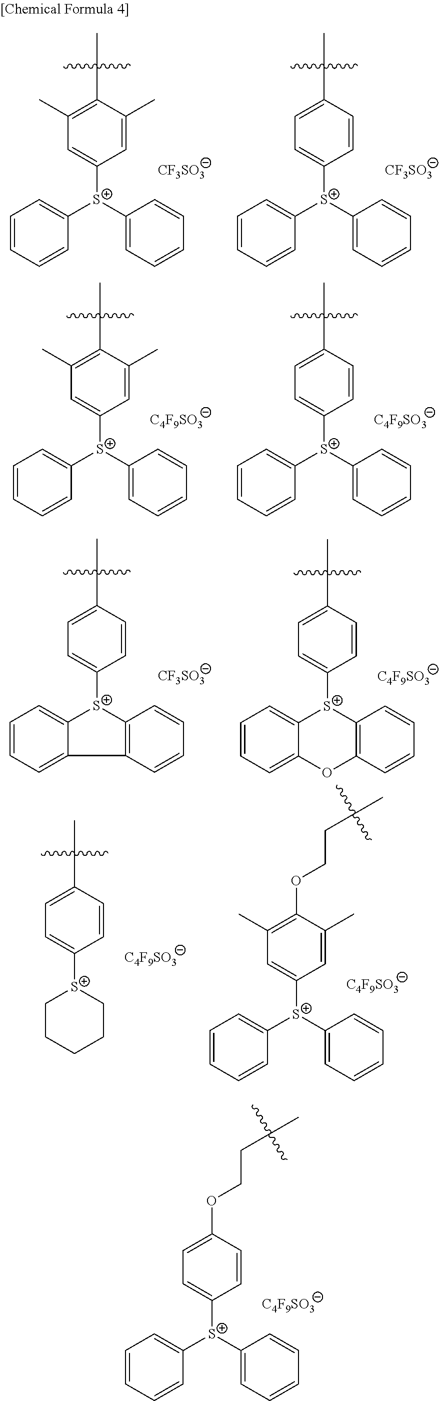

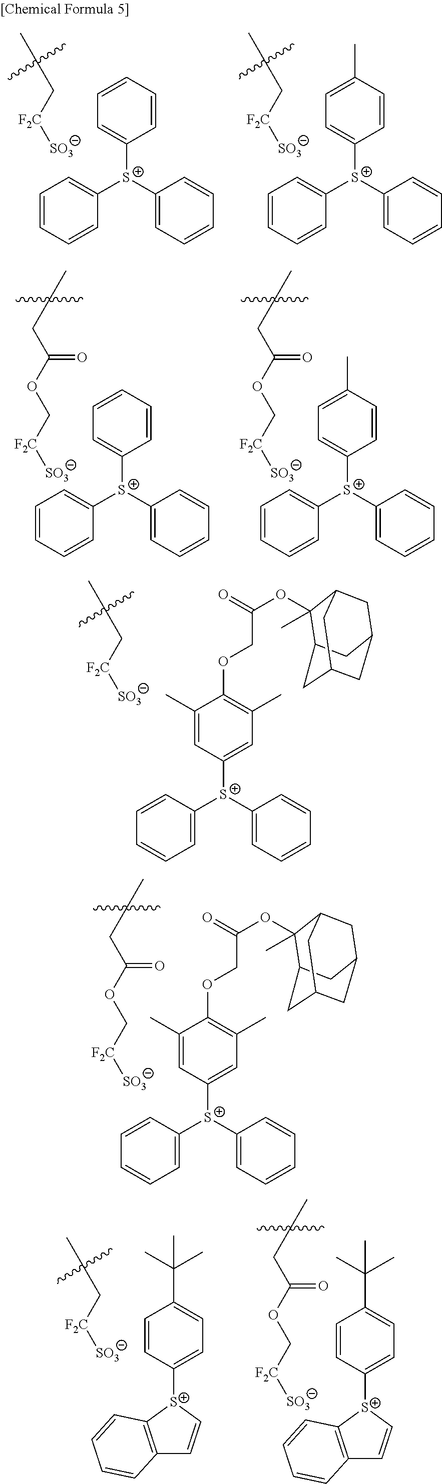

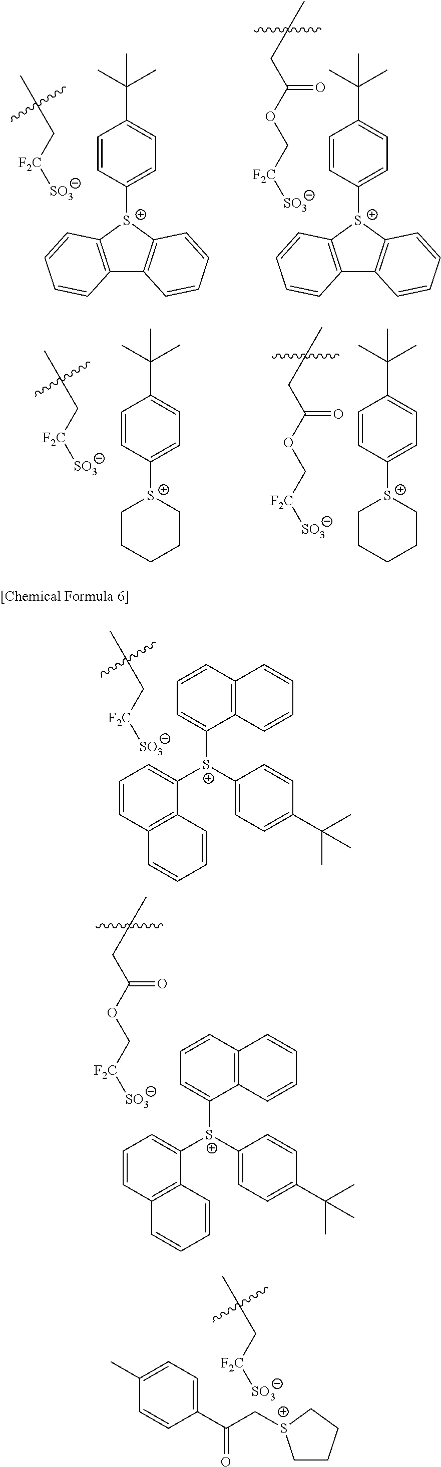

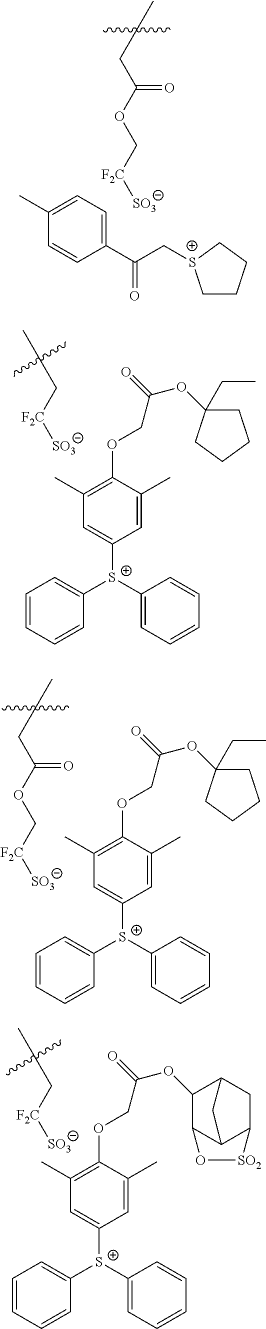

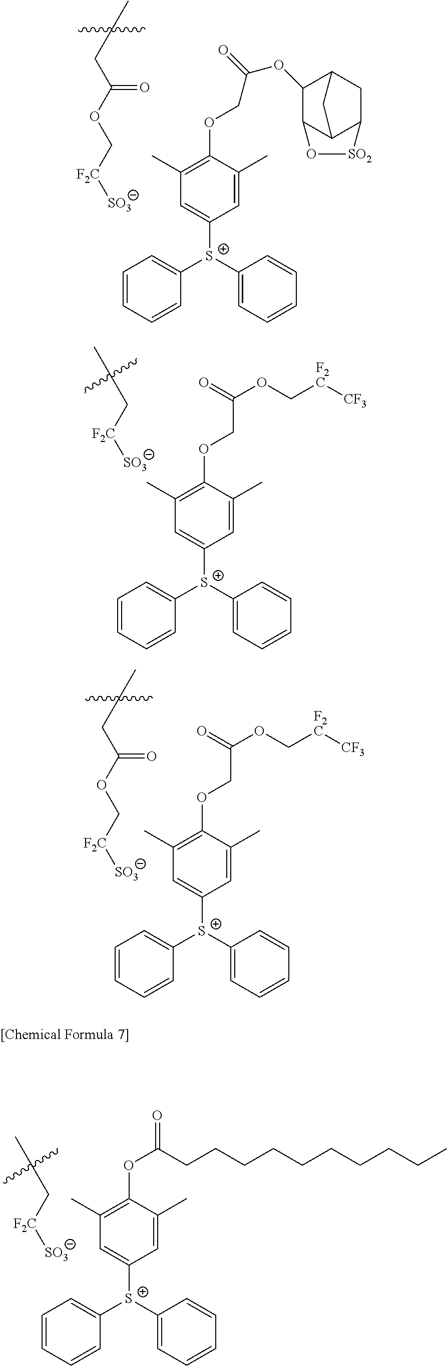

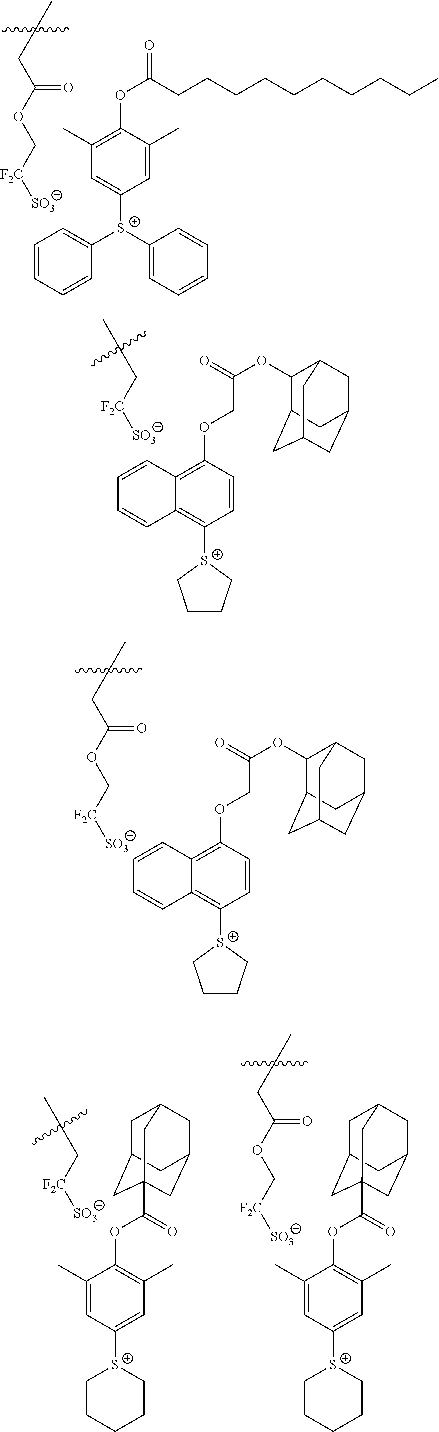

As the structural unit (a0) having the group represented by general formula (I) or (II) above, structural units represented by general formula (a0-1) or (a0-2) shown below are particularly preferred in view of acid strength, sensitivity, resolution, roughness, ease of synthesis, and the like.

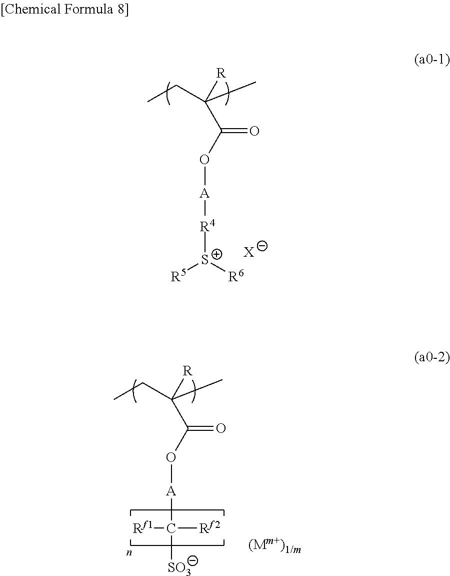

In the formulas, R represents a hydrogen atom, an alkyl group of 1 to 5 carbon atoms or a halogenated alkyl group of 1 to 5 carbon atoms; A represents a single bond or a divalent linking group; R⁴ represents an arylene group which may have a substituent; each of R⁵ and R⁶ independently represents an organic group, wherein R⁵ and R⁶ may be mutually bonded to form a ring together with the sulfur atom in the formula; X⁻ represents a counter anion; each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group; n represents an integer of 1 to 8; M^{m+} represents a counter cation; and m represents an integer of 1 to 3.

In formulas (a0-1) and (a0-2), R represents a hydrogen atom, an alkyl group of 1 to 5 carbon atoms or a halogenated alkyl group of 1 to 5 carbon atoms.

As the alkyl group for R, a linear or branched alkyl group is preferable, and specific examples thereof include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl groups of 1 to 5 carbon atoms has been substituted with a halogen atom. Specific examples of the alkyl group include the same alkyl groups as those described above for R. Examples of the halogen atom which substitutes the hydrogen atom within the alkyl group include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

In formulas (a0-1) and (a0-2), A, R⁴, R⁵, R⁶, X⁻, R^{f1}, R^{f2}, n, M^{m+} and m are respectively the same as defined for A, R⁴, R⁵, R⁶, X⁻, R^{f1}, R^{f2}, n, M^{m+} and m in the aforementioned formulas (I) and (II).

As the structural unit (a0) contained in the component (A1), one type of structural unit may be used, or two or more types may be used.

In the component (A1), the amount of the structural unit (a0) based on the combined total of all structural units constituting the component (A1) is preferably 1 to 30 mol %, more preferably 3 to 25 mol %, and still more preferably 5 to 20 mol %. When the amount of the structural unit (a0) is 1 mol % or more, the sensitivity improves, whereas the amount of 30 mol % or less improves the solubility in an organic solvent.

[Structural Unit (a1)]

A structural unit (a1) is a structural unit derived from an acrylate ester, in which a hydrogen atom bonded to the carbon atom on the α-position may be substituted with a substituent, and also a structural unit including an acid decomposable group that exhibits increased polarity by the action of acid.

In the present descriptions and the claims, the term “structural unit derived from an acrylate ester” refers to a structural unit which is formed by the cleavage of the ethylenic double bond of an acrylate ester.

An “acrylate ester” is a compound in which the hydrogen atom at the carboxyl group terminal of acrylic acid (CH₂═CH—COOH) has been substituted with an organic group.

With respect to the acrylate ester, a hydrogen atom bonded to the carbon atom on the α-position may be substituted with a substituent. The substituent for substituting the hydrogen atom bonded to the carbon atom on the α-position is an atom or group other than a hydrogen atom, and example thereof include an alkyl group of 1 to 5 carbon atoms, a halogenated alkyl group of 1 to 5 carbon atoms and a hydroxyalkyl group. A carbon atom on the α-position of an acrylate ester refers to the carbon atom bonded to the carbonyl group, unless specified otherwise.

Hereafter, an acrylate ester in which a hydrogen atom bonded to the carbon atom on the α-position has been substituted with a substituent is sometimes referred to as an α-substituted acrylate ester. Further, acrylate esters and α-substituted acrylate esters are sometimes collectively referred to as (α-substituted) acrylate esters.

With respect to the α-substituted acrylate esters, the alkyl group as a substituent on the α-position is preferably a linear or branched alkyl group, and specific examples thereof include a methyl group, an ethyl group, a propyl group, an isopropyl group, an n-butyl group, an isobutyl group, a tert-butyl group, a pentyl group, an isopentyl group and a neopentyl group.

Further, specific examples of the halogenated alkyl group as a substituent on the α-position include groups in which some or all of the hydrogen atoms of the aforementioned “alkyl group as a substituent on the α-position” have been substituted with halogen atoms. Examples of the halogen atom include a fluorine atom, a chlorine atom, a bromine atom and an iodine atom, and a fluorine atom is particularly desirable.

It is preferable that a hydrogen atom, an alkyl group of 1 to 5 carbon atoms or a halogenated alkyl group of 1 to 5 carbon atoms is bonded to the α-position of the α-substituted acrylate esters, and more preferably a hydrogen atom, an alkyl group of 1 to 5 carbon atoms or a fluorinated alkyl group of 1 to 5 carbon atoms. In terms of industrial availability, a hydrogen atom or a methyl group is the most desirable.

The term “acid decomposable group” refers to a group exhibiting acid decomposability in which at least a part of the bond within the structure of this acid decomposable group may be cleaved by the action of an acid (including the acid generated from the structural unit (a0) upon exposure).

Examples of acid decomposable groups that exhibit increased polarity by the action of an acid include groups which are decomposed by the action of an acid to form a polar group.

Examples of the polar group include a carboxyl group, a hydroxyl group, an amino group and a sulfo group (—SO₃H). Of these, polar groups containing an —O—H moiety within the structure (hereafter, sometimes referred to as an “OH-containing polar group”) are preferable, a carboxyl group or a hydroxyl group is more preferable, and a carboxyl group is particularly desirable.

Specific examples of acid decomposable groups include groups in which the aforementioned polar group is protected with an acid dissociable group (such as groups in which the hydrogen atom of an OH-containing polar group is protected with an acid dissociable group).

An “acid dissociable group” is a group exhibiting acid dissociability in which at least the bond between the acid dissociable group and the atom adjacent to this acid dissociable group may be cleaved by the action of an acid (including the acid generated from the structural unit (a0) upon exposure). The acid dissociable group constituting an acid decomposable group needs to be a group that exhibits lower polarity than the polar group formed by the dissociation of this acid dissociable group. Due to this, when the acid dissociable group dissociates by the action of acid, a polar group exhibiting higher polarity than this acid dissociable group is formed, thereby increasing the polarity. As a result, the polarity of the entire component (A1) increases. Due to the increase in polarity, relatively, the solubility in an alkali developing solution increases, whereas the solubility in an organic developing solution containing an organic solvent reduces.

The acid dissociable group is not particularly limited, and any of the groups that have been conventionally proposed as acid dissociable groups for the base resins of chemically amplified resists can be used. Generally, groups that form either a cyclic or chain-like tertiary alkyl ester with the carboxyl group of the (meth)acrylic acid, and acetal-type acid dissociable groups such as alkoxyalkyl groups are widely known. Here, the term “(meth)acrylate ester” is a generic term that includes either or both of the acrylate ester having a hydrogen atom bonded to the α-position and the methacrylate ester having a methyl group bonded to the α-position.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(O)—O—). In this tertiary alkyl ester, the action of acid causes cleavage of the bond between the oxygen atom and the tertiary carbon atom, thereby forming a carboxyl group.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and aliphatic cyclic group-containing acid dissociable groups.

Here, the term “aliphatic branched” refers to a branched structure having no aromaticity. The “aliphatic branched, acid dissociable group” is not limited to be constituted of only carbon atoms and hydrogen atoms (not limited to hydrocarbon groups), but is preferably a hydrocarbon group. Further, the “hydrocarbon group” may be either saturated or unsaturated, but is preferably saturated.

As an example of the aliphatic branched, acid dissociable group, for example, a group represented by the formula —C(R⁷¹)(R⁷²)(R⁷³) can be given (in the formula, each of R⁷¹ to R⁷³ independently represents a linear alkyl group of 1 to 5 carbon atoms). The group represented by the formula —C(R⁷¹)(R⁷²)(R⁷³) preferably has 4 to 8 carbon atoms, and specific examples include a tert-butyl group, a 2-methyl-2-butyl group, a 2-methyl-2-pentyl group and a 3-methyl-3-pentyl group.

Among these, a tert-butyl group is particularly desirable.

The term “aliphatic cyclic group” refers to a monocyclic group or polycyclic group that has no aromaticity.

In the “aliphatic cyclic group-containing acid dissociable group”, the “aliphatic cyclic group” may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (hydrocarbon groups), but is preferably a hydrocarbon group. Further, the “hydrocarbon group” may be either saturated or unsaturated, but is preferably saturated.

The aliphatic cyclic group may be either a monocyclic group or a polycyclic group.

As such aliphatic cyclic groups, groups in which one or more hydrogen atoms have been removed from a monocycloalkane or a polycycloalkane such as a bicycloalkane, tricycloalkane or tetracycloalkane which may or may not be substituted with an alkyl group of 1 to 5 carbon atoms, a fluorine atom or a fluorinated alkyl group, may be used. Specific examples of aliphatic cyclic hydrocarbon groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. Further, in these aliphatic cyclic hydrocarbon groups, part of the carbon atoms constituting the ring may be replaced with an ether group (—O—).

Examples of aliphatic cyclic group-containing acid dissociable groups include

(i) a group which forms a tertiary carbon atom on the ring structure of a monovalent aliphatic cyclic group in which a substituent (a group or an atom other than hydrogen) is bonded to the carbon atom to which an atom adjacent to the acid dissociable, dissolution inhibiting group (e.g., “—O—” within “—C(═O)—O— group”) is bonded; and

(ii) a group which has a branched alkylene group containing a tertiary carbon atom, and a monovalent aliphatic cyclic group to which the tertiary carbon atom is bonded.

In the group (i), as the substituent bonded to the carbon atom to which an atom adjacent to the acid dissociable group is bonded on the ring skeleton of the aliphatic cyclic group, an alkyl group can be mentioned. Examples of the alkyl group include the same groups as those represented by R¹⁴ in formulas (1-1) to (1-9) described later.

Specific examples of the group (i) include groups represented by general formulas (1-1) to (1-9) shown below.

Specific examples of the group (ii) include groups represented by general formulas (2-1) to (2-6) shown below.

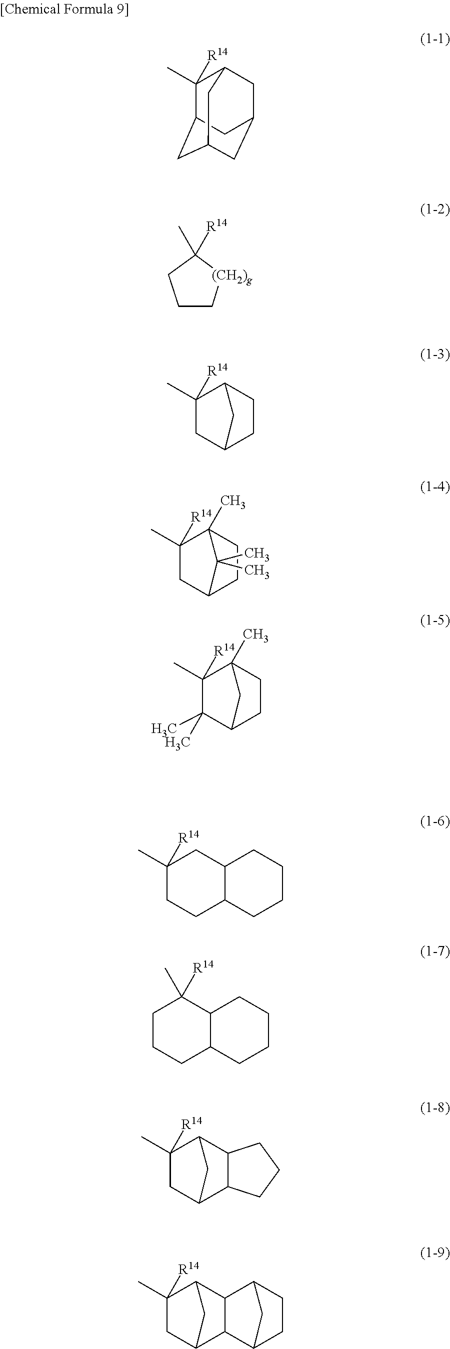

In the formulas above, R¹⁴ represents an alkyl group; and g represents an integer of 0 to 8.

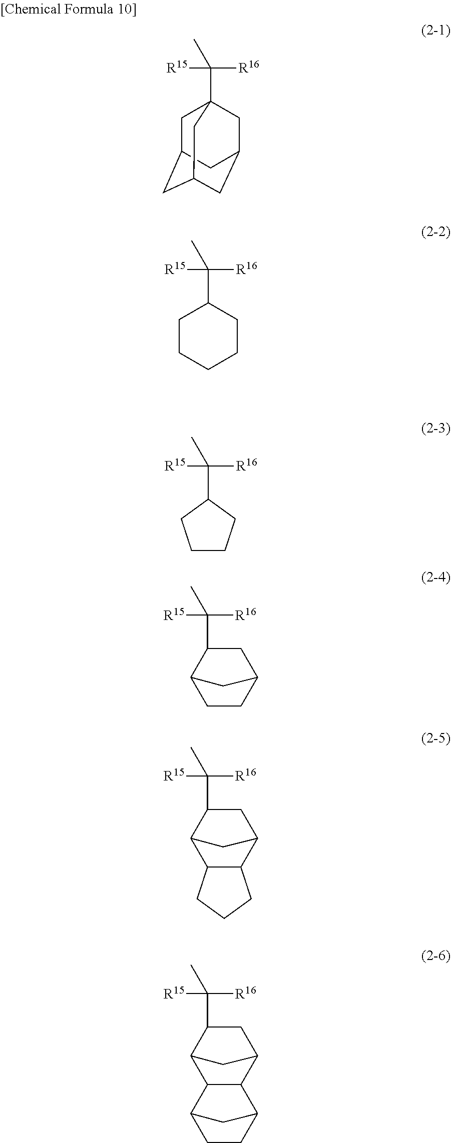

In the formulas above, each of R¹⁵ and R¹⁶ independently represents an alkyl group.

In formulas (1-1) to (1-9), the alkyl group for R¹⁴ may be linear, branched or cyclic, and is preferably linear or branched.

The linear alkyl group preferably has 1 to 5 carbon atoms, more preferably 1 to 4 carbon atoms, and still more preferably 1 or 2 carbon atoms. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5 carbon atoms. Specific examples of such branched alkyl groups include an isopropyl group, an isobutyl group, a tert-butyl group, an isopentyl group and a neopentyl group, and an isopropyl group is particularly desirable.

g is preferably an integer of 0 to 3, more preferably an integer of 1 to 3, and still more preferably 1 or 2.

In formulas (2-1) to (2-6), as the alkyl group for R¹⁵ and R¹⁶, the same alkyl groups as those for R¹⁴ can be used.

In formulas (1-1) to (1-9) and (2-1) to (2-6), part of the carbon atoms constituting the ring may be replaced with an ethereal oxygen atom (—O—).

Further, in formulas (1-1) to (1-9) and (2-1) to (2-6), one or more of the hydrogen atoms bonded to the carbon atoms constituting the ring may be substituted with a substituent. Examples of the substituent include an alkyl group of 1 to 5 carbon atoms, a fluorine atom and a fluorinated alkyl group.

An “acetal-type acid dissociable group” generally substitutes a hydrogen atom at the terminal of an OH-containing polar group such as a carboxyl group or hydroxyl group, so as to be bonded with an oxygen atom. When acid is generated upon exposure, the generated acid acts to break the bond between the acetal-type acid dissociable group and the oxygen atom to which the acetal-type, acid dissociable group is bonded, thereby forming an OH-containing polar group such as a carboxyl group or a hydroxyl group.

Examples of acetal-type acid dissociable groups include groups represented by general formula (p1) shown below.

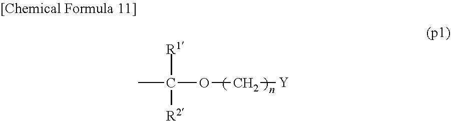

In the formula, each of R^{1′} and R^{2′} independently represents a hydrogen atom or an alkyl group of 1 to 5 carbon atoms; n represents an integer of 0 to 3; and Y represents an alkyl group of 1 to 5 carbon atoms or an aliphatic cyclic group.

In general formula (p1), n is preferably an integer of 0 to 2, more preferably 0 or 1, and most preferably 0.

As the alkyl group for R^{1′} and R^{2′}, the same alkyl groups as those described above as the substituent on the α-position of the aforementioned acrylate ester can be used, although a methyl group or ethyl group is preferable, and a methyl group is particularly desirable.

In the present invention, it is preferable that at least one of R^{1′} and R^{2′} be a hydrogen atom. That is, it is preferable that the acid dissociable group (p1) is a group represented by general formula (p1-1) shown below.

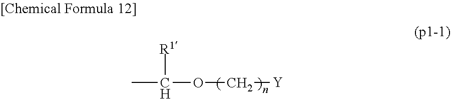

In the formula, R^{1′}, n and Y are the same as defined above.

As the alkyl group for Y, the same alkyl groups as those described above for the substituent on the α-position of the aforementioned acrylate ester can be used.

As the aliphatic cyclic group for Y, any of the aliphatic monocyclic or polycyclic groups that have been proposed for conventional ArF resists and the like can be appropriately selected for use. For example, the same aliphatic cyclic groups as those described above in connection with the “acid dissociable group containing an aliphatic cyclic group” can be used.

Further, as the acetal-type, acid dissociable group, groups represented by general formula (p2) shown below can also be used.

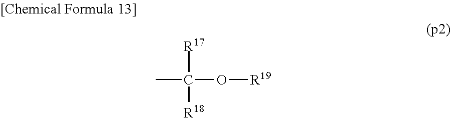

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represents a linear or branched alkylene group, and the R¹⁷ group is bonded to the R¹⁹ group to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cyclic alkyl group, it preferably has 4 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

Further, in general formula (p2) above, each of R¹⁷ and R¹⁹ may independently represent a linear or branched alkylene group (preferably an alkylene group of 1 to 5 carbon atoms), and the R¹⁹ group may be bonded to the R¹⁷ group.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include a tetrahydropyranyl group and a tetrahydrofuranyl group.

Specific examples of the structural unit (a1) include a structural unit represented by general formula (a1-0-1) shown below and a structural unit represented by general formula (a1-0-2) shown below.

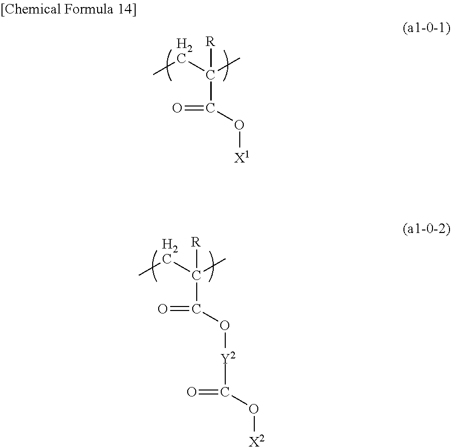

In the formulas, R represents a hydrogen atom, an alkyl group of 1 to 5 carbon atoms or a halogenated alkyl group of 1 to 5 carbon atoms; X¹ represents an acid dissociable group; Y² represents a divalent linking group; and X² represents an acid dissociable group.

In general formula (a1-0-1), the alkyl group and the halogenated alkyl group for R are respectively the same as defined for the alkyl group and the halogenated alkyl group for the substituent on the α-position of the aforementioned α-substituted acrylate ester. R is preferably a hydrogen atom, an alkyl group of 1 to 5 carbon atoms or a fluorinated alkyl group of 1 to 5 carbon atoms, and is most preferably a hydrogen atom or a methyl group.

X¹ is not particularly limited as long as it is an acid dissociable group. Examples thereof include the aforementioned tertiary alkyl ester-type acid dissociable groups and acetal-type acid dissociable groups, and tertiary alkyl ester-type acid dissociable groups are preferable.

In general formula (a1-0-2), R is the same as defined above.

X² is the same as defined for X¹ in general formula (a1-0-1).

The divalent linking group for Y² is not particularly limited, and preferable examples thereof include a divalent hydrocarbon group which may have a substituent and a divalent linking group containing a hetero atom. Examples of these “divalent hydrocarbon groups which may have a substituent” and “divalent linking groups containing a hetero atom” include the same divalent linking groups as those defined above for A in general formula (a0-1) or (a0-2) described in connection with the structural unit (a0).

As the divalent linking group for Y², a linear or branched alkylene group, a divalent alicyclic hydrocarbon group or a divalent linking group containing a hetero atom is particularly desirable. Among these, a linear or branched alkylene group, or a divalent linking group containing a hetero atom is more preferable.

When Y² represents an alkylene group, the alkylene group preferably has 1 to 10 carbon atoms, more preferably 1 to 6 carbon atoms, still more preferably 1 to 4 carbon atoms, and most preferably 1 to 3 carbon atoms. Specific examples of alkylene groups include the aforementioned linear alkylene groups and branched alkylene groups.

When Y² represents a divalent alicyclic hydrocarbon group, as the alicyclic hydrocarbon group, the same alicyclic hydrocarbon groups as those described above for the “aliphatic hydrocarbon group containing a ring in the structure thereof” can be used.

As the alicyclic hydrocarbon group, a group in which two or more hydrogen atoms have been removed from cyclopentane, cyclohexane, norbornane, isobornane, adamantane, tricyclodecane or tetracyclododecane is particularly desirable.

When Y² represents a divalent linking group containing a hetero atom, preferred examples of the linking groups include —O—, —C(═O)—O—, —C(═O)—, —O—C(═O)—O—, —C(═O)—NH—, —NH— (H may be replaced with a substituent such as an alkyl group, an acyl group or the like), —S—, —S(═O)₂—, —S(═O)₂—O—, groups represented by general formula —Y²¹—O—Y²²—, —[Y²¹—C(═O)—O]_{m′}—Y²²— or —Y²¹—O—C(═O)—Y²²—[in the formulas, each of Y²¹ and Y²² independently represents a divalent hydrocarbon group which may have a substituent, O represents an oxygen atom, and m′ represents an integer of 0 to 3].

When Y² represents —NH—, H may be substituted with a substituent such as an alkyl group, an aryl group (an aromatic group) or the like. The substituent (an alkyl group, an aryl group or the like) preferably has 1 to 10 carbon atoms, more preferably 1 to 8 carbon atoms, and most preferably 1 to 5 carbon atoms.

In formulas —Y²¹—O—Y²²—, —[Y²¹—C(═O)—O]_{m′}—Y²²— or —Y²¹—O—C(═O)—Y²²—, each of Y²¹ and Y²² independently represents a divalent hydrocarbon group which may have a substituent. Examples of the divalent hydrocarbon groups include the same groups as those described above for the “divalent hydrocarbon group which may have a substituent” usable as Y².

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}—Y²²—, m′ represents an integer of 0 to 3, preferably an integer of 0 to 2, more preferably 0 or 1, and most preferably 1. In other words, it is particularly desirable that the group represented by the formula —[Y²¹—C(═O)—O]_{m′}—Y²²— be a group represented by the formula —Y²¹—C(═O)—O—Y²²—. Of these, groups represented by the formula —(CH2)_{a′}—C(═O)—O—(CH₂)_{b′}— are preferred. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking groups containing a hetero atom, linear groups containing an oxygen atom as a hetero atom, e.g., groups containing an ether bond or ester bond are preferred, and groups represented by the above formula —Y²¹—O—Y²²—, —[Y²¹—C(═O)—O]_{m′}—Y²²— or —Y²¹—O—C(═O)—Y²²— are more preferred.

Specific examples of the structural unit (a1) include structural units represented by general formulas (a1-1) to (a1-4) shown below.

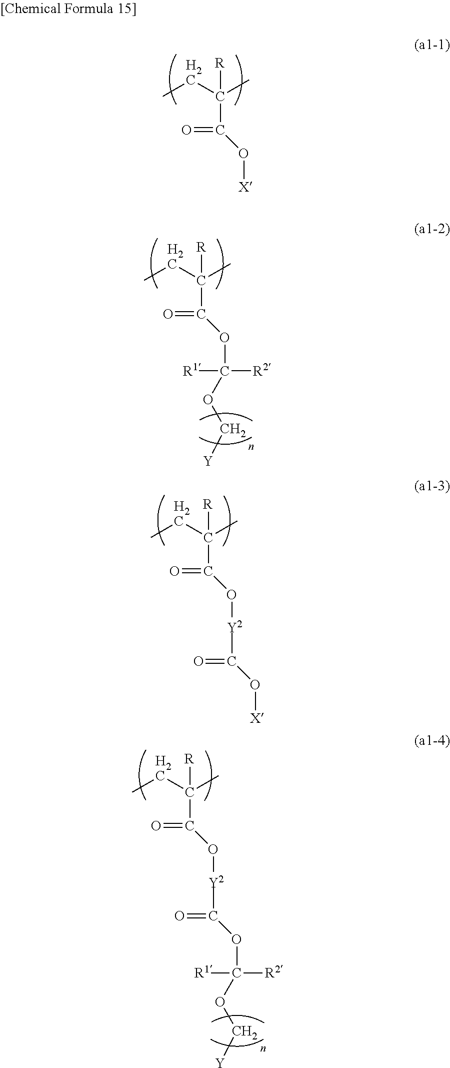

In the formulas, R, R^{1′}, R^{2′}, n, Y and Y² are the same as defined above; and X′ represents a tertiary alkyl ester-type acid dissociable group.

In the formulas, the tertiary alkyl ester-type acid dissociable group for X′ include the same tertiary alkyl ester-type acid dissociable groups as those described above.

As R^{1′}, R^{2′}, n and Y are respectively the same as defined for R^{1′}, R^{2′}, n and Y in general formula (p1) described above in connection with the “acetal-type acid dissociable group”.

As examples of Y², the same groups as those described above for Y² in general formula (a1-0-2) can be given.

Specific examples of structural units represented by general formula (a1-1) to (a1-4) are shown below.

In each of the following formulas, R^{α} represents a hydrogen atom, a methyl group or a trifluoromethyl group.

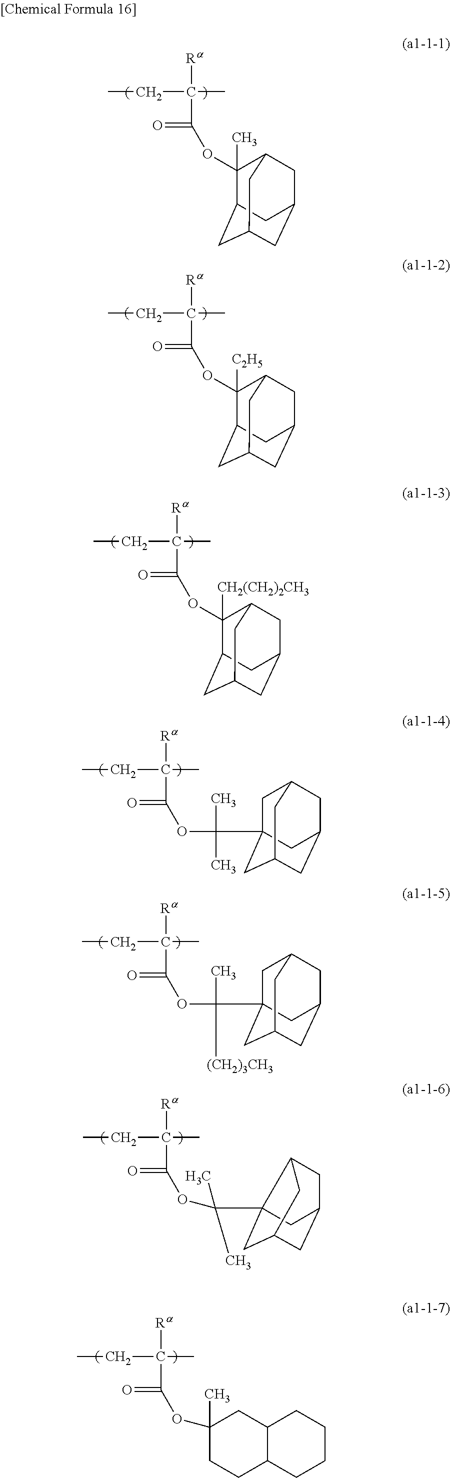

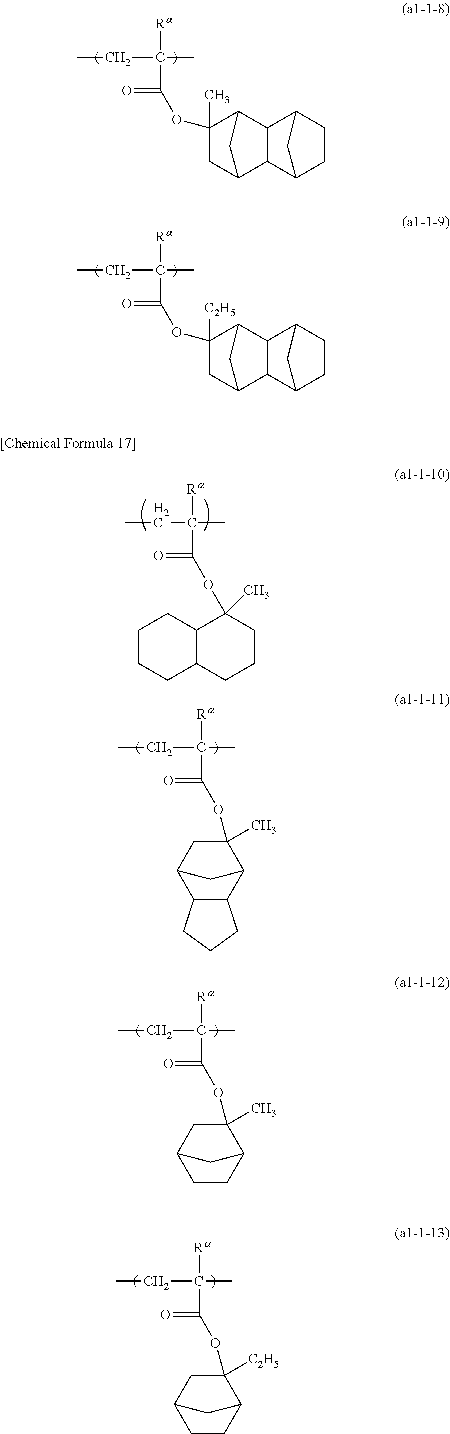

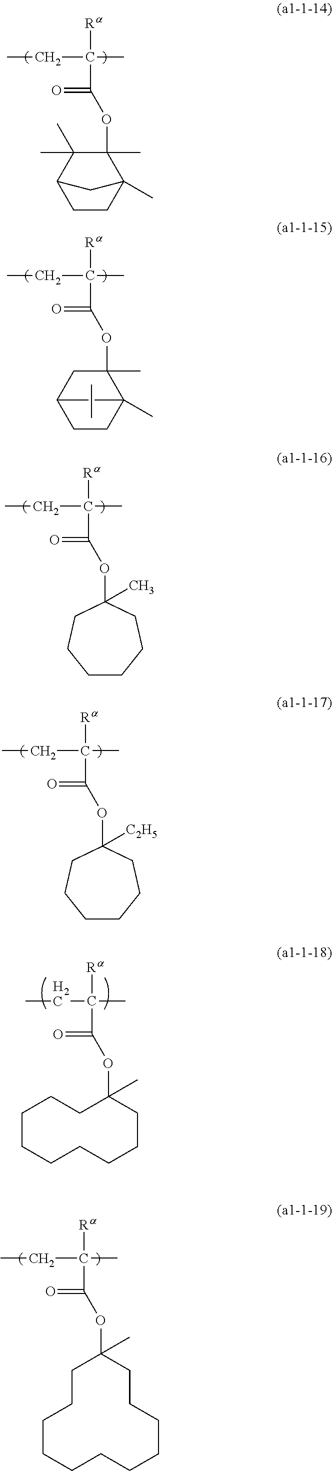

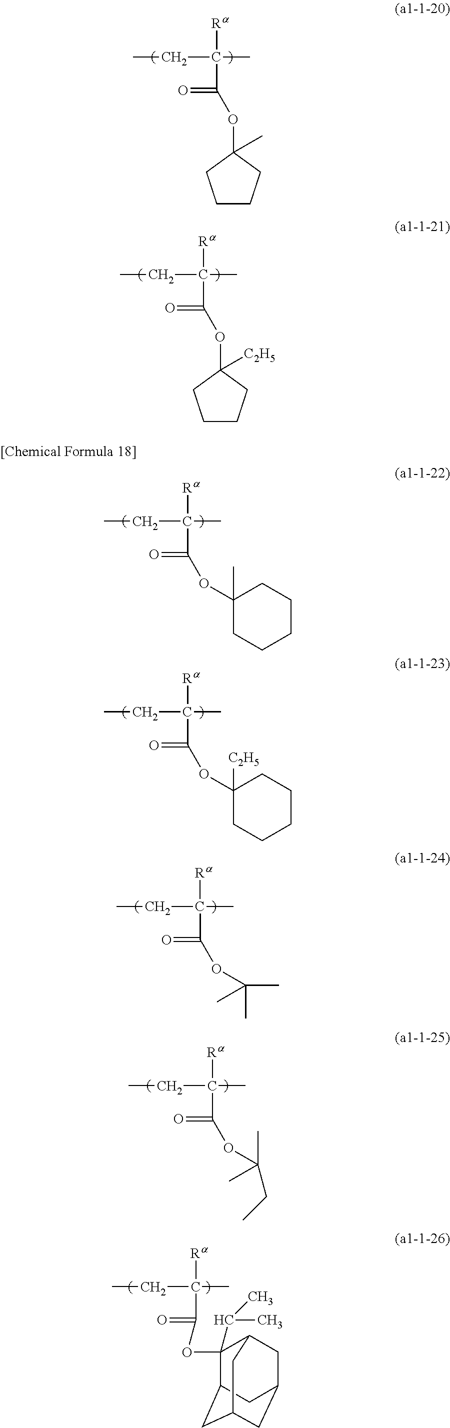

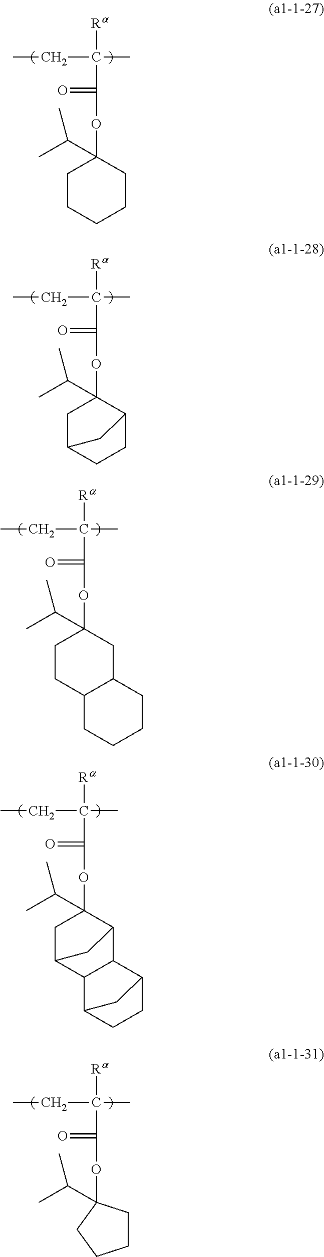

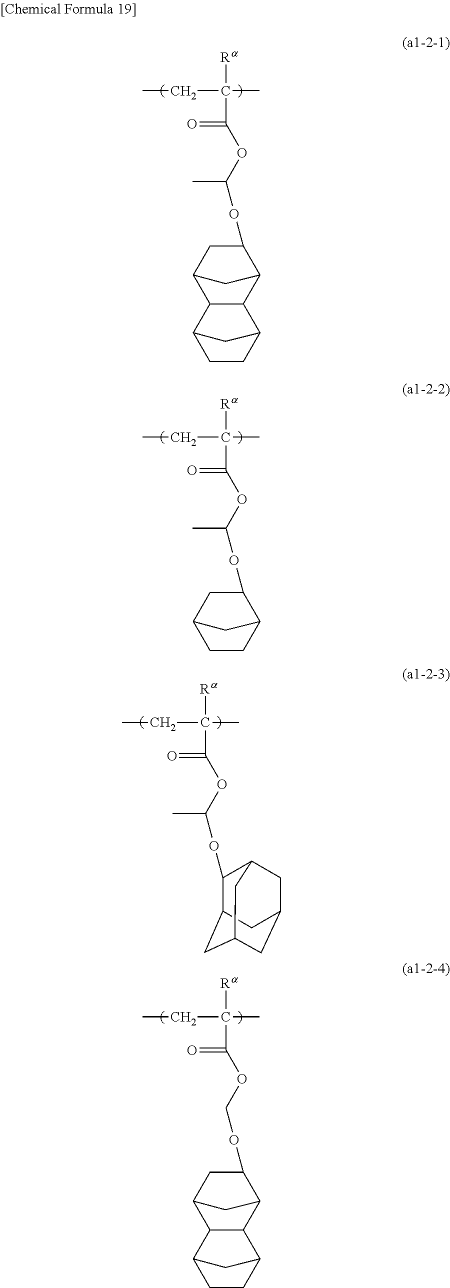

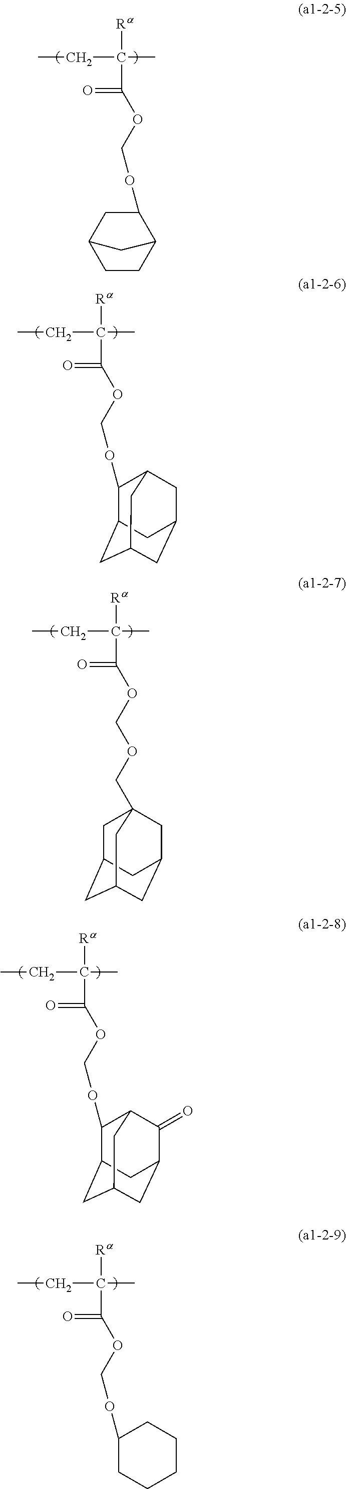

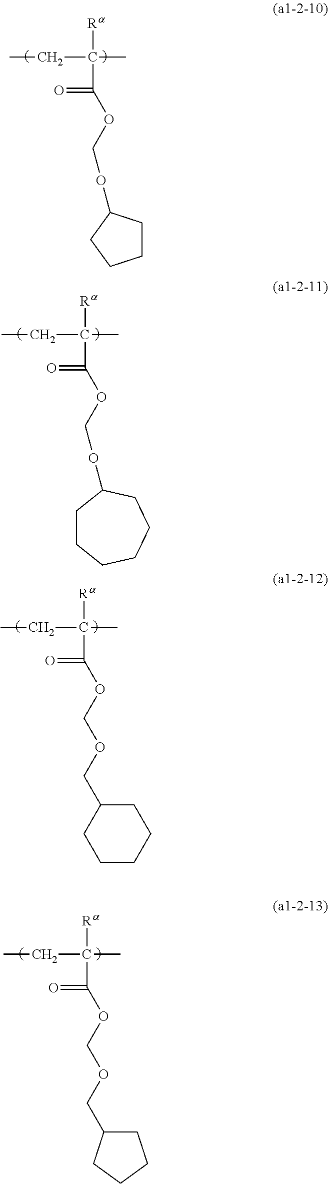

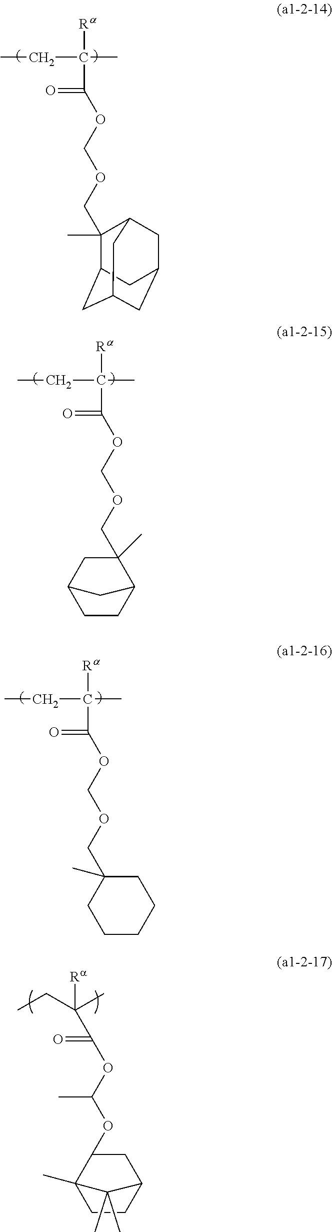

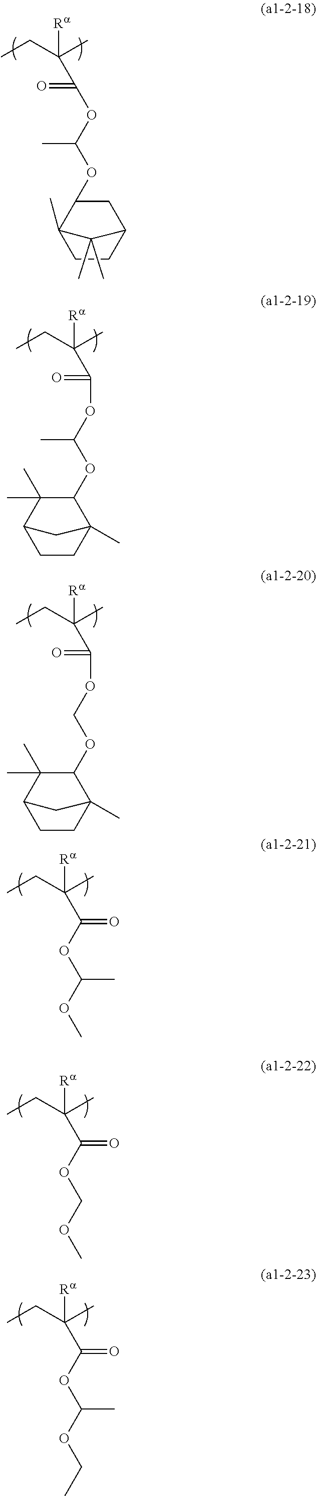

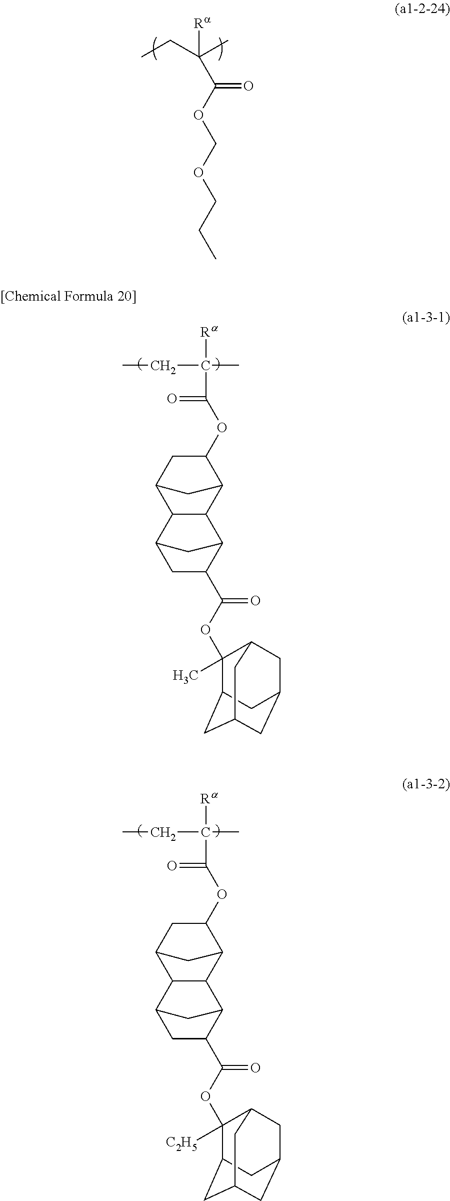

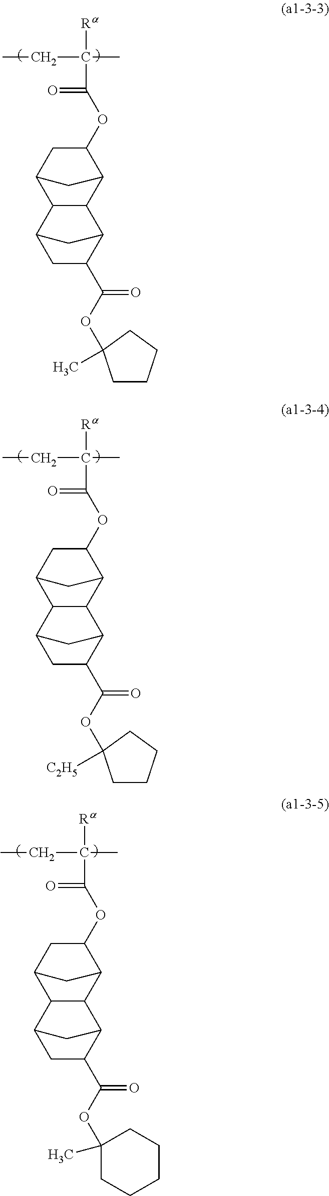

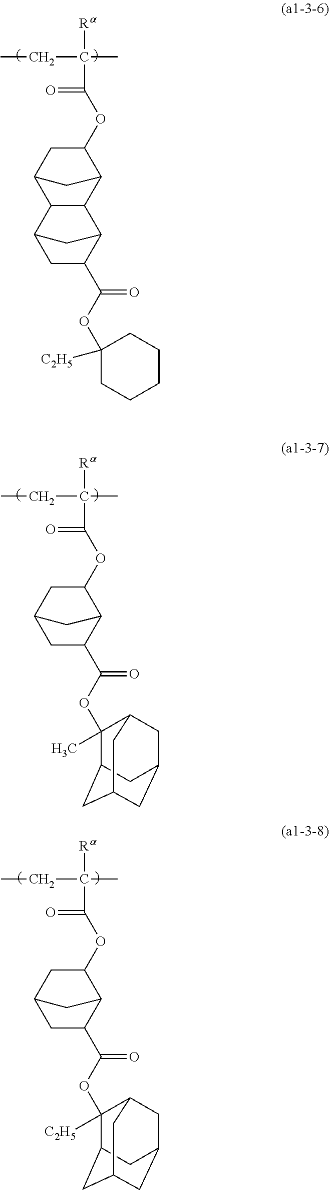

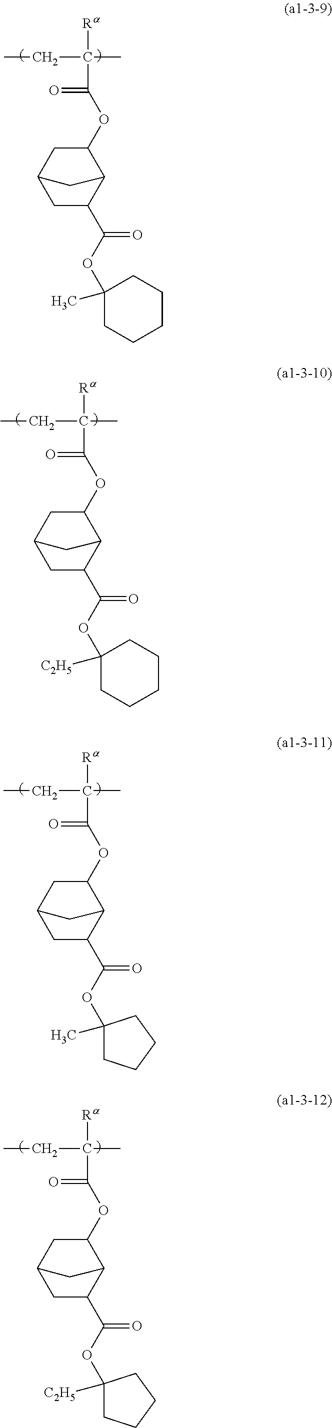

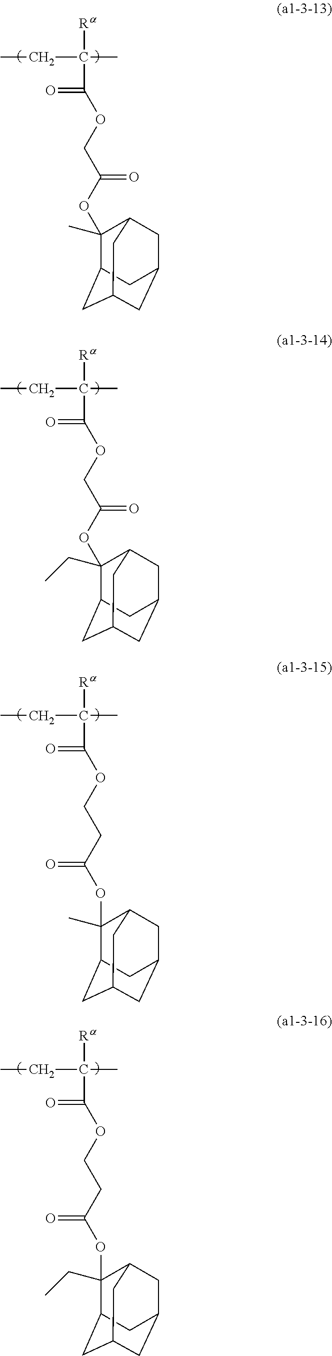

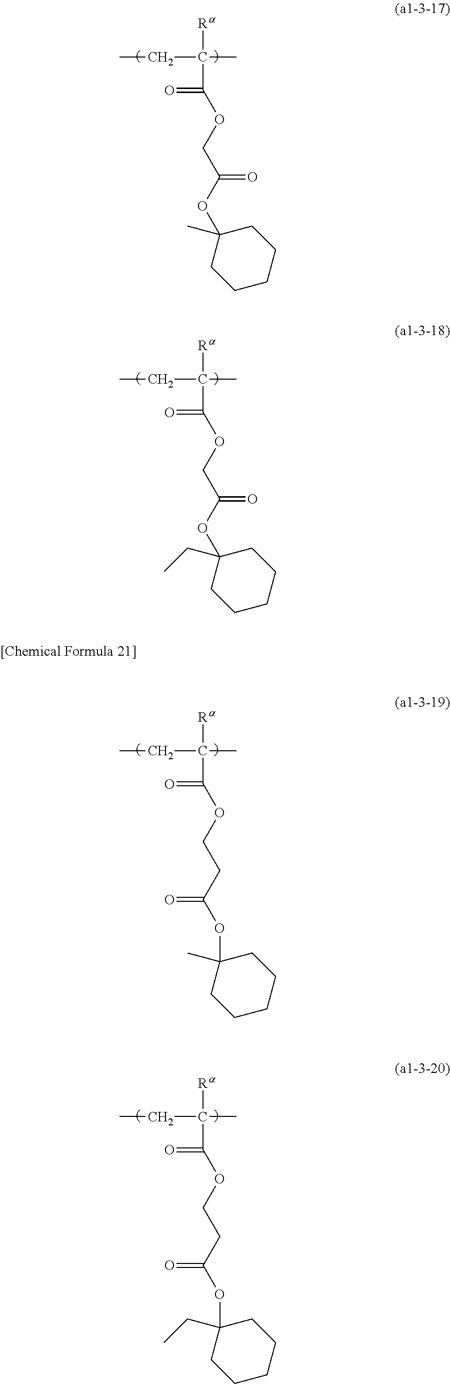

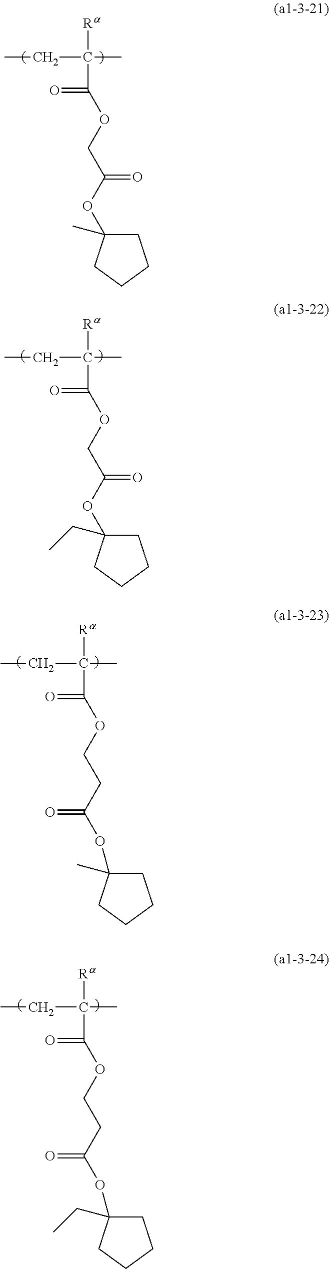

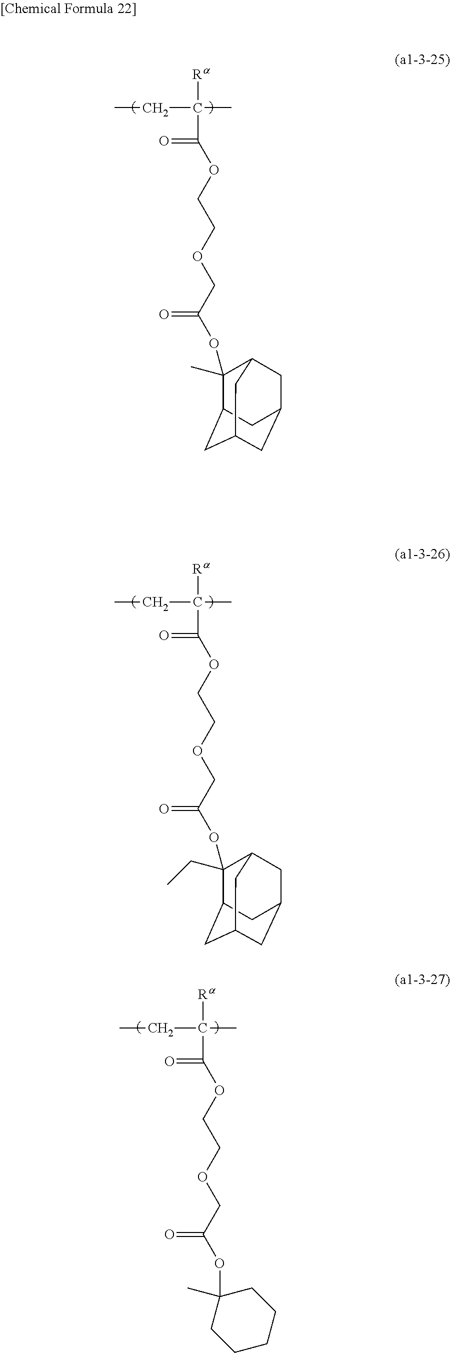

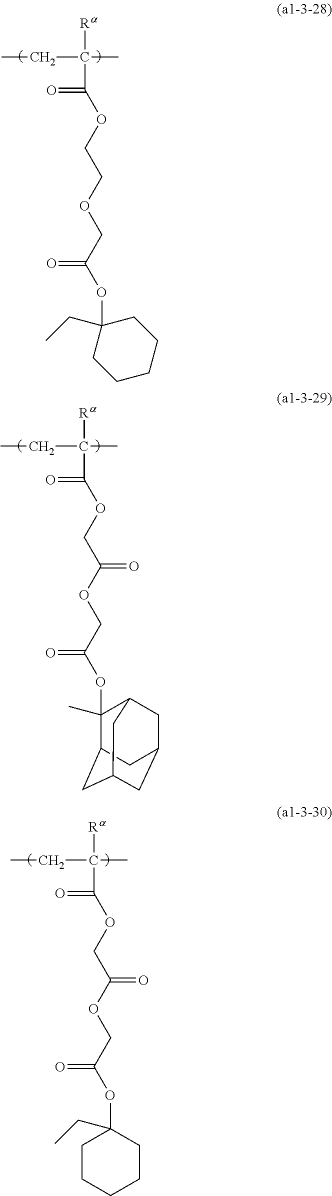

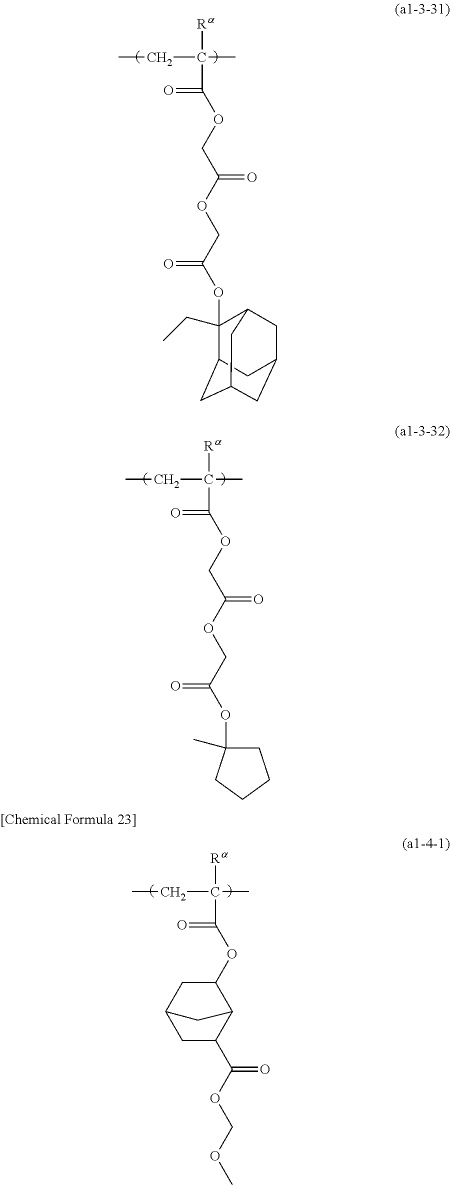

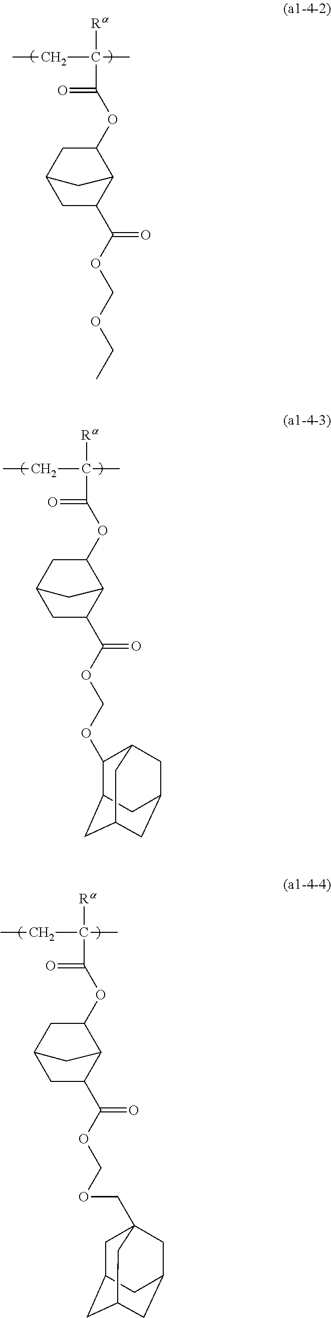

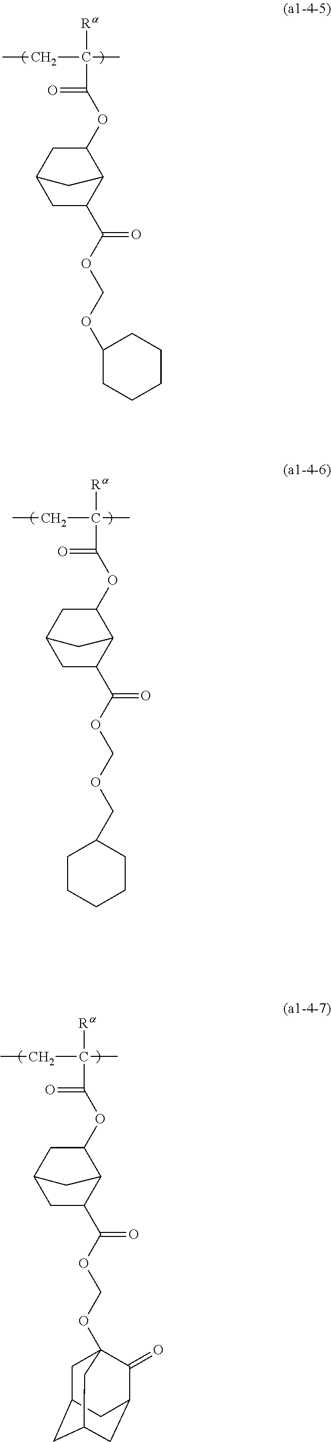

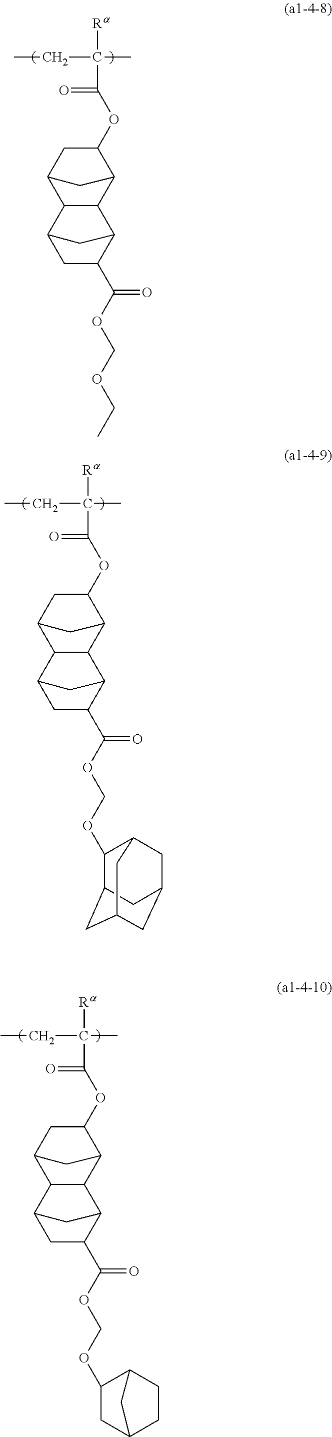

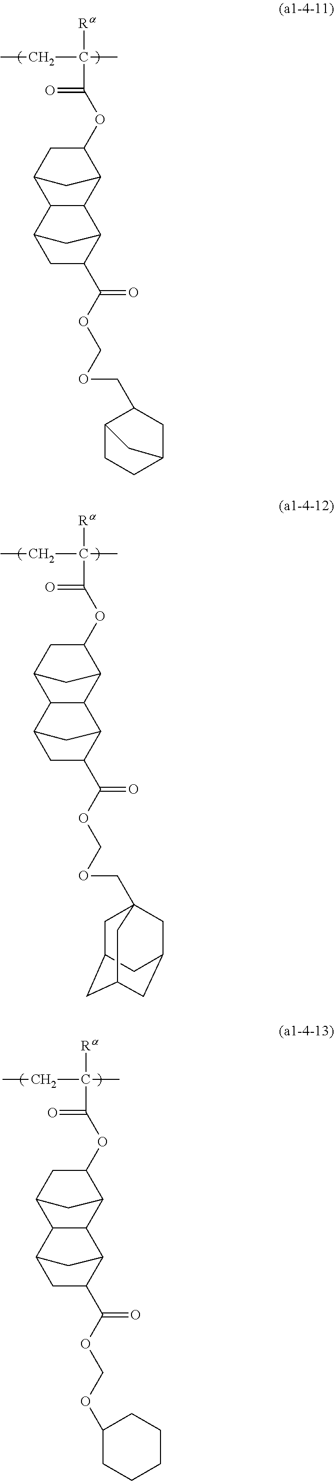

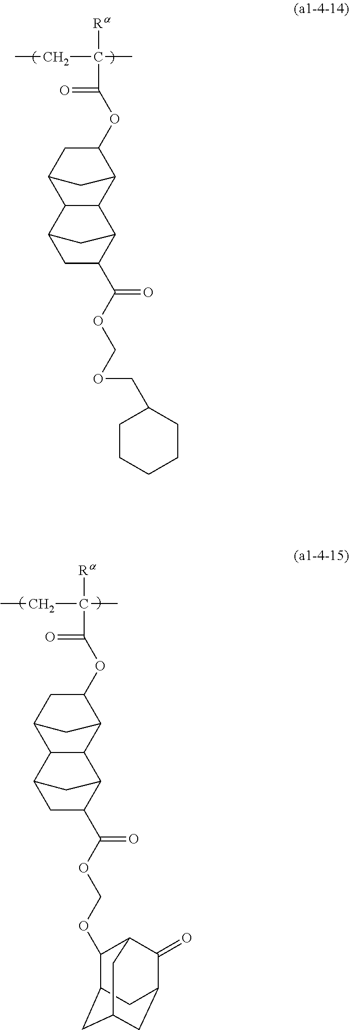

In the present invention, as the structural unit (a1), it is preferable to include at least one structural unit selected from the group consisting of structural units represented by general formula (a1-0-11) shown below, structural units represented by general formula (a1-0-12) shown below, structural units represented by general formula (a1-0-13) shown below and structural units represented by general formula (a1-0-2) shown below. It is particularly desirable that the structural unit (a1) include at least one structural unit selected from the group consisting of structural units represented by general formula (a1-0-11) shown below, structural units represented by general formula (a1-0-12) shown below and structural units represented by general formula (a1-0-2) shown below.

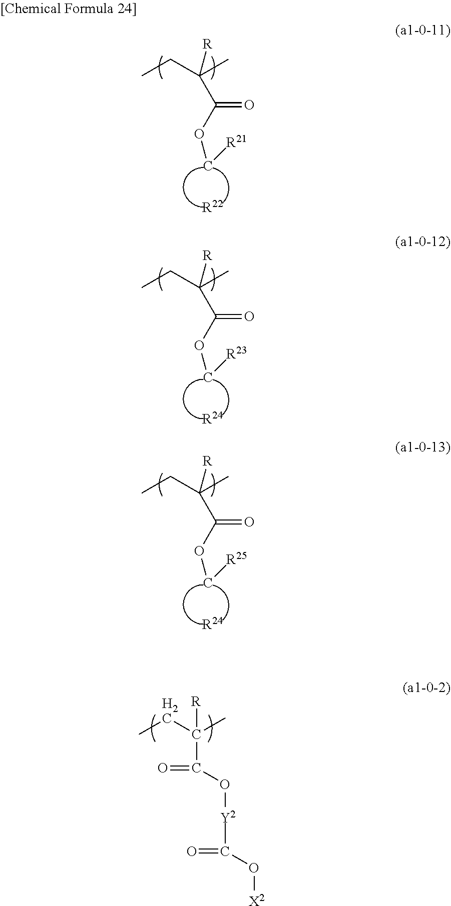

In the formulas, R represents a hydrogen atom, an alkyl group of 1 to 5 carbon atoms or a halogenated alkyl group of 1 to 5 carbon atoms; R²¹ represents an alkyl group; R²² represents a group which forms an aliphatic monocyclic group with the carbon atom to which this R²² group is bonded; R²³ represents a branched alkyl group; R²⁴ represents a group which forms an aliphatic polycyclic group with the carbon atom to which this R²⁴ group is bonded; R²⁵ represents a linear alkyl group of 1 to 5 carbon atoms; Y² represents a divalent linking group; and X² represents an acid dissociable group.

In the formulas, R, Y² and X² are the same as defined above.

In general formula (a1-0-11), as the alkyl group for R²¹, the same alkyl groups as those described above for R¹⁴ in formulas (1-1) to (1-9) can be used, and a methyl group, an ethyl group or an isopropyl group is preferable.

As the aliphatic monocyclic group formed by R²² and the carbon atoms to which this R²² group is bonded, the same aliphatic cyclic groups as those described above for the aforementioned tertiary alkyl ester-type acid dissociable group and which are monocyclic can be used. Specific examples include groups in which one or more hydrogen atoms have been removed from a monocycloalkane. The monocycloalkane is preferably a 3- to 11-membered ring, more preferably a 3- to 8-membered ring, still more preferably a 4- to 6-membered ring, and most preferably a 5- or 6-membered ring.

The monocycloalkane may or may not have part of the carbon atoms constituting the ring replaced with an ether group (—O—).

Further, the monocycloalkane may have a substituent such as an alkyl group of 1 to 5 carbon atoms, a fluorine atom or a fluorinated alkyl group of 1 to 5 carbon atoms.

As an examples of R²² constituting such an aliphatic monocyclic group, a linear alkylene group which may have an ether group (—O—) interposed between the carbon atoms can be given.

Specific examples of structural units represented by general formula (a1-0-11) include structural units represented by the aforementioned formulas (a1-1-16) to (a1-1-23), (a1-1-27) and (a1-1-31). Among these, structural units represented by general formula (a1-1-02) shown below which includes the structural units represented by the aforementioned formulas (a1-1-16), (a1-1-17), (a1-1-20) to (a1-1-23), (a1-1-27) and (a1-1-31) are preferable. Further, structural units represented by general formula (a1-1-02′) shown below are also preferable.

In the formulas, h is preferably 1 or 2.

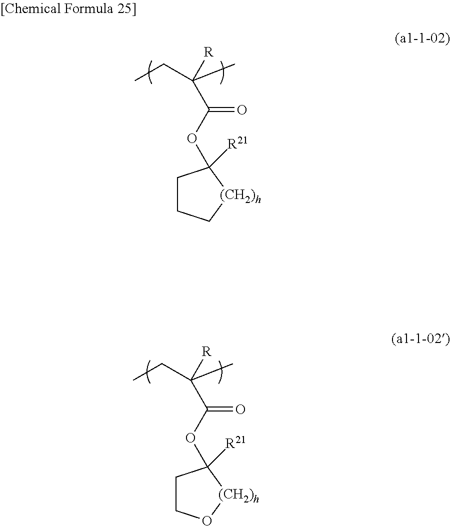

In the formulas, R and R²¹ are the same as defined above; and h represents an integer of 1 to 3.

In general formula (a1-0-12), as the branched alkyl group for R²³, the same alkyl groups as those described above for R¹⁴ in formulas (1-1) to (1-9) which are branched can be used, and an isopropyl group is particularly desirable.

As the aliphatic polycyclic group formed by R²⁴ and the carbon atoms to which this R²⁴ group is bonded, the same aliphatic cyclic groups as those described above for the aforementioned tertiary alkyl ester-type acid dissociable group and which are polycyclic group can be used.

Specific examples of structural units represented by general formula (a1-0-12) include structural units represented by the aforementioned formulas (a1-1-26) and (a1-1-28) to (a1-1-30).

As the structural unit represented by formula (a1-0-12), a structural unit in which the aliphatic polycyclic group formed by R²⁴ and the carbon atom to which this R²⁴ group is bonded is a 2-adamantyl group is preferable, and a structural unit represented by the aforementioned formula (a1-1-26) is particularly desirable.

In general formula (a1-0-13), R and R²⁴ are the same as defined above.

As the linear alkyl group for R²⁵, the same linear alkyl groups as those described above for R¹⁴ in the aforementioned formulas (1-1) to (1-9) can be mentioned, and a methyl group or an ethyl group is particularly desirable.

Specific examples of structural units represented by general formula (a1-0-13) include structural units represented by the aforementioned formulas (a1-1-1), (a1-1-2) and (a1-1-7) to (a1-1-15) which were described above as specific examples of the structural unit represented by general formula (a1-1).

As the structural unit represented by formula (a1-0-13), a structural unit in which the aliphatic polycyclic group formed by R²⁴ and the carbon atom to which this R²⁴ group is bonded is a 2-adamantyl group is preferable, and a structural unit represented by the aforementioned formula (a1-1-1) or (a1-1-2) is particularly desirable.

Examples of structural units represented by general formula (a1-0-2) include structural units represented by the aforementioned formulas (a1-3) and (a1-4), and structural units represented by formula (a1-3) are particularly desirable.

As a structural unit represented by general formula (a1-0-2), those in which Y² in the formula is a group represented by the aforementioned formula —Y²¹—O—Y²²— or —Y²¹—C(═O)—O—Y²²— is particularly desirable.

Preferable examples of such structural units include a structural unit represented by general formula (a1-3-01) shown below, a structural unit represented by general formula (a1-3-02) shown below, and a structural unit represented by general formula (a1-3-03) shown below.

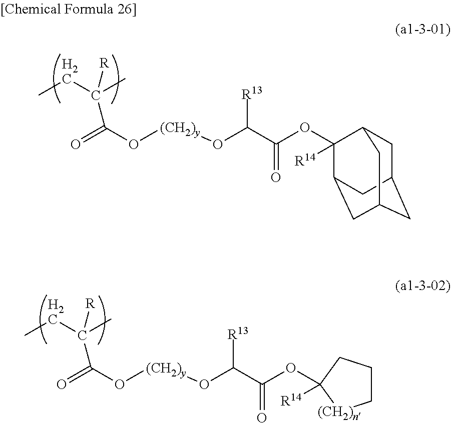

In the formulas, R is the same as defined above; R¹³ represents a hydrogen atom or a methyl group; R¹⁴ represents an alkyl group; y represents an integer of 1 to 10; and n′ represents an integer of 0 to 3.

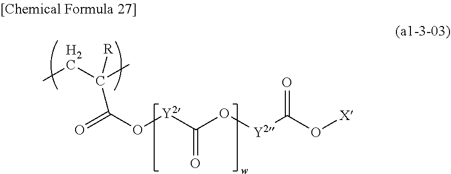

In the formula, R is the same as defined above; each of Y^{2′} and Y^{2″} independently represents a divalent linking group; X′ represents an acid dissociable group; and w represents an integer of 0 to 3.

In general formulas (a1-3-01) and (a1-3-02), R¹³ is preferably a hydrogen atom.

R¹⁴ is the same as defined for R¹⁴ in the aforementioned formulas (1-1) to (1-9).

y is preferably an integer of 1 to 8, more preferably an integer of 1 to 5, and most preferably 1 or 2.

n′ is preferably 1 or 2, and most preferably 2.

Specific examples of structural units represented by general formula (a1-3-01) include structural units represented by the aforementioned formulas (a1-3-25) and (a1-3-26).

Specific examples of structural units represented by general formula (a1-3-02) include structural units represented by the aforementioned formulas (a1-3-27) and (a1-3-28).

In general formula (a1-3-03), as the divalent linking group for Y^{2′} and Y^{2″}, the same groups as those described above for Y² in general formula (a1-3) can be used.

As Y2′, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As Y^{2″}, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As the acid dissociable group for X′, the same groups as those described above can be used. X′ is preferably a tertiary alkyl ester-type acid dissociable group, more preferably the aforementioned (i) a group which forms a tertiary carbon atom on the ring structure of a monovalent aliphatic cyclic group in which a substituent is bonded to the carbon atom to which an atom adjacent to the acid dissociable, dissolution inhibiting group is bonded. Among these, a group represented by the aforementioned general formula (1-1) is particularly desirable.

w represents an integer of 0 to 3, preferably an integer of 0 to 2, more preferably 0 or 1, and most preferably 1.

As the structural unit represented by general formula (a1-3-03), a structural unit represented by general formula (a1-3-03-1) or (a1-3-03-2) shown below is preferable, and a structural unit represented by general formula (a1-3-03-1) is particularly desirable.

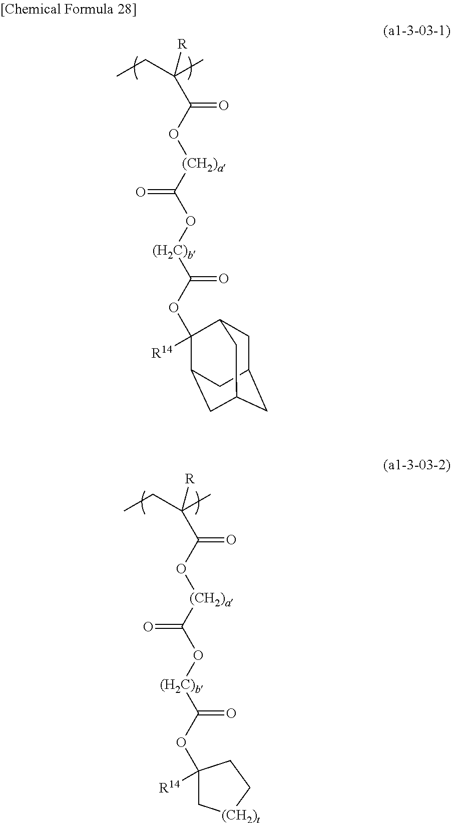

In the formulas, R and R¹⁴ are the same as defined above; a′ represents an integer of 1 to 10; b′ represents an integer of 1 to 10; and t represents an integer of 0 to 3.

In general formulas (a1-3-03-1) and (a1-3-03-2), a′ is preferably an integer of 1 to 8, more preferably an integer of 1 to 5, and most preferably 1 or 2.

b′ is preferably an integer of 1 to 8, more preferably an integer of 1 to 5, and most preferably 1 or 2.

t is preferably an integer of 1 to 3, and most preferably 1 or 2.

Specific examples of structural units represented by general formula (a1-3-03-1) or (a1-3-03-2) include structural units represented by the aforementioned formulas (a1-3-29) to (a1-3-32).

As the structural unit (a1) contained in the component (A1), one type of structural unit may be used, or two or more types may be used.

In the component (A1), the amount of the structural unit (a1) based on the combined total of all structural units constituting the component (A1) is preferably 15 to 70 mol %, more preferably 15 to 60 mol %, and still more preferably 20 to 55 mol %. When the amount of the structural unit (a1) is at least as large as the lower limit of the above-mentioned range, a pattern can be easily formed using a resist composition prepared from the component (A1), and various lithography properties such as sensitivity, resolution, LER and the like are also improved. On the other hand, when the amount of the structural unit (a1) is no more than the upper limit of the above-mentioned range, a good balance can be achieved with the other structural units.

Further, in the component (A1), the ratio (in terms of the molar ratio) between the structural unit (a0) and the structural unit (a1) (i.e., structural unit (a0): structural unit (a1)) is preferably from 1:99 to 40:60, and more preferably from 5:95 to 35:65, as the effects of the present invention are improved.

In the present invention, it is particularly desirable that in the component (A1), the amount of the structural unit (a0) be 1 to 30 mol %, and also the amount of the structural unit (a1) be 15 to 60 mol %.

[Structural Unit (a3)]

The structural unit (a3) is a structural unit represented by general formula (a3-0) shown below.

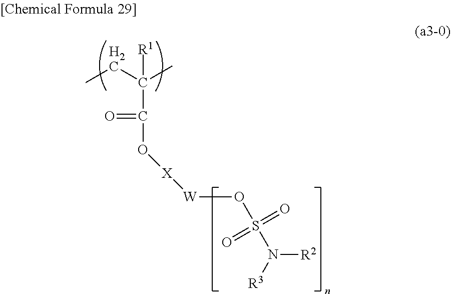

In the formula, R¹ represents a hydrogen atom, an alkyl group of 1 to 5 carbon atoms or a halogenated alkyl group of 1 to 5 carbon atoms; X represents a single bond or a divalent linking group; W represents a cyclic saturated hydrocarbon group that may include an oxygen atom at an arbitrary position; each of R² and R³ independently represents a hydrogen atom or an alkyl group that may include an oxygen atom at an arbitrary position, or R² and R³ may be mutually bonded to form a ring together with the nitrogen atom in the formula; and n represents an integer of 1 to 3.

In general formula (a3-0), as the alkyl group and the halogenated alkyl group for R¹, the same alkyl groups and the halogenated alkyl groups as those defined above for R in general formula (a1-0-1) or (a1-0-2) described in connection with the structural unit (a1) can be used.

The divalent linking group for X is not particularly limited, and preferable examples thereof include a divalent hydrocarbon group which may have a substituent and a divalent linking group containing a hetero atom. Examples of these “divalent hydrocarbon groups which may have a substituent” and “divalent linking groups containing a hetero atom” include the same divalent linking groups as those defined above for A in general formula (a0-1) or (a0-2) described in connection with the structural unit (a0).

In formula (a3-0), W represents a cyclic saturated hydrocarbon group that may include an oxygen atom at an arbitrary position. The saturated hydrocarbon group preferably has 3 to 20 carbon atoms, and more preferably 5 to 12 carbon atoms.

In terms of improvement in various lithography properties, both monocyclic groups and polycyclic groups are preferable as the saturated hydrocarbon group. In terms of raising the Tg to improve lithography properties and improving the etching resistance, a polycyclic group is preferable, and a bi-, tri- or tetra-cyclic group is more preferable.

Specific examples of the saturated hydrocarbon group include a cyclopropanediyl group, a cyclobutane-1,2-diyl group, a cyclobutane-1,3-diyl group, a cyclopentane-1,2-diyl group, a cyclopentane-1,3-diyl group, a cyclohexane-1,2-diyl group, a cyclohexane-1,3-diyl group, a cyclohexane-1,4-diyl group, a bicyclo[2.2.1]heptane-2,3-diyl group, a bicyclo[2.2.1]heptane-2,5-diyl group, a 7-oxabicyclo[2.2.1]heptane-2,5-diyl group, a bicyclo[2.2.1]heptane-2,6-diyl group, a 7-oxabicyclo[2.2.1]heptane-2,6-diyl group, an adamantane-1,3-diyl group, and an adamantane-1,2-diyl group.

In formula (a3-0), each of R² and R³ independently represents a hydrogen atom or an alkyl group that may include an oxygen atom at an arbitrary position.

The alkyl groups for R² and R³ may be linear, branched or cyclic groups.

As the linear or branched alkyl group, alkyl groups of 1 to 5 carbon atoms are preferable, and specific examples include a methyl group, an ethyl group, an n-propyl group, an i-propyl group, an n-butyl group, an i-butyl group, a t-butyl group, a 2-methyl-2-butyl group, a 3-methyl-2-butyl group, a 1-pentyl group, a 2-pentyl group and a 3-pentyl group.

Examples of the cyclic alkyl group include a cyclopropyl group, a cyclobutyl group, a cyclopentyl group, a 1-methyl-1-cyclopentyl group, a 1-ethyl-1-cyclopentyl group, a cyclohexyl group, a 1-methyl-1-cyclohexyl group, a 1-ethyl-1-cyclohexyl group, a 1-methyl-1-cycloheptyl group, a 1-ethyl-1-cycloheptyl group, a 1-methyl-1-cyclooctyl group, a 1-ethyl-1-cyclooctyl group, a bicyclo[2.2.1]heptan-2-yl group, a 1-adamantyl group, a 2-adamantyl group, a 2-methyl-2-adamantyl group, and a 2-ethyl-2-adamantyl group.

Each of the alkyl groups for R² and R³ may include an oxygen atom at an arbitrary position. The expression “include an oxygen atom” means that an oxygen atom (—O—) is introduced into the carbon chain of the alkyl group.

The alkyl group for R² and R³ may have a substituent (an atom or group other than a hydrogen atom) for substituting the hydrogen atoms within this alkyl group. Examples of the substituent include a fluorine atom, a fluorinated lower alkyl group of 1 to 5 carbon atoms, and an oxygen atom (═O). Further, when this alkyl group is a linear or branched alkyl group, the alkyl group may have a cyclic alkyl group as a substituent. Furthermore, when this alkyl group is a cyclic alkyl group, the alkyl group may have a linear or branched alkyl group as a substituent.

The R² and R³ groups may be mutually bonded to form a ring together with the nitrogen atom in the formula.

This ring may be either a monocyclic ring or a polycyclic ring, and a monocyclic ring is preferred.

Such a ring including the nitrogen atom is preferably a 3- to 10-membered ring, and most preferably a 5- to 7-membered ring.

Specific examples of the ring to be formed include those in which a —CH₂— group constituting the ring skeleton of the saturated hydrocarbon ring has been substituted with a —NH— group, and also a hydrogen atom has been removed from this —NH— group. The saturated hydrocarbon ring preferably has 3 to 20 carbon atoms, and more preferably 3 to 12 carbon atoms. Specific examples of the saturated hydrocarbon ring include a monocycloalkane such as cyclopropane, cyclobutane, cyclopentane or cyclohexane; and a polycycloalkane such as adamantane, norbornane, isobornane, tricyclodecane or tetracyclododecane.

Such a ring may include another hetero atom as an atom to constitute the ring skeleton, in addition to the nitrogen atom to which R² and R³ are bonded. Examples of the hetero atom include a sulfur atom, an oxygen atom and a nitrogen atom.

In the present invention, it is preferable that at least one of R² and R³ represent a hydrogen atom, and it is more preferable that both R² and R³ represent a hydrogen atom, or one of R² and R³ represent a hydrogen atom and the other represent an alkyl group which may contain an oxygen atom at an arbitrary position thereof. It is particularly desirable that both R² and R³ represent a hydrogen atom.

Specific examples of preferred structural units (a3) include structural units represented by formulas (a3-20-10) to (a3-20-41) shown below. Further, these structural units in which —NH₂ has been replaced with —NH—CH₃ are also preferred.

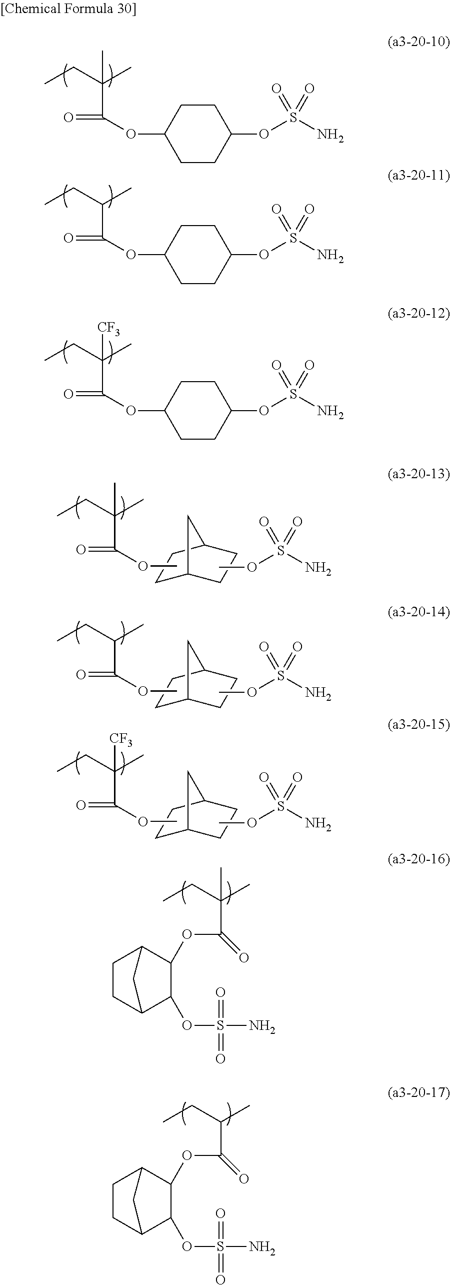

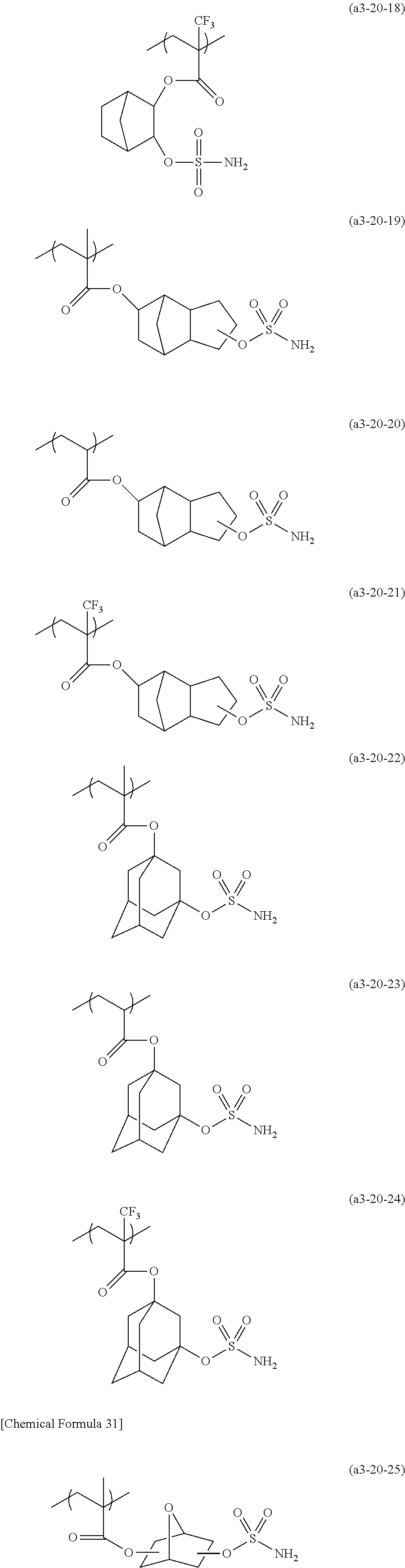

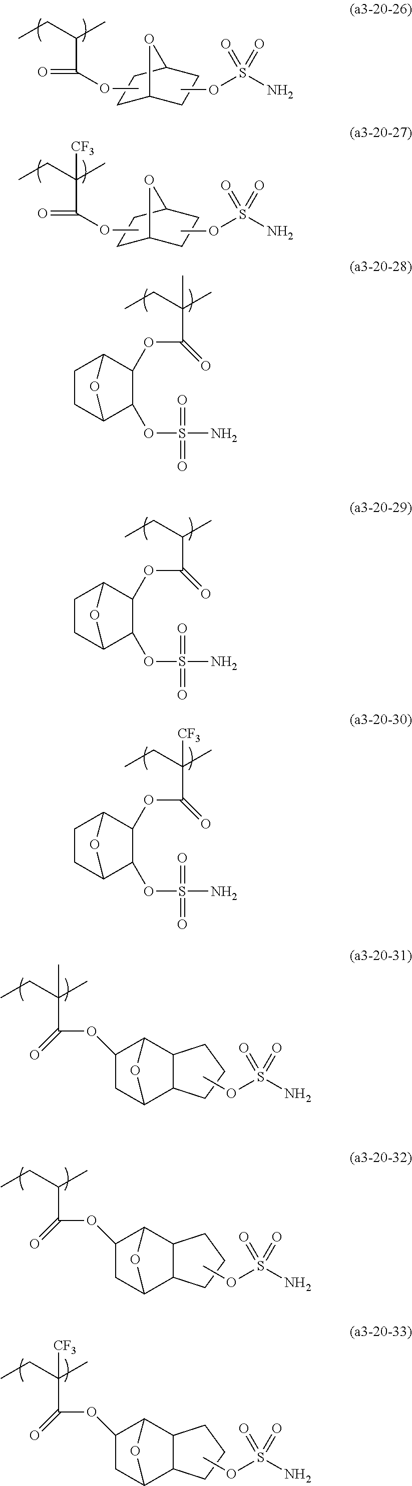

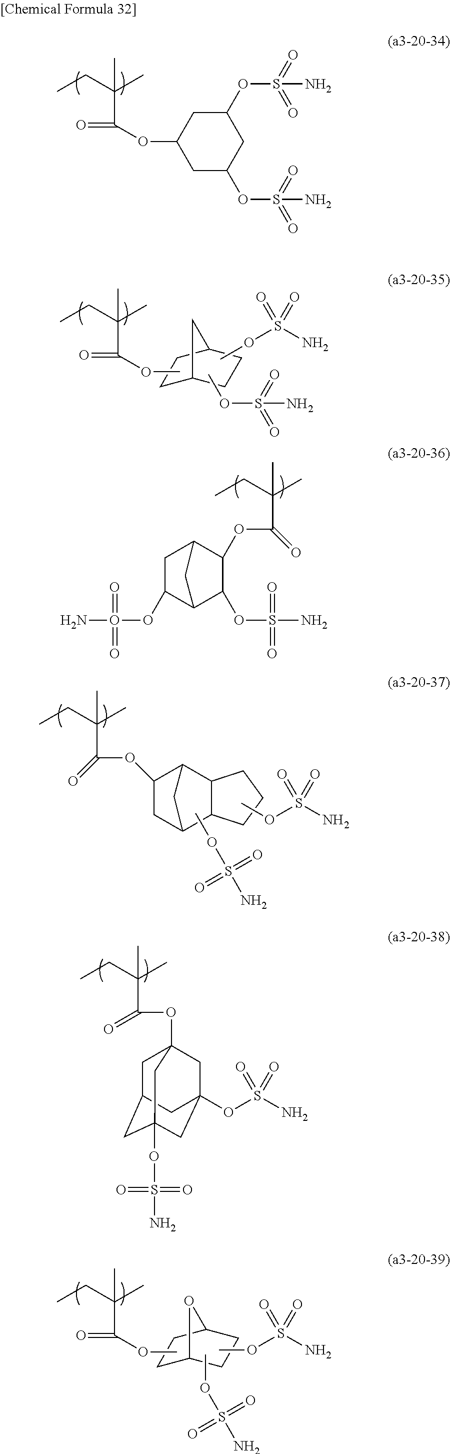

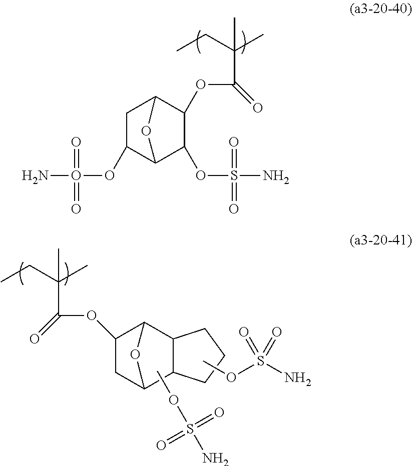

As the structural unit (a3) contained in the component (A1), one type of structural unit may be used, or two or more types may be used.

In the component (A1), the amount of the structural unit (a3) based on the combined total of all structural units constituting the component (A1) is preferably 1 to 40 mol %, more preferably 2 to 30 mol %, and still more preferably 3 to 20 mol %. When the amount of the structural unit (a3) is 1 mol % or more, the heat resistance improves, whereas the amount of 40 mol % or less improves various lithography properties.

Further, in the component (A1), the ratio (in terms of the molar ratio) between the structural unit (a0) and the structural unit (a3) (i.e., structural unit (a0): structural unit (a3)) is preferably from 30:70 to 80:20, and more preferably from 40:60 to 70:30, as the effects of the present invention are improved.

[Structural Unit (a2)]

It is preferable that the component (A1) further include at least one type of structural unit (a2) selected from the group consisting of structural units (hereafter, referred to as “structural unit (a2^{S})”) derived from an (α-substituted) acrylate ester containing a —SO₂-containing cyclic group and structural units (hereafter, referred to as “structural unit (a2^{L})”) derived from an (α-substituted) acrylate ester containing a lactone-containing cyclic group, in addition to the structural units (a0), (a1) and (a3).

When the component (A1) is used for forming a resist film, the —SO₂-containing cyclic group or lactone-containing cyclic group of the structural unit (a2) is effective in improving the adhesion between the resist film and the substrate. Further, it is also effective in the alkali developing process in terms of improving the compatibility with developing solutions containing water, such as alkali developing solutions.

In those cases where the aforementioned structural unit (a0), (a1) or (a3) includes a —SO₂-containing cyclic group or lactone-containing cyclic group within the structure thereof, this structural unit would also meet the definition for the structural unit (a2). However, it is defined so that such structural units correspond to the structural unit (a0), (a1) or (a3) and do not correspond to the structural unit (a2).

Structural Unit (a2^{S}):

The structural unit (a2^{S}) is a structural unit derived from an (α-substituted) acrylate ester containing a —SO₂-containing cyclic group.

As described above, a —SO₂-containing cyclic group refers to a cyclic group including a ring that contains —SO₂— within the ring skeleton thereof, and more specifically, a cyclic group in which the sulfur atom (S) within —SO₂— forms a part of the ring skeleton of the cyclic group. This ring that contains —SO₂— within the ring skeleton thereof is counted as the first ring. A cyclic group in which the only ring structure is this ring is referred to as a monocyclic group, and a group containing other ring structures is described as a polycyclic group regardless of the structure of the other rings. The —SO₂-containing cyclic group may be either a monocyclic group or a polycyclic group.

As the —SO₂-containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

The —SO₂-containing cyclic group preferably has 3 to 30 carbon atoms, more preferably 4 to 20 carbon atoms, still more preferably 4 to 15 carbon atoms, and most preferably 4 to 12 carbon atoms. Herein, the number of carbon atoms refers to the number of carbon atoms constituting the ring skeleton, excluding the number of carbon atoms within a substituent.

The —SO₂-containing cyclic group may be either a —SO₂-containing aliphatic cyclic group or a —SO₂-containing aromatic cyclic group. A —SO₂-containing aliphatic cyclic group is preferable.

Examples of the —SO₂-containing aliphatic cyclic group include aliphatic cyclic groups in which part of the carbon atoms constituting the ring skeleton thereof has been substituted with a —SO₂— group or a —O—SO₂— group and has at least one hydrogen atom removed from the aliphatic hydrocarbon ring. Specific examples include an aliphatic hydrocarbon ring in which a —CH₂— group constituting the ring skeleton thereof has been substituted with a —SO₂— group and has at least one hydrogen atom removed therefrom; and an aliphatic hydrocarbon ring in which a —CH₂—CH₂— group constituting the ring skeleton thereof has been substituted with a —O—SO₂— group and has at least one hydrogen atom removed therefrom.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic alicyclic hydrocarbon group, a group in which two hydrogen atoms have been removed from a monocycloalkane of 3 to 6 carbon atoms is preferable. Examples of the monocycloalkane include cyclopentane and cyclohexane. As the polycyclic alicyclic hydrocarbon group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The —SO₂-containing cyclic group may have a substituent. Examples of the substituent include an alkyl group, an alkoxy group, a halogen atom, a hydroxyl group, an oxygen atom (═O), a halogenated alkyl group, a halogenated alkoxy group, a hydroxyalkyl group, —C(═O)—R⁸⁰ [R⁸⁰ represents an alkyl group], —COOR⁸¹ [R⁸¹ represents a hydrogen atom or an alkyl group], —OC(═O)R⁸¹ [R⁸¹ represents a hydrogen atom or an alkyl group], a cyano group, an amino group, an amide group, a nitro group, a sulfur atom and a sulfonyl group (SO₂).

The alkyl group for the substituent may be a linear, branched or cyclic group, or may be a combination of these groups. The number of carbon atoms thereof is preferably 1 to 30.

When the alkyl group is linear or branched, the number of carbon atoms thereof is preferably 1 to 20, more preferably 1 to 17, still more preferably 1 to 15, and most preferably 1 to 10. More specifically, the same linear or branched saturated hydrocarbon groups as those described later as specific examples of aliphatic hydrocarbon groups can be used. Of these, alkyl groups of 1 to 6 carbon atoms are preferred, and specific examples thereof include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or ethyl group is preferable, and a methyl group is particularly desirable.

When the alkyl group is cyclic (i.e., a cycloalkyl group), the number of carbon atoms is preferably 3 to 30, more preferably 3 to 20, still more preferably 3 to 15, still more preferably 4 to 12, and most preferably 5 to 10. The alkyl group may be either a monocyclic group or a polycyclic group. Examples thereof include groups in which one or more of the hydrogen atoms have been removed from a monocycloalkane; and groups in which one or more of the hydrogen atoms have been removed from a polycycloalkane such as a bicycloalkane, a tricycloalkane, or a tetracycloalkane. Specific examples of the monocycloalkane include cyclopentane and cyclohexane. Further, specific examples of the polycycloalkane include adamantane, norbornane, isobornane, tricyclodecane and tetracyclododecane. These cycloalkyl groups may or may not have part or all of the hydrogen atoms bonded to the ring substituted with a substituent such as a fluorine atom or a fluorinated alkyl group.

Examples of the alkoxy group for the substituent include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

As examples of the halogenated alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

As examples of the halogenated alkoxy group for the substituent, groups in which part or all of the hydrogen atoms of the aforementioned alkoxy groups for the substituent have been substituted with the aforementioned halogen atoms can be given. As the halogenated alkoxy group, a fluorinated alkoxy group is preferable.

As examples of the hydroxyalkyl group for the substituent, groups in which at least one of the hydrogen atoms of the aforementioned alkyl groups for the substituent has been substituted with a hydroxyl group can be given. The number of hydroxyl groups within the hydroxyalkyl group is preferably 1 to 3, and most preferably 1.

With respect to the aforementioned —C(═O)—R⁸⁰, —COOR⁸¹ and —OC(═O)R⁸¹ for the substituent, as the alkyl groups for R⁸⁰ and R⁸¹, the same alkyl groups as those listed above as the alkyl groups for the substituent can be used.

Of the various possibilities described above, as the substituent within the —SO₂-containing cyclic group, an alkyl group, an alkoxy group, a halogen atom, a hydroxyl group, an oxygen atom (═O), a halogenated alkyl group, a hydroxyalkyl group, —COOR⁸¹, —OC(═O)R⁸¹, a cyano group or the like is preferred.

More specific examples of the —SO₂-containing cyclic group include groups represented by general formulas (3-1) to (3-4) shown below.

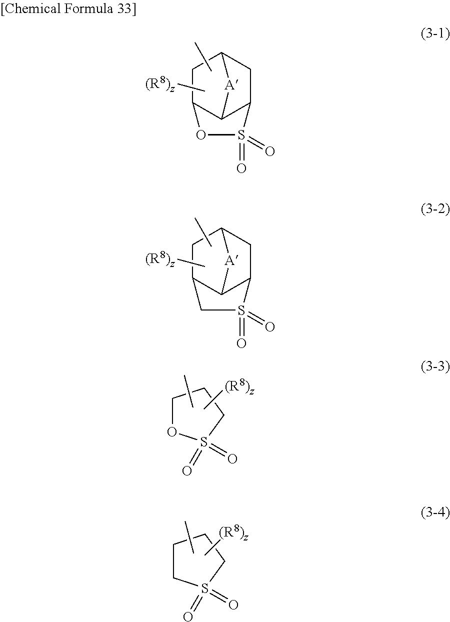

In the formulas, A′ represents an oxygen atom, a sulfur atom or an alkylene group of 1 to 5 carbon atoms which may contain an oxygen atom or a sulfur atom; z represents an integer of 0 to 2; and R⁸ represents an alkyl group, an alkoxy group, a halogen atom, a hydroxyl group, an oxygen atom (═O), a halogenated alkyl group, a hydroxyalkyl group, —COOR⁸¹, —OC(═O)R⁸¹ or a cyano group, wherein R⁸¹ represents a hydrogen atom or an alkyl group.

In general formulas (3-1) to (3-4) above, A′ represents an oxygen atom (—O—), a sulfur atom (—S—) or an alkylene group of 1 to 5 carbon atoms which may contain an oxygen atom or a sulfur atom.

As the alkylene group of 1 to 5 carbon atoms represented by A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include —O—CH₂—, —CH₂—O—CH₂—, —S—CH₂—, —CH₂—S—CH₂—.

A′ is preferably an alkylene group of 1 to 5 carbon atoms or —O—, is more preferably an alkylene group of 1 to 5 carbon atoms, and is most preferably a methylene group.

z represents an integer of 0 to 2, and is most preferably 0.

When z is 2, the plurality of R⁸ may be the same or different from each other.

As the alkyl group, alkoxy group, halogen atom, halogenated alkyl group, hydroxyalkyl group, —COOR⁸¹ and —OC(═O)R⁸¹ for R⁸, the same alkyl groups, alkoxy groups, halogenated alkyl groups, —COOR⁸¹, —OC(═O)R⁸¹ and hydroxyalkyl groups as those described above as the substituent which the —SO₂-containing cyclic group may have can be used.

Specific examples of the cyclic groups represented by general formulas (3-1) to (3-4) are shown below. In each of the following formulas, “Ac” represents an acetyl group.

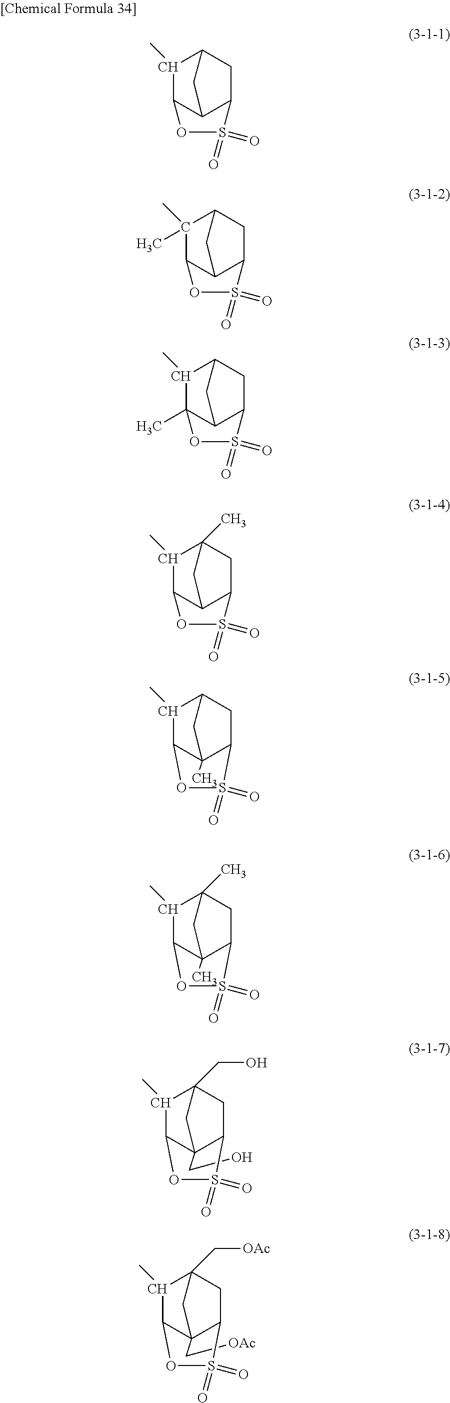

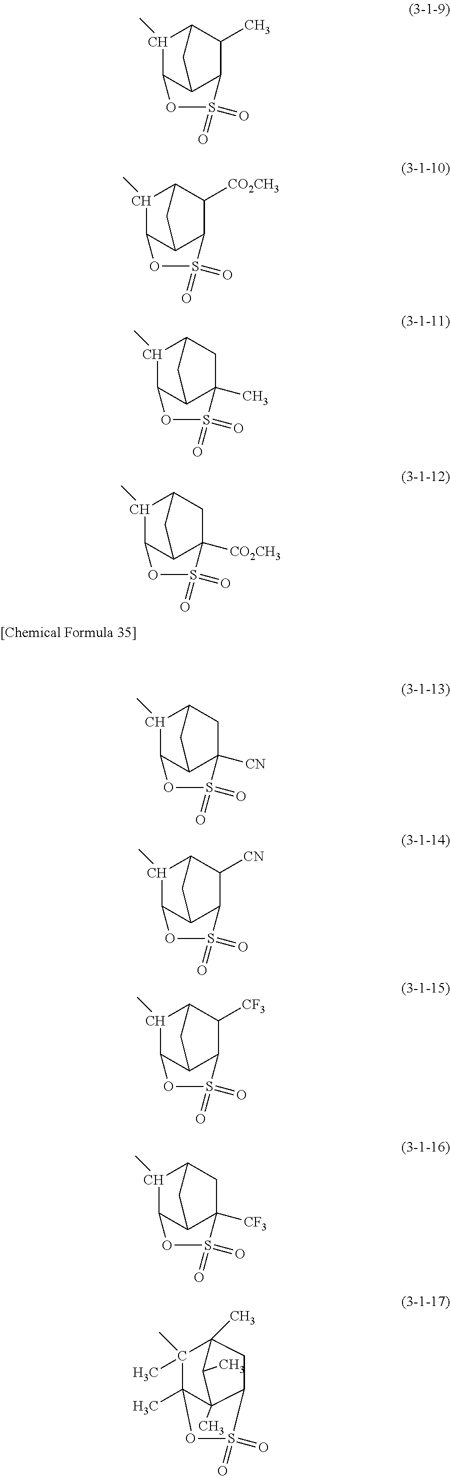

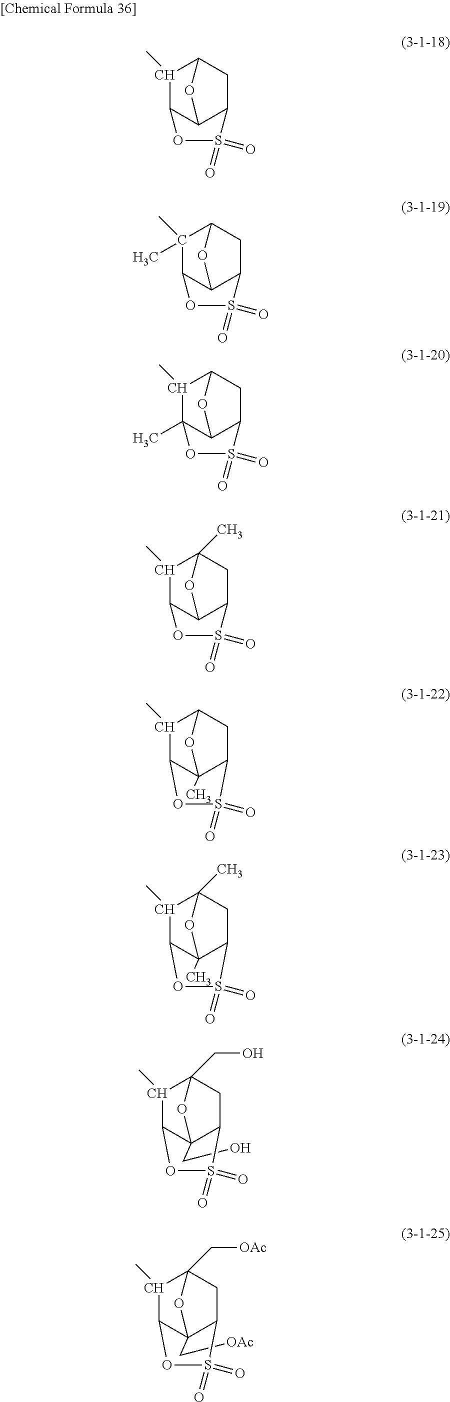

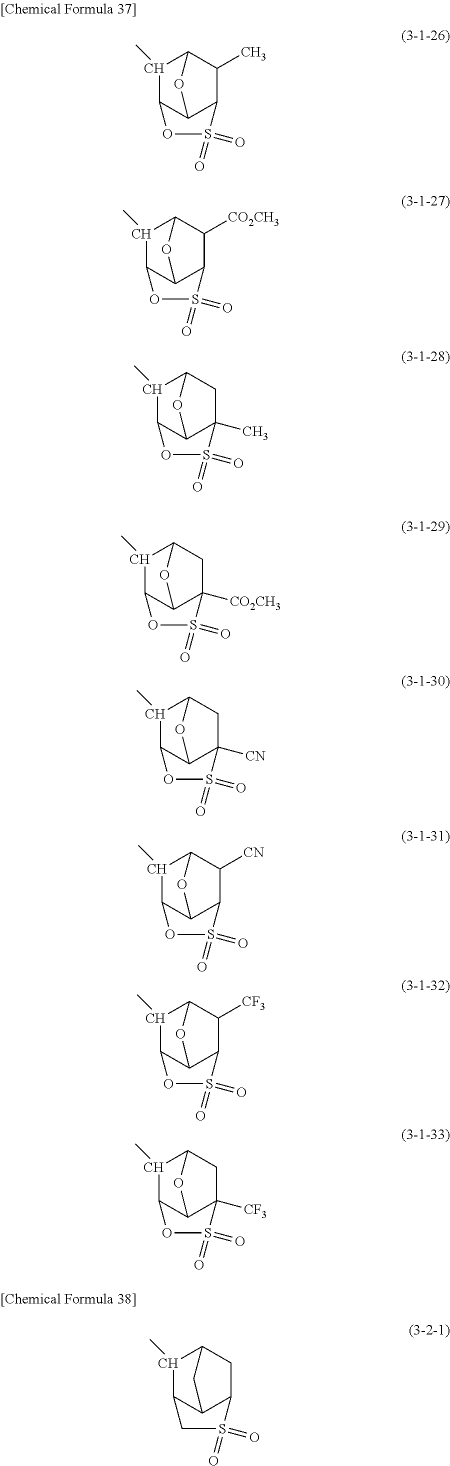

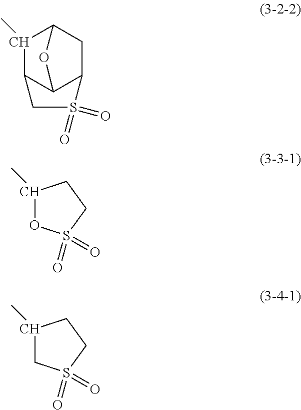

Of the various possibilities, as the —SO₂-containing cyclic group, a group represented by the aforementioned general formula (3-1) is preferable, at least one member selected from the group consisting of groups represented by the aforementioned chemical formulas (3-1-1), (3-1-18), (3-3-1) and (3-4-1) is more preferable, and a group represented by the aforementioned chemical formula (3-1-1) is most preferable.

More specific examples of the structural unit (a2^{S}) include structural units represented by general formula (a2-6) shown below.

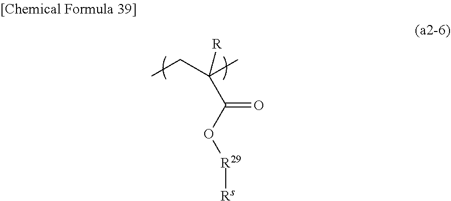

In the formula, R represents a hydrogen atom, an alkyl group of 1 to 5 carbon atoms or a halogenated alkyl group of 1 to 5 carbon atoms; R^{S} represents a —SO₂-containing cyclic group; and R²⁹ represents a single bond or a divalent linking group.

In genera formula (a2-6), R is the same as defined above for R in general formula (a1-0-1) or (a1-0-2) described in connection with the structural unit (a1).

R^{S} is the same as defined for the aforementioned —SO₂-containing group.

R²⁹ may be either a single bond or a divalent linking group. In terms of the effects of the present invention, a divalent linking group is preferable.

The divalent linking group for R²⁹ is not particularly limited. For example, the same divalent linking groups as those described for Y² in general formula (a1-0-2) explained above in relation to the structural unit (a1) can be mentioned.

As the divalent linking group for R²⁹, an alkylene group or a divalent linking group containing an ester bond (—C(═O)—O—) is preferable.

As the alkylene group, a linear or branched alkylene group is preferable. Specific examples include the same linear alkylene groups and branched alkylene groups as those described above for the aliphatic hydrocarbon group represented by Y².

As the divalent linking group containing an ester bond, a group represented by general formula: -L⁴-C(═O)—O— (in the formula, L⁴ represents a divalent linking group) is particularly desirable. That is, the structural unit (a2^{S}) is preferably a structural unit represented by general formula (a2-6-1) shown below.

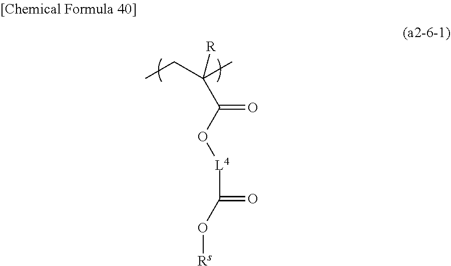

In the formula, R and R^{S} are the same as defined above; and L⁴ represents a divalent linking group.

L⁴ is not particularly limited. For example, the same divalent linking groups as those described for Y² in general formula (a1-0-2) explained above in relation to the structural unit (a1) can be mentioned.

As the divalent linking group for L⁴, a linear or branched alkylene group, a divalent alicyclic hydrocarbon group or a divalent linking group containing a hetero atom is preferable.

As the linear or branched alkylene group, the divalent alicyclic hydrocarbon group and the divalent linking group containing a hetero atom, the same linear or branched alkylene group, divalent alicyclic hydrocarbon group and divalent linking group containing a hetero atom as those described above as preferable examples of Y² can be mentioned.

Among these, a linear or branched alkylene group, or a divalent linking group containing an oxygen atom as a hetero atom is more preferable.

The linear or branched alkylene group for L⁴ preferably has 1 to 10 carbon atoms, more preferably 1 to 8 carbon atoms, and still more preferably 1 to 5 carbon atoms. As the linear alkylene group, a methylene group or an ethylene group is preferable, and a methylene group is particularly desirable. As the branched alkylene group, an alkylmethylene group or an alkylethylene group is preferable, and —CH(CH₃)—, —C(CH₃)₂— or —C(CH₃)₂CH₂— is particularly desirable.

As the divalent linking group containing an oxygen atom, a divalent linking group containing an ether bond or an ester bond is preferable, and a group represented by the general formula —Y²¹—O—Y²²—, —Y²¹—O—C(═O)—Y²²— or —[Y²¹—C(═O)—O]_{m′}—Y²²— described above for Y² in general formula (a1-0-2) is more preferable. Among these, a group represented by the formula —[Y²¹—C(═O)—O]_{m′}—Y²²— is preferable, and a group represented by the formula: —(CH₂)_{c}—C(═O)—O—(CH₂)_{d}— is particularly desirable. c represents an integer of 1 to 5, and preferably 1 or 2. d represents an integer of 1 to 5, and preferably 1 or 2.

In particular, as the structural unit (a2^{S}), a structural unit represented by general formula (a2-6-11) or (a2-6-12) shown below is preferable, and a structural unit represented by general formula (a2-6-12) shown below is more preferable.

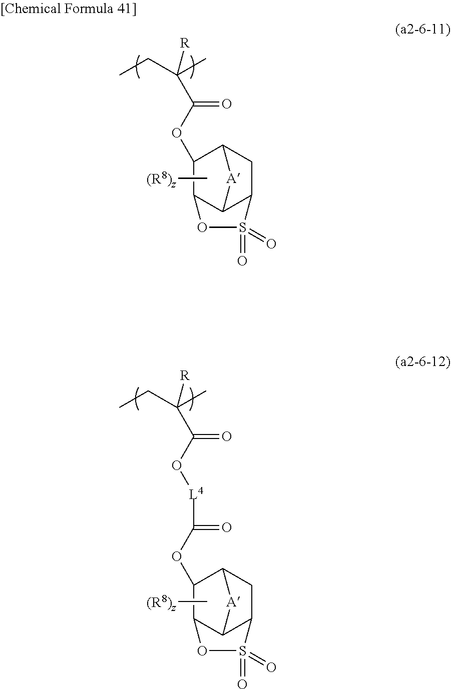

In the formulas, R, A′, R⁸, z and L⁴ are the same as defined above.

In general formula (a2-6-11), A′ is preferably a methylene group, an oxygen atom (—O—) or a sulfur atom (—S—).

As L⁴, a linear or branched alkylene group or a divalent linking group containing an oxygen atom is preferable. As the linear or branched alkylene group and the divalent linking group containing an oxygen atom represented by L⁴, the same linear or branched alkylene groups and the divalent linking groups containing an oxygen atom as those described above can be mentioned.

As the structural unit represented by general formula (a2-6-12), a structural unit represented by general formula (a2-6-12a) or (a2-6-12b) shown below is particularly desirable.

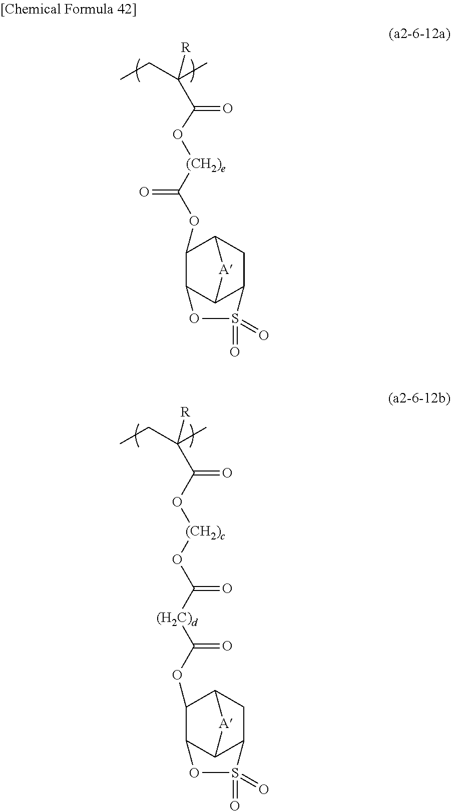

In the formulas, R and A′ are the same as defined above; and each of c to e independently represents an integer of 1 to 3.

Structural Unit (a2^{L}):

The structural unit (a2^{L}) is a structural unit derived from an (α-substituted) acrylate ester containing a lactone-containing cyclic group.

As described above, the term “lactone-containing cyclic group” refers to a cyclic group including one ring containing a —O—C(O)— structure (lactone ring). This “lactone ring” is counted as the first ring, so that a lactone-containing cyclic group in which the only ring structure is the lactone ring is referred to as a monocyclic group, and groups that also contain other ring structures are described as polycyclic groups regardless of the structure of the other rings.

The lactone-containing cyclic group for the structural unit (a2^{L}) is not particularly limited, and an arbitrary group may be used. Specific examples of lactone-containing monocyclic groups include a group in which one hydrogen atom has been removed from a 4- to 6-membered lactone ring, such as a group in which one hydrogen atom has been removed from β-propiolactone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

The lactone-containing cyclic group may have a substituent. Examples of the substituent include an alkyl group, an alkoxy group, a halogen atom, a hydroxyl group, an oxygen atom (═O), a halogenated alkyl group, a halogenated alkoxy group, a hydroxyalkyl group, —C(═O)—R⁸⁰ [R⁸⁰ represents an alkyl group], —COOR⁸¹ [R⁸¹ represents a hydrogen atom or an alkyl group], —OC(═O)R⁸¹ [R⁸¹ represents a hydrogen atom or an alkyl group], a cyano group, an amino group, an amide group, a nitro group, a sulfur atom and a sulfonyl group (SO₂).

Of these, as the alkyl group, alkoxy group, halogen atom, halogenated alkyl group, halogenated alkoxy group, hydroxyalkyl group, —C(═O)—R⁸⁰, —COOR⁸¹ and —OC(═O)R⁸¹, the same groups as those described above as the substituent which the —SO₂-containing cyclic group may have can be used.

As the substituent included within the lactone-containing cyclic group, an alkyl group of 1 to 5 carbon atoms, an alkoxy group of 1 to 5 carbon atoms or —COOR″ [R″ represents a hydrogen atom or an alkyl group] is particularly desirable. As the alkyl group, alkoxy group and —COOR″, the same alkyl groups, alkoxy groups and —COOR″ groups as those described above for R′ in general formulas (a2-1) to (a2-5) shown below can be used.

Examples of the structural unit (a2^{L}) include structural units represented by the aforementioned general formula (a2-6) in which the R^{S} group has been substituted with a lactone-containing cyclic group. Specific examples thereof include structural units represented by general formulas (a2-1) to (a2-5) shown below.

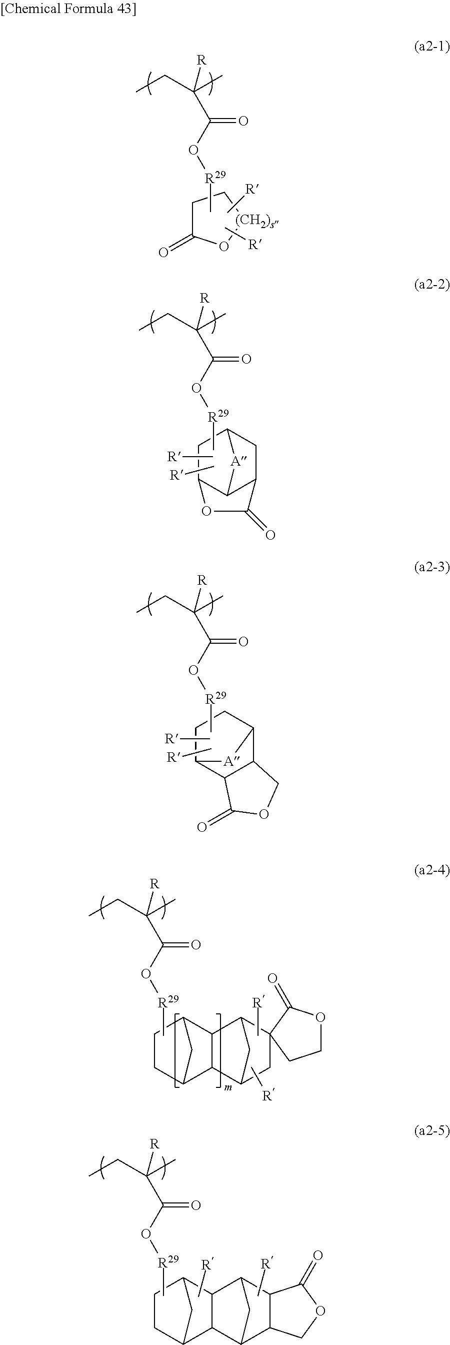

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, an alkoxy group of 1 to 5 carbon atoms or —COOR″ [R″ represents a hydrogen atom or an alkyl group]; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

In genera formulas (a2-1) to (a2-5), R is the same as defined above for R in general formula (a1-0-1) or (a1-0-2) described in connection with the structural unit (a1).

Examples of the alkyl group of 1 to 5 carbon atoms for R′ include a methyl group, an ethyl group, a propyl group, an n-butyl group and a tert-butyl group.

Examples of the alkoxy group of 1 to 5 carbon atoms for R′ include a methoxy group, an ethoxy group, an n-propoxy group, an iso-propoxy group, an n-butoxy group and a tert-butoxy group.

In terms of industrial availability, R′ is preferably a hydrogen atom.

The alkyl group for R″ may be any of linear, branched or cyclic.

In those cases where R″ represents a linear or branched alkyl group, the alkyl group preferably has 1 to 10 carbon atoms, and more preferably 1 to 5 carbon atoms.

In those cases where R″ represents a cyclic alkyl group, the cyclic alkyl group preferably has 3 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

A″ is preferably an alkylene group of 1 to 5 carbon atoms, an oxygen atom (—O—) or a sulfur atom (—S—), and more preferably an alkylene group of 1 to 5 carbon atoms or —O—. As the alkylene group of 1 to 5 carbon atoms, a methylene group or a dimethylmethylene group is more preferable, and a methylene group is particularly desirable.

R²⁹ is the same as defined for R²⁹ in the aforementioned general formula (a2-6).

In formula (a2-1), s″ is preferably 1 or 2.

Specific examples of structural units represented by general formulas (a2-1) to (a2-5) are shown below. In each of the following formulas, R^{a} represents a hydrogen atom, a methyl group or a trifluoromethyl group.

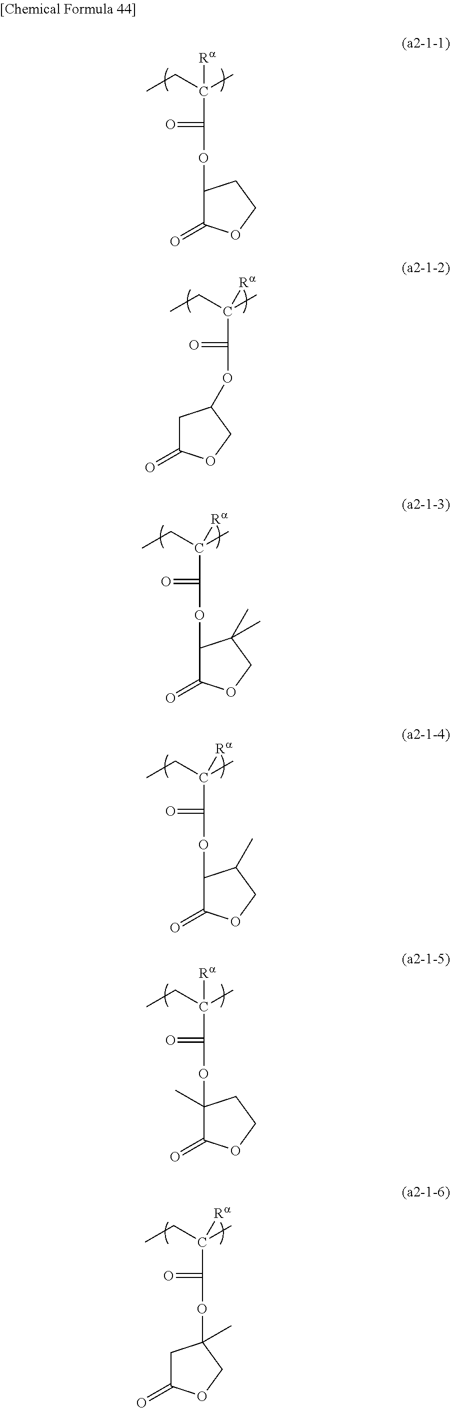

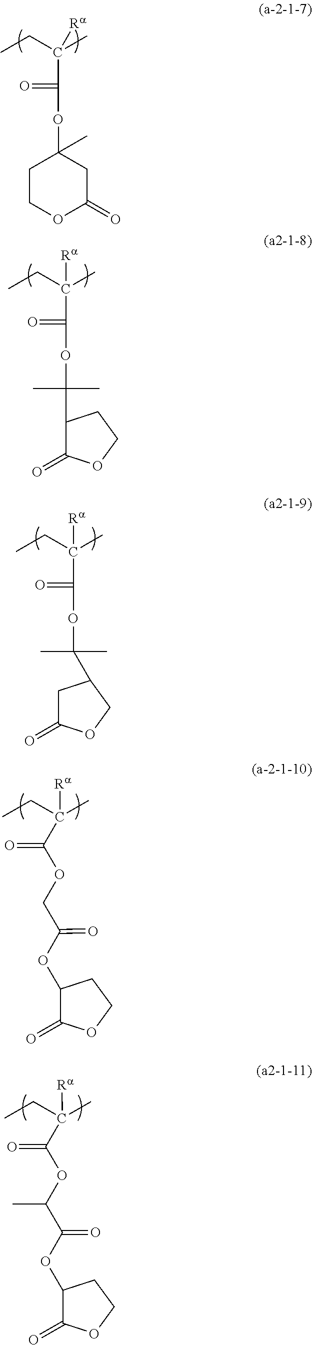

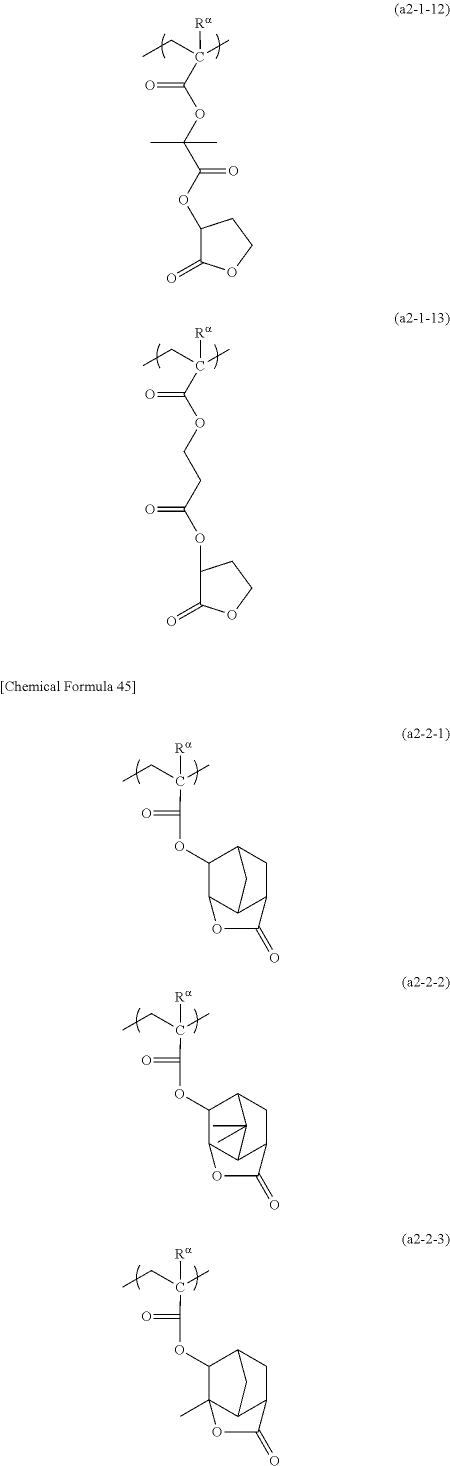

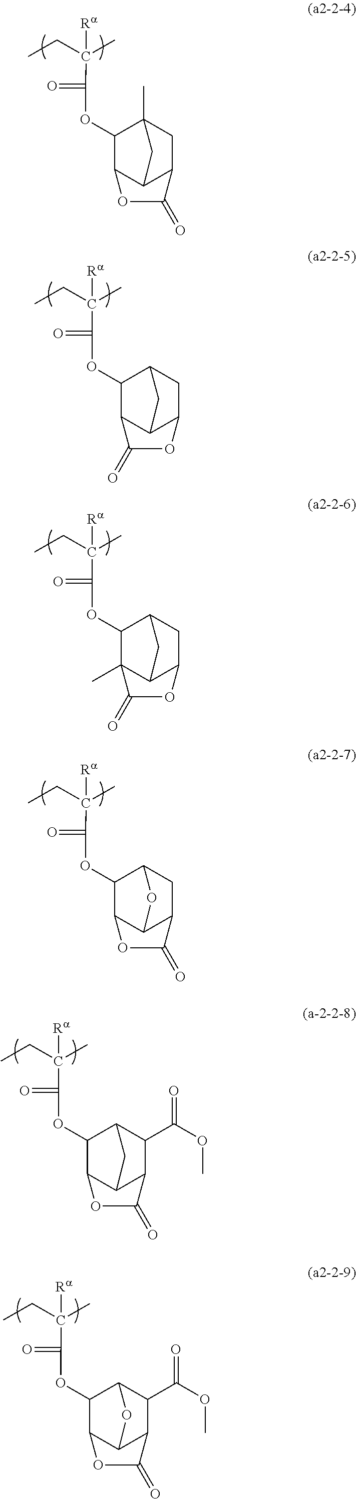

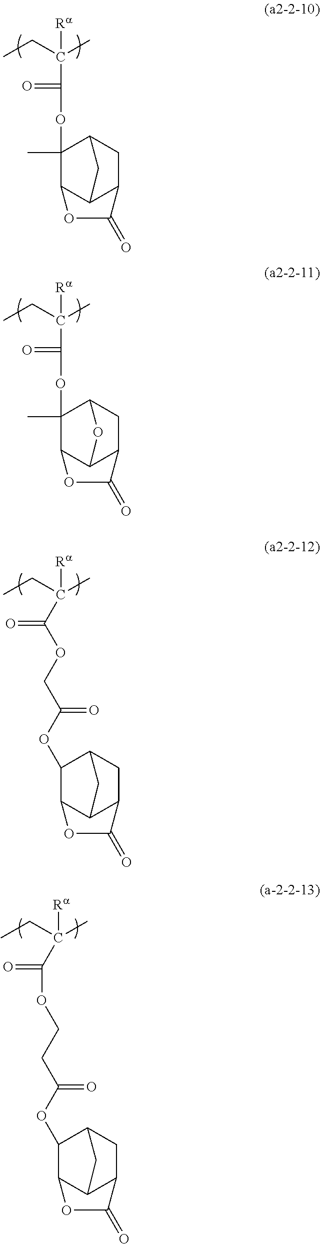

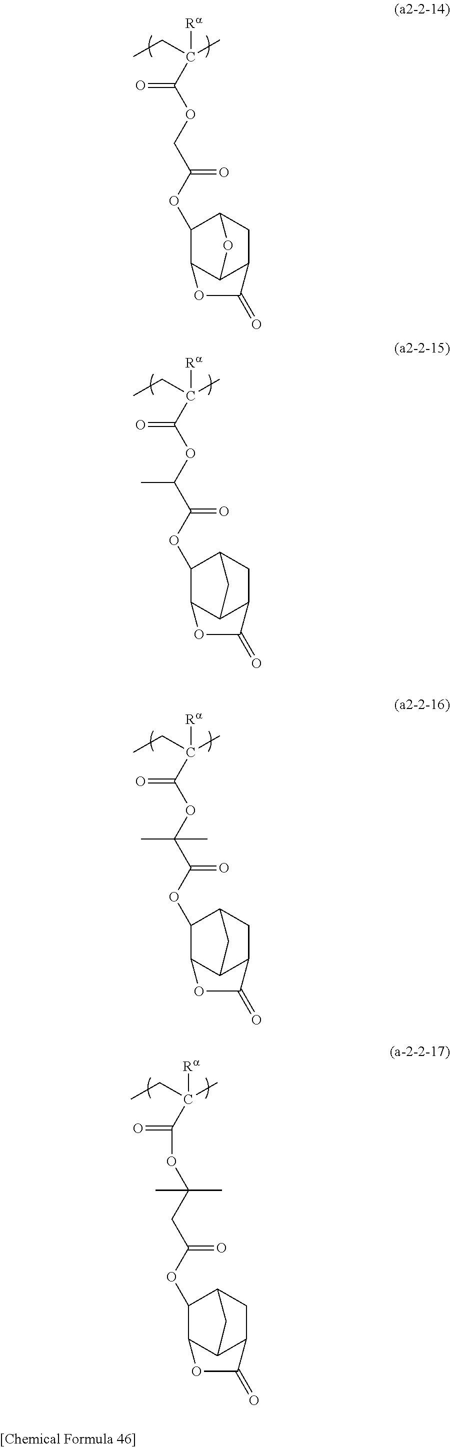

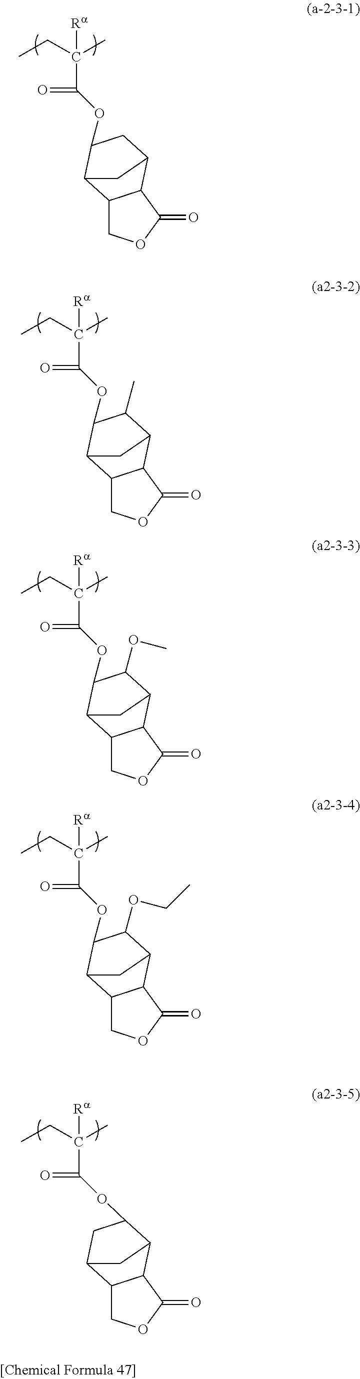

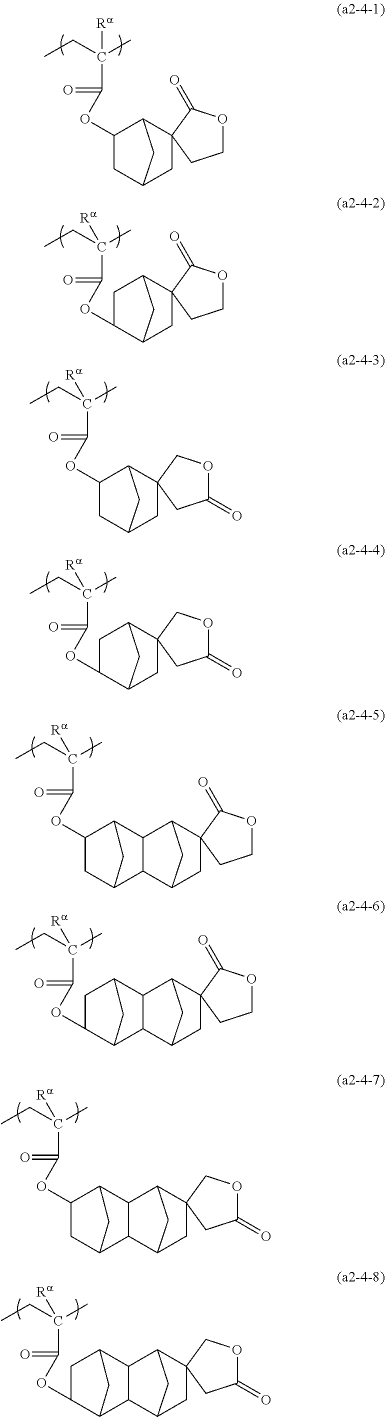

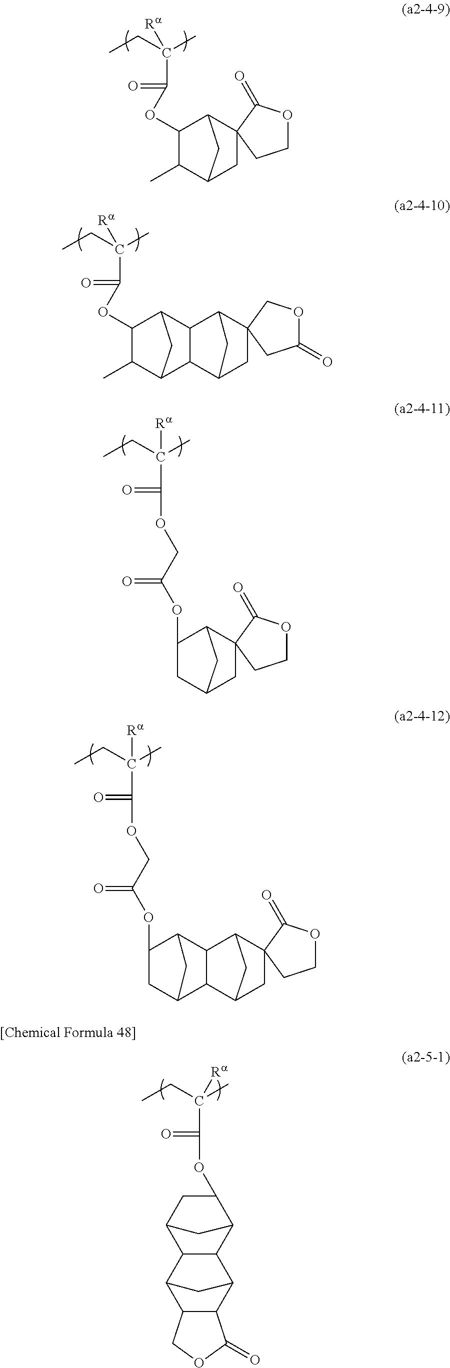

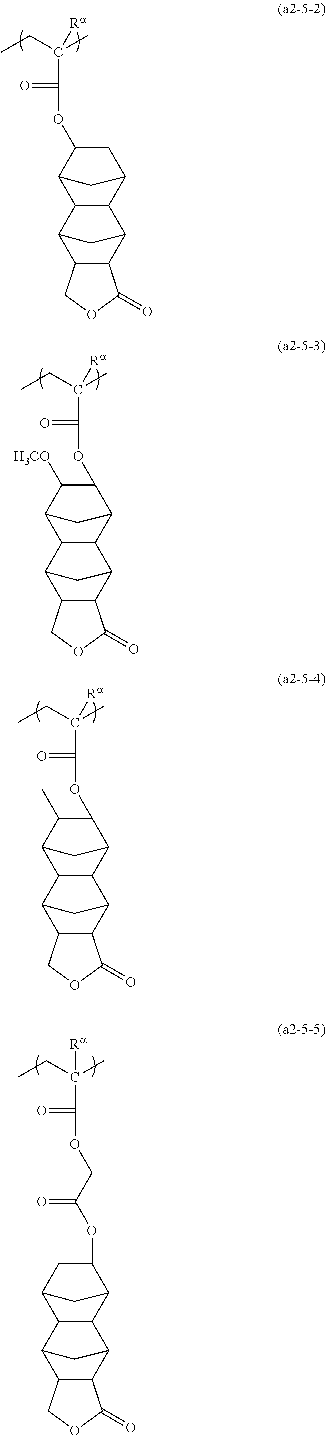

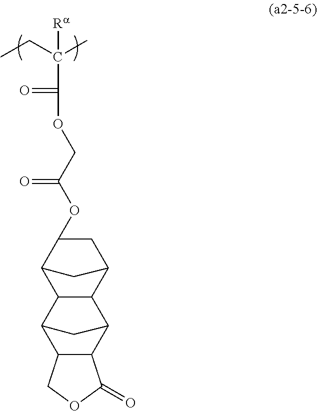

As the structural unit (a2) contained in the component (A1), one type of structural unit may be used, or two or more types may be used. For example, as the structural unit (a2), a structural unit (a2^{S}) may be used alone, or a structural unit (a2^{L}) may be used alone, or a combination of these structural units may be used. Further, as the structural unit (a2^{S}) or the structural unit (a2^{L}), either a single type of structural unit may be used, or two or more types may be used in combination.

As the structural unit (a2), at least one structural unit selected from the group consisting of structural units represented by the above general formulas (a2-1) to (a2-6) is preferable, and at least one structural unit selected from the group consisting of structural units represented by general formulas (a2-1) to (a2-3) and (a2-6) is more preferable. Of these, it is particularly preferable to use at least one structural unit selected from the group consisting of the structural units represented by chemical formulas (a2-1-1), (a2-2-1), (a2-2-7), (a2-3-1), (a2-3-5) and (a2-6-1).

In the component (A1), the amount of the structural unit (a2) based on the combined total of all structural units constituting the component (A1) is preferably 5 to 60 mol %, more preferably 10 to 50 mol %, and still more preferably 20 to 50 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units.

[Structural Unit (a3′)]

The component (A1) may also include at least one type of structural unit (hereafter, referred to as “structural unit (a3′)”) selected from structural units derived from an (α-substituted) acrylate ester having a polar group-containing aliphatic hydrocarbon group and structural units derived from an (α-substituted) acrylate ester having a polar group-containing aromatic hydrocarbon group which are not included within the definition of the aforementioned structural unit (a3), as long as the effects of the present invention are not impaired. By including the structural unit (a3′) within the component (A1), the polarity of the component (A1) following exposure is further improved. The polarity increase contributes to favorable improvements in the resolution and the like, especially in the case of alkali developing process.

Preferred examples of polar group in the structural unit (a3′) include a hydroxyl group, a cyano group, a carboxyl group, a hydroxyalkyl group and a fluorinated alcohol group (namely, a hydroxyalkyl group in which some or all of the hydrogen atoms bonded to the carbon atoms have been substituted with fluorine atoms). The carbon chains within the hydroxyalkyl group and fluorinated alcohol group may be linear, branched or cyclic, or may be a combination thereof. The number of carbon atoms within the carbon chains is preferably 1 to 10.

Among the above-mentioned examples, as the polar group, a hydroxyl group is preferred.

In the structural unit (a3′), the number of polar groups bonded to the aliphatic hydrocarbon group is not particularly limited, although 1 to 3 groups is preferable, and 1 group is particularly desirable.

The aliphatic hydrocarbon group to which the polar group is bonded may be either saturated or unsaturated, but is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 12 carbon atoms, more preferably 1 to 10 carbon atoms, still more preferably 1 to 8 carbon atoms, and still more preferably 1 to 6 carbon atoms.

The linear or branched aliphatic hydrocarbon group may have part or all of the hydrogen atoms substituted with a substituent other than the aforementioned polar group. Examples of the substituent include a fluorine atom, a fluorinated alkyl group of 1 to 5 carbon atoms, and an oxygen atom (═O). Further, the linear or branched aliphatic hydrocarbon group may have a divalent group containing a hetero atom present between the carbon atoms. Examples of the “divalent group containing a hetero atom” include the same groups as those described for the “divalent linking group containing a hetero atom” as the divalent linking group represented by A in general formula (a0-1) or (a0-2) explained above in connection with the structural unit (a0).

As examples of the “aliphatic hydrocarbon group containing a ring in the structure thereof”, a cyclic aliphatic hydrocarbon group, and a group in which the cyclic aliphatic hydrocarbon group is bonded to the terminal of the aforementioned chain-like aliphatic hydrocarbon group or interposed within the aforementioned chain-like aliphatic hydrocarbon group, can be given.

The cyclic aliphatic hydrocarbon group preferably has 3 to 30 carbon atoms. Further, the cyclic aliphatic hydrocarbon group may be either a polycyclic group or a monocyclic group, and is preferably a polycyclic group.

Specifically, the cyclic aliphatic hydrocarbon group can be selected appropriately from the multitude of groups that have been proposed for the resins of resist compositions designed for use with ArF excimer lasers. As the monocyclic aliphatic hydrocarbon group, a group in which two or more hydrogen atoms have been removed from a monocycloalkane of 3 to 20 carbon atoms is preferable. Examples of the monocycloalkane include cyclopentane and cyclohexane. As the polycyclic aliphatic hydrocarbon group, a group in which two or more hydrogen atoms have been removed from a polycycloalkane of 7 to 30 carbon atoms is preferable. Examples of the polycycloalkane include adamantane, norbornane, isobornane, tricyclodecane and tetracyclododecane.

The cyclic aliphatic hydrocarbon group may have part or all of the hydrogen atoms substituted with a substituent other than the aforementioned polar group. Examples of the substituent include an alkyl group of 1 to 5 carbon atoms, a fluorine atom, a fluorinated alkyl group of 1 to 5 carbon atoms, and an oxygen atom (═O).

When the hydrocarbon group within the polar group-containing aliphatic hydrocarbon group is a linear or branched aliphatic hydrocarbon group, the structural unit (a3′) is preferably a structural unit derived from a hydroxyalkyl ester of acrylic acid. The hydroxyalkyl group within the structural unit is preferably a hydroxyalkyl group of 1 to 10 carbon atoms.

Further, when the hydrocarbon group within the polar group-containing aliphatic hydrocarbon group is an aliphatic hydrocarbon group containing a ring in the structure thereof, the structural unit (a3′) is preferably those having an adamantyl group or norbornyl group to which 1 to 3 hydroxyl groups, cyano groups or hydroxyalkyl groups are bonded (for example, structural units represented by general formulas (a3-1) to (a3-3) described later).

Examples of aromatic hydrocarbon groups to which the polar group is bonded include a divalent aromatic hydrocarbon group in which one hydrogen atom has been removed from a benzene ring of a monovalent aromatic hydrocarbon group such as a phenyl group, a biphenyl group, a fluorenyl group, a naphthyl group, an anthryl group or a phenanthryl group;

an aromatic hydrocarbon group in which part of the carbon atoms constituting the ring of the aforementioned divalent aromatic hydrocarbon group has been substituted with a hetero atom such as an oxygen atom, a sulfur atom or a nitrogen atom; and

an aromatic hydrocarbon group in which one hydrogen atom has been removed from a benzene ring of an arylalkyl group such as a benzyl group, a phenethyl group, a 1-naphthylmethyl group, a 2-naphthylmethyl group, a 1-naphthylethyl group or a 2-naphthylethyl group.

The aromatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

As the structural unit (a3′), structural units represented by general formulas (a3-1) to (a3-10) shown below are preferred.

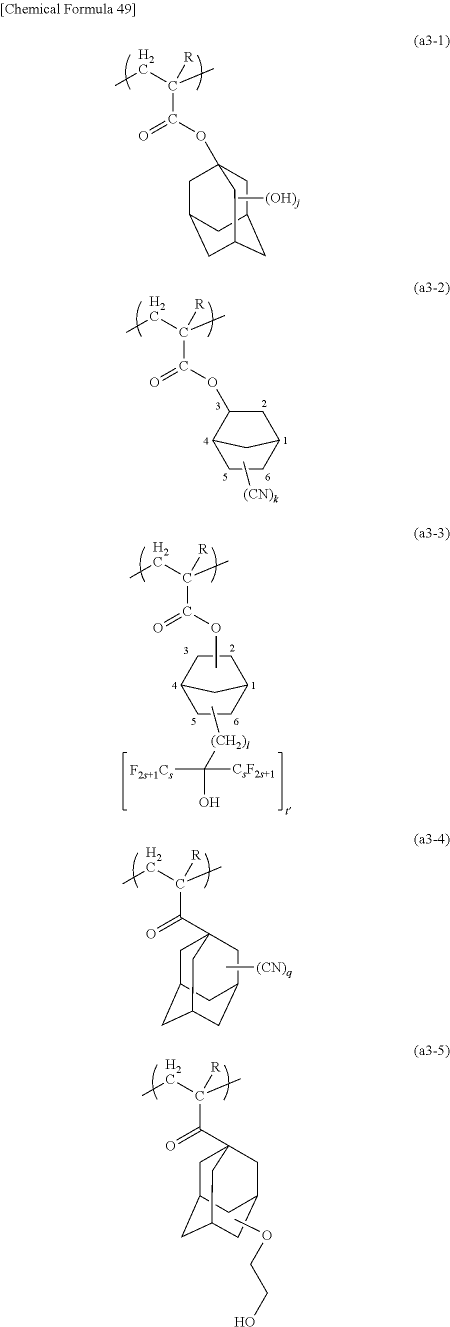

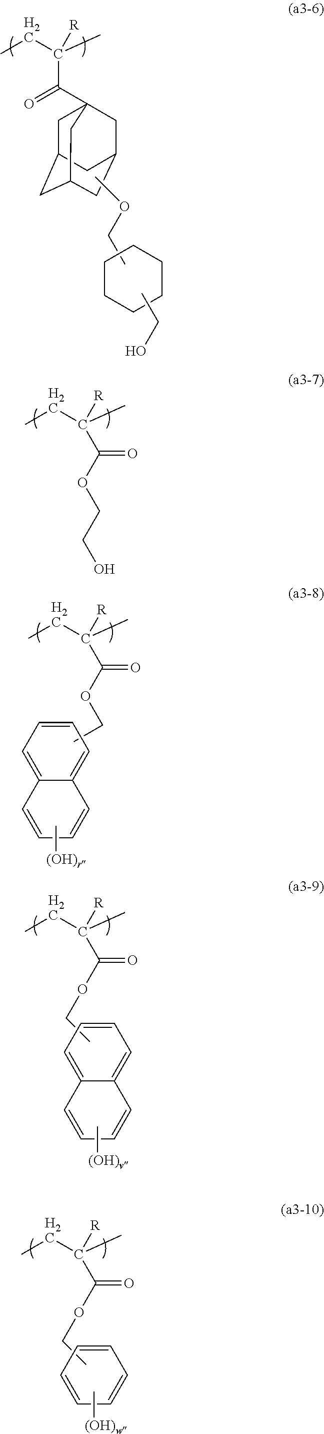

In the formulas above, R is the same as defined above; j is an integer of 1 to 3; k is an integer of 1 to 3; t′ is an integer of 1 to 3; 1 is an integer of 1 to 5; s is an integer of 1 to 3; and each of q, r″, v″ and w″ independently represents an integer of 1 to 3.

In formula (a3-1), j is preferably 1 or 2, and more preferably 1. When j is 1, it is preferable that the hydroxyl group be bonded to the 3rd position of the adamantyl group.

When j is 2, it is preferable that the hydroxyl groups be bonded to the 3rd and 5th positions of the adamantyl group.

In formula (a3-2), k is preferably 1. The cyano group is preferably bonded to the 5th or 6th position of the norbornyl group.

In formula (a3-3), t′ is preferably 1. l is preferably 1. s is preferably 1. Further, it is preferable that a 2-norbornyl group or 3-norbornyl group be bonded to the terminal of the carboxyl group of the acrylic acid. The fluorinated alkyl alcohol is preferably bonded to the 5th or 6th position of the norbornyl group.

In general formula (a3-4), q is preferably 1 or 2, and more preferably 1. When q is 2, it is preferable that the cyano groups be bonded to the 3rd and 5th positions of the adamantyl group. When q is 1, it is preferable that the cyano group be bonded to the 3rd position of the adamantyl group.

In general formula (a3-8), r″ is preferably 1 or 2, and more preferably 1.

In general formula (a3-9), v″ is preferably 1 or 2, and more preferably 1.

In general formula (a3-10), w″ is preferably 1 or 2, and more preferably 1.

As the structural unit (a3′) contained in the component (A1), one type of structural unit may be used, or two or more types may be used.

In the component (A1), the amount of the structural unit (a3′) based on the combined total of all structural units constituting the component (A1) is preferably 1 to 40 mol %, more preferably 1 to 30 mol %, and still more preferably 5 to 20 mol %. By making the amount of the structural unit (a3′) at least as large as the lower limit of the above-mentioned range, the effect of using the structural unit (a3′) can be satisfactorily achieved. On the other hand, by making the amount of the structural unit (a3′) no more than the upper limit of the above-mentioned range, a good balance can be achieved with the other structural units.

The component (A1) may also include other structural units besides the above structural units (a0) to (a3) and (a3′), provided the inclusion of these other structural units does not impair the effects of the present invention.

As such a structural unit, any other structural unit which cannot be classified as one of the above structural units (a0) to (a3) and (a3′) can be used without any particular limitations, and any of the multitude of conventional structural units used within resist resins for ArF excimer lasers or KrF excimer lasers (and particularly for ArF excimer lasers) can be used.

Examples of such other structural units include a structural unit (a4) derived from an (α-substituted) acrylate ester containing a non-acid-dissociable aliphatic polycyclic group.

The “non-acid-dissociable aliphatic cyclic group” for the structural unit (a4) is an aliphatic cyclic group that does not dissociate, when acid is generated from the structural unit (a0) or an arbitrary component (B) described later upon exposure, and remains within this structural unit as it is in spite of the action of this acid. By including the structural unit (a4) containing such an aliphatic cyclic group, the dry etching resistance of the formed resist pattern is improved. Further, the hydrophobicity of the component (A1) increases. The hydrophobicity increase contributes to favorable improvements in the resolution, resist pattern shape and the like, especially in the case of developing process using an organic solvent.

Examples of the non-acid-dissociable aliphatic cyclic group include a monovalent aliphatic cyclic group in which a substituent (a group or an atom other than hydrogen) is not bonded to the carbon atom to which an atom adjacent to this aliphatic cyclic group (e.g., “—O—” within “—C(═O)—O— group”) is bonded. The aliphatic cyclic group is not particularly limited as long as it is acid non-dissociable, and any of the multitude of conventional cyclic groups used within the resin component of resist compositions for ArF excimer lasers or KrF excimer lasers (and particularly for ArF excimer lasers) can be used. The aliphatic cyclic group may be either saturated or unsaturated, but is preferably saturated. Specific examples thereof include a group in which one hydrogen atom has been removed from the cycloalkane such as the monocycloalkane or the polycycloalkane listed above in connection with the aliphatic cyclic group in the structural unit (a1).

The aliphatic cyclic group may be either a monocyclic group or a polycyclic group. In terms of the effects of the above effects, the polycyclic group is preferable. It is particularly desirable that the aliphatic polycyclic group be a bi-, tri- or tetra-cyclic group, as the above effects are improved. Of these, in terms of factors such as industrial availability and the like, at least one polycyclic group selected from amongst a tricyclodecyl group, adamantyl group, tetracyclododecyl group, isobornyl group and norbornyl group is particularly desirable.

Specific examples of the non-acid-dissociable aliphatic cyclic group include a monovalent aliphatic cyclic group in which a substituent (a group or an atom other than hydrogen) is not bonded to the carbon atom to which an atom adjacent to this aliphatic cyclic group (e.g., “—O—” within “—C(═O)—O— group”) is bonded.

More specific examples of the non-acid-dissociable aliphatic cyclic group include a group in which R¹⁴ within the groups represented by formulas (1-1) to (1-9) listed above in connection with the structural unit (a1) has been substituted with a hydrogen atom; and a group in which a hydrogen atom has been removed from a tertiary carbon atom within the cycloalkane formed solely of the carbon atoms constituting the ring skeleton.

A substituent may be bonded to this aliphatic cyclic group. Examples of the substituent include an alkyl group of 1 to 5 carbon atoms, a fluorine atom and a fluorinated alkyl group.

As the structural unit (a4), a structural unit represented by general formula (a4-0) shown below is preferable, and a structural unit represented by any one of general formulas (a4-1) to (a4-5) shown below is particularly desirable.

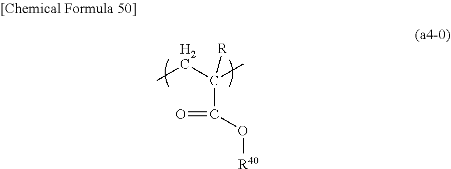

In the formula, R is the same as defined above; and R⁴⁰ represents an acid non-dissociable, aliphatic polycyclic group.

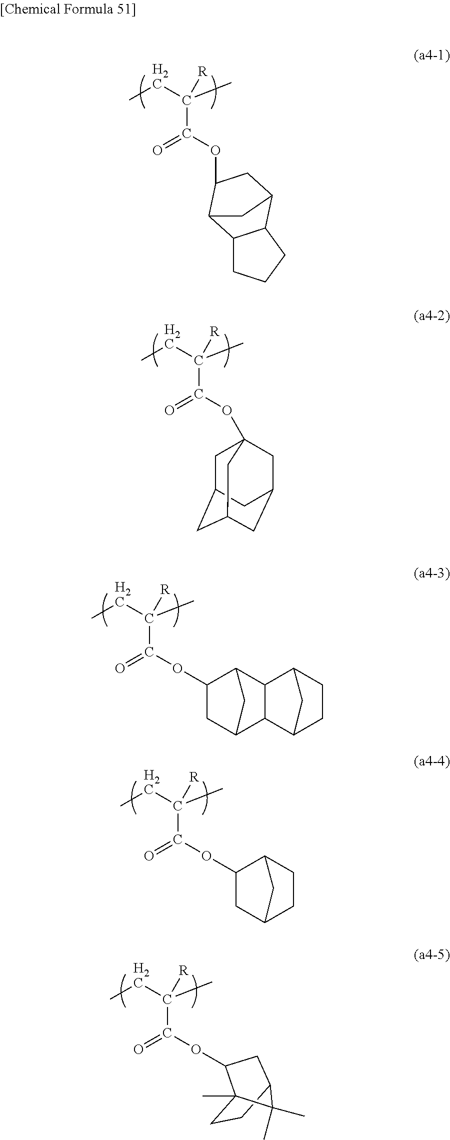

In the formulas, R is the same as defined above.

As the structural unit (a4) contained in the component (A1), one type of structural unit may be used, or two or more types may be used.

In the component (A1), the amount of the structural unit (a4) based on the combined total of all structural units constituting the component (A1) is preferably 1 to 30 mol %, more preferably 1 to 20 mol %, and still more preferably 5 to 20 mol %. By ensuring that this amount is at least as large as the lower limit of the above range, the effects generated by including the structural unit (a4) are obtained satisfactorily, whereas by ensuring that the amount is not more than the upper limit of the above range, a good balance can be achieved with the other structural units.

The component (A1) is preferably a copolymer having the structural units (a0), (a1) and (a3). Examples of such copolymers include a copolymer consisting of the structural units (a0), (a1) and (a3); a copolymer consisting of the structural units (a0), (a1), (a2) and (a3); and a copolymer consisting of the structural units (a0), (a1), (a2), (a3) and (a3′).

The weight average molecular weight (Mw) (the polystyrene equivalent value determined by gel permeation chromatography (GPC)) of the component (A1) is not particularly limited, but is preferably 1,000 to 50,000, more preferably 1,500 to 30,000, and most preferably 2,000 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) is not particularly limited, but is preferably 1.0 to 5.0, more preferably 1.0 to 3.0, and most preferably 1.0 to 2.5. Here, Mn is the number average molecular weight.

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH during the above polymerization, a —C(CF₃)₂—OH group can be introduced at the terminals of the component (A1). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

As the monomers for deriving the corresponding structural units, commercially available monomers may be used, or the monomers may be synthesized by a conventional method. For example, monomers for deriving the aforementioned structural unit (a3) can be produced by a method disclosed in Japanese Unexamined Patent Application, First Publication No. 2009-286720. Further, of the various structural units classified as the structural unit (a0), with respect to the structural units having a cation moiety in the resin side, such as the structural units represented by the above general formula (a0-1), monomers for deriving these structural units can be readily synthesized through an esterification reaction or the like of (α-substituted) acrylic acid chloride with an onium salt having a hydroxyl group within the cation moiety. Furthermore, of the various structural units classified as the structural unit (a0), with respect to the structural units having an anion moiety in the resin side, such as the structural units represented by the above general formula (a0-2), monomers for deriving these structural units can be produced by the methods disclosed in Japanese Unexamined Patent Application, First Publication No. 2009-91350, Japanese Unexamined Patent Application, First Publication No. 2010-095643, and Japanese Unexamined Patent Application, First Publication No. 2009-7327.

### <Component (B)>

The resist composition of the present invention may also include an acid generator component (B) (hereafter, referred to as “component (B)”) which generates acid upon exposure, other than the component (A).

As the component (B), there is no particular limitation, and any of the known acid generators used in conventional chemically amplified resist compositions can be used. Examples of these acid generators are numerous, and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; imino sulfonate-based acid generators; and disulfone-based acid generators.

As an onium salt-based acid generator, a compound represented by general formula (b-1) or (b-2) shown below can be used.

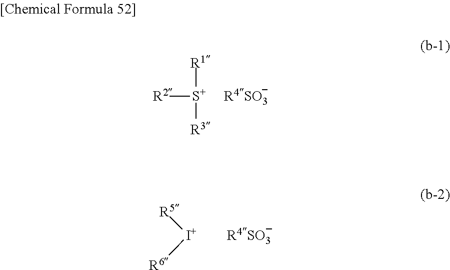

In the above formulas, each of R^{1″} to R^{3″} and R^{5″} to R^{6″} independently represents an aryl group which may have a substituent, an alkyl group or an alkenyl group, wherein two of R^{1″} to R^{3″} in formula (b-1) may be bonded to each other to form a ring with the sulfur atom in the formula; and R^{4″} represents an alkyl group which may have a substituent, a halogenated alkyl group, an aryl group or an alkenyl group.

In formula (b-1), each of R^{1″} to R^{3″} independently represents an aryl group which may have a substituent, an alkyl group or an alkenyl group. Two of R^{1″} to R^{3″} may be mutually bonded to form a ring with the sulfur atom in the formula.

Further, at least one of R^{1″} to R^{3″} preferably represents an aryl group, more preferably two or more of R^{1″} to R^{3″} represent aryl groups, and it is particularly desirable that all of R^{1″} to R^{3″} be aryl groups, as such groups yield superior improvements in the lithography properties and resist pattern shape.

Examples of the aryl groups for R^{1″} to R^{3″} include an unsubstituted aryl group having 6 to 20 carbon atoms; and a substituted aryl group in which a part or all of the hydrogen atoms of the aforementioned unsubstituted aryl group has been substituted with alkyl groups, alkoxy groups, halogen atoms, hydroxyl groups, oxo groups (═O), aryl groups, alkoxyalkyloxy groups, alkoxycarbonylalkyloxy groups, —C(═O)—O—R^{6′}, —O—C(═O)—R^{7′}, —O—R^{8′} or the like. Each of R^{6′}, R^{7′} and R^{8′} represents a linear or branched saturated hydrocarbon group of 1 to 25 carbon atoms or cyclic saturated hydrocarbon group of 3 to 20 carbon atoms, or a linear or branched, unsaturated aliphatic hydrocarbon group of 2 to 5 carbon atoms.

The unsubstituted aryl group for R^{1″} to R^{3″} is preferably an aryl group having 6 to 10 carbon atoms because it can be synthesized at a low cost. Specific examples thereof include a phenyl group and a naphthyl group.

The alkyl group as the substituent for the substituted aryl group represented by R^{1″} to R^{3″} is preferably an alkyl group of 1 to 5 carbon atoms, and a methyl group, an ethyl group, a propyl group, an n-butyl group, or a tert-butyl group is particularly desirable.

The alkoxy group as the substituent for the substituted aryl group is preferably an alkoxy group having 1 to 5 carbon atoms, and a methoxy group, an ethoxy group, an n-propoxy group, an iso-propoxy group, an n-butoxy group or a tert-butoxy group is particularly desirable.

The halogen atom as the substituent for the substituted aryl group is preferably a fluorine atom.

As the aryl group as the substituent for the substituted aryl group, the same aryl groups as those described above for R^{1″} to R^{3″} can be mentioned, and an aryl group of 6 to 20 carbon atoms is preferable, an aryl group of 6 to 10 carbon atoms is more preferable, and a phenyl group or a naphthyl group is still more preferable.

Examples of the alkoxyalkyloxy group as the substituent for the substituted aryl group include groups represented by a general formula: —O—C(R⁴⁷)(R⁴⁸)—O—R⁴⁹ [wherein each of R⁴⁷ and R⁴⁸ independently represents a hydrogen atom or a linear or branched alkyl group; and R⁴⁹ represents an alkyl group].

The alkyl group for R⁴⁷ and R⁴⁸ preferably has 1 to 5 carbon atoms, and may be either linear or branched, and is preferably an ethyl group or a methyl group, and most preferably a methyl group.

It is preferable that at least one of R⁴⁷ and R⁴⁸ be a hydrogen atom. It is particularly desirable that either one of R⁴⁷ and R⁴⁸ be a hydrogen atom, and the other be a hydrogen atom or a methyl group.

The alkyl group for R⁴⁹ preferably has 1 to 15 carbon atoms, and may be linear, branched or cyclic.

The linear or branched alkyl group for R⁴⁹ preferably has 1 to 5 carbon atoms. Examples thereof include a methyl group, an ethyl group, a propyl group, an n-butyl group and a tert-butyl group.

The cyclic alkyl group for R⁴⁹ preferably has 4 to 15 carbon atoms, more preferably 4 to 12 carbon atoms, and most preferably 5 to 10 carbon atoms. Specific examples thereof include groups in which one or more hydrogen atoms have been removed from a monocycloalkane or a polycycloalkane such as a bicycloalkane, tricycloalkane or tetracycloalkane, and which may or may not be substituted with alkyl groups of 1 to 5 carbon atoms, fluorine atoms or fluorinated alkyl groups. Examples of the monocycloalkane include cyclopentane and cyclohexane. Examples of polycycloalkane include adamantane, norbornane, isobornane, tricyclodecane and tetracyclododecane. Among these, a group in which one or more hydrogen atoms have been removed from adamantane is preferable.

Examples of the alkoxycarbonylalkyloxy group as the substituent for the substituted aryl group include groups represented by a general formula: —O—R⁵⁰—C(═O)—O—R⁵⁶ [wherein R⁵⁰ represents a linear or branched alkylene group; and R⁵⁶ represents a tertiary alkyl group].

The linear or branched alkylene group for R⁵⁰ preferably has 1 to 5 carbon atoms, and examples thereof include a methylene group, an ethylene group, a trimethylene group, a tetramethylene group and a 1,1-dimethylethylene group.

Examples of the tertiary alkyl group for R⁵⁶ include a 2-methyl-2-adamantyl group, a 2-ethyl-2-adamantyl group, a 1-methyl-1-cyclopentyl group, a 1-ethyl-1-cyclopentyl group, a 1-methyl-1-cyclohexyl group, a 1-ethyl-1-cyclohexyl group, a 1-(1-adamantyl)-1-methylethyl group, a 1-(1-adamantyl)-1-methylpropyl group, a 1-(1-adamantyl)-1-methylbutyl group, a 1-(1-adamantyl)-1-methylpentyl group, a 1-(1-cyclopentyl)-1-methylethyl group, a 1-(1-cyclopentyl)-1-methylpropyl group, a 1-(1-cyclopentyl)-1-methylbutyl group, a 1-(1-cyclopentyl)-1-methylpentyl group, a 1-(1-cyclohexyl)-1-methylethyl group, a 1-(1-cyclohexyl)-1-methylpropyl group, a 1-(1-cyclohexyl)-1-methylbutyl group, a 1-(1-cyclohexyl)-1-methylpentyl group, a tert-butyl group, a tert-pentyl group and a tert-hexyl group.

Further, a group in which R⁵⁶ in the group represented by the aforementioned general formula: —O—R⁵⁰—C(═O)—O—R⁵⁶ has been substituted with R^{56′} can also be mentioned. R^{56′} represents a hydrogen atom, an alkyl group, a fluorinated alkyl group or an aliphatic cyclic group which may contain a hetero atom.

The alkyl group for R^{56′} is the same as defined for the alkyl group for the aforementioned R⁴⁹.

Examples of the fluorinated alkyl group for R^{56′} include groups in which part or all of the hydrogen atoms within the alkyl group for R⁴⁹ has been substituted with a fluorine atom.

Examples of the aliphatic cyclic group for R^{56′} which may contain a hetero atom include an aliphatic cyclic group which does not contain a hetero atom, an aliphatic cyclic group containing a hetero atom in the ring structure, and an aliphatic cyclic group in which a hydrogen atom has been substituted with a hetero atom.

As an aliphatic cyclic group for R^{56′} which does not contain a hetero atom, a group in which one or more hydrogen atoms have been removed from a monocycloalkane or a polycycloalkane such as a bicycloalkane, a tricycloalkane or a tetracycloalkane can be mentioned. Examples of the monocycloalkane include cyclopentane and cyclohexane. Examples of polycycloalkane include adamantane, norbornane, isobornane, tricyclodecane and tetracyclododecane. Among these, a group in which one or more hydrogen atoms have been removed from adamantane is preferable.

Specific examples of the aliphatic cyclic group for R^{56′} containing a hetero atom in the ring structure include groups represented by formulas (L1) to (L5) and (S1) to (S4) described later.

As the aliphatic cyclic group for R^{56′} in which a hydrogen atom has been substituted with a hetero atom, an aliphatic cyclic group in which a hydrogen atom has been substituted with an oxygen atom (═O) can be mentioned.

Each of R^{6′}, R^{7′} and R^{8′} in —C(═O)—O—R^{6′}, —O—C(═O)—R^{7′} and —O—R^{8′} represents a linear or branched saturated hydrocarbon group of 1 to 25 carbon atoms or cyclic saturated hydrocarbon group of 3 to 20 carbon atoms, or a linear or branched, unsaturated aliphatic hydrocarbon group of 2 to 5 carbon atoms.

The linear or branched, saturated hydrocarbon group has 1 to 25 carbon atoms, preferably 1 to 15 carbon atoms, and more preferably 4 to 10 carbon atoms.

Examples of the linear, saturated hydrocarbon group include a methyl group, an ethyl group, a propyl group, a butyl group, a pentyl group, a hexyl group, a heptyl group, an octyl group, a nonyl group and a decyl group.

Examples of the branched, saturated hydrocarbon group include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group, but excluding tertiary alkyl groups.

The linear or branched, saturated hydrocarbon group may have a substituent. Examples of the substituent include an alkoxy group, a halogen atom, a halogenated alkyl group, a hydroxyl group, an oxygen atom (═O), a cyano group and a carboxyl group.

The alkoxy group as the substituent for the linear or branched saturated hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the linear or branched, saturated hydrocarbon group include a fluorine atom, a chlorine atom, a bromine atom and an iodine atom, and a fluorine atom is preferable.

Examples of the halogenated alkyl group as the substituent for the linear or branched, saturated hydrocarbon group include a group in which part or all of the hydrogen atoms within the aforementioned linear or branched, saturated hydrocarbon group have been substituted with the aforementioned halogen atoms.

The cyclic saturated hydrocarbon group of 3 to 20 carbon atoms for R^{6′}, R^{7′} and R^{8′} may be either a polycyclic group or a monocyclic group, and examples thereof include groups in which one hydrogen atom has been removed from a monocycloalkane, and groups in which one hydrogen atom has been removed from a polycycloalkane (e.g., a bicycloalkane, a tricycloalkane or a tetracycloalkane). More specific examples include groups in which one hydrogen atom has been removed from a monocycloalkane such as cyclopentane, cyclohexane, cycloheptane or cyclooctane; and groups in which one or more hydrogen atoms have been removed from a polycycloalkane such as adamantane, norbornane, isobornane, tricyclodecane or tetracyclododecane.

The cyclic, saturated hydrocarbon group may have a substituent. For example, part of the carbon atoms constituting the ring within the cyclic alkyl group may be substituted with a hetero atom, or a hydrogen atom bonded to the ring within the cyclic alkyl group may be substituted with a substituent.

In the former example, a heterocycloalkane in which part of the carbon atoms constituting the ring within the aforementioned monocycloalkane or polycycloalkane has been substituted with a hetero atom such as an oxygen atom, a sulfur atom or a nitrogen atom, and one or more hydrogen atoms have been removed therefrom, can be used. Further, the ring may contain an ester bond (—C(═O)—O—). More specific examples include a lactone-containing monocyclic group, such as a group in which one hydrogen atom has been removed from γ-butyrolactone; and a lactone-containing polycyclic group, such as a group in which one hydrogen atom has been removed from a bicycloalkane, tricycloalkane or tetracycloalkane that includes a lactone ring.

In the latter example, as the substituent, the same substituent groups as those for the aforementioned linear or branched alkyl group, or a lower alkyl group of 1 to 5 carbon atoms can be used.

Alternatively, R^{6′}, R^{7′} and R^{8′} may be a combination of a linear or branched alkyl group and a cyclic alkyl group.

Examples of the combination of a linear or branched alkyl group with a cyclic alkyl group include groups in which a cyclic alkyl group as a substituent is bonded to a linear or branched alkyl group, and groups in which a linear or branched alkyl group as a substituent is bonded to a cyclic alkyl group.

Examples of the linear aliphatic unsaturated hydrocarbon group for R^{6′}, R^{7′} and R^{8′} include a vinyl group, a propenyl group (an allyl group) and a butynyl group.

Examples of the branched aliphatic unsaturated hydrocarbon group for R^{6′}, R^{7′} and R^{8′} include a 1-methylpropenyl group and a 2-methylpropenyl group.

The aforementioned linear or branched, aliphatic unsaturated hydrocarbon group may have a substituent. Examples of the substituents include the same substituents as those which the aforementioned linear or branched alkyl group may have.

Among the aforementioned examples, as R^{7′} and R^{8′}, in terms of improvement in lithography properties and shape of the resist pattern, a linear or branched, saturated hydrocarbon group of 1 to 15 carbon atoms or a cyclic saturated hydrocarbon group of 3 to 20 carbon atoms is preferable.

The aryl group for each of R^{1″} to R^{3″} is preferably a phenyl group or a naphthyl group.

Examples of the alkyl group for R^{1″} to R^{3″} include linear, branched or cyclic alkyl groups of 1 to 10 carbon atoms. Among these, alkyl groups of 1 to 5 carbon atoms are preferable as the resolution becomes excellent. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decyl group, and a methyl group is most preferable because it is excellent in resolution and can be synthesized at a low cost.

The alkenyl group for R^{1″} to R^{3″} preferably has 2 to 10 carbon atoms, more preferably 2 to 5 carbon atoms, and still more preferably 2 to 4 carbon atoms. Specific examples thereof include a vinyl group, a propenyl group (an allyl group), a butynyl group, a 1-methylpropenyl group and a 2-methylpropenyl group.

When two of R^{1″} to R^{3″} are bonded to each other to form a ring with the sulfur atom in the formula, it is preferable that the two of R^{1″} to R^{3″} form a 3 to 10-membered ring including the sulfur atom, and it is particularly desirable that the two of R^{1″} to R^{3″} form a 5 to 7-membered ring including the sulfur atom.

When two of R^{1″} to R^{3″} are bonded to each other to form a ring with the sulfur atom in the formula, the remaining one of R^{1″} to R^{3″} is preferably an aryl group. As examples of the aryl group, the same as the above-mentioned aryl groups for R^{1″} to R^{3″} can be given.

Specific examples of cation moiety of the compound represented by the above general formula (b-1) include triphenylsulfonium, (3,5-dimethylphenyl)diphenylsulfonium, (4-(2-adamantoxymethyloxy)-3,5-dimethylphenyl)diphenylsulfonium, (4-(2-adamantoxymethyloxy)phenyl)diphenylsulfonium, (4-(tert-butoxycarbonylmethyloxy)phenyl)diphenylsulfonium, (4-(tert-butoxycarbonylmethyloxy)-3,5-dimethylphenyl)diphenylsulfonium, (4-(2-methyl-2-adamantyloxycarbonylmethyloxy)phenyl)diphenylsulfonium, (4-(2-methyl-2-adamantyloxycarbonylmethyloxy)-3,5-dimethylphenyl)diphenylsulfonium, tri(4-methylphenyl)sulfonium, dimethyl(4-hydroxynaphthyl)sulfonium, monophenyldimethylsulfonium, diphenylmonomethylsulfonium, (4-methylphenyl)diphenylsulfonium, (4-methoxyphenyl)diphenylsulfonium, tri(4-tert-butyl)phenylsulfonium, diphenyl(1-(4-methoxy)naphthyl)sulfonium, di(1-naphthyl)phenylsulfonium, 1-phenyltetrahydrothiophenium, 1-(4-methylphenyl)tetrahydrothiophenium, 1-(3,5-dimethyl-4-hydroxyphenyl)tetrahydrothiophenium, 1-(4-methoxynaphthalene-1-yl)tetrahydrothiophenium, 1-(4-ethoxynaphthalene-1-yl)tetrahydrothiophenium, 1-(4-n-butoxynaphthalene-1-yl)tetrahydrothiophenium, 1-phenyltetrahydrothiopyranium, 1-(4-hydroxyphenyl)tetrahydrothiopyranium, 1-(3,5-dimethyl-4-hydroxyphenyl)tetrahydrothiopyranium and 1-(4-methylphenyl)tetrahydrothiopyranium.

Further, specific examples of the preferred cation moiety for the compound represented by the above formula (b-1) include cation moieties shown below.

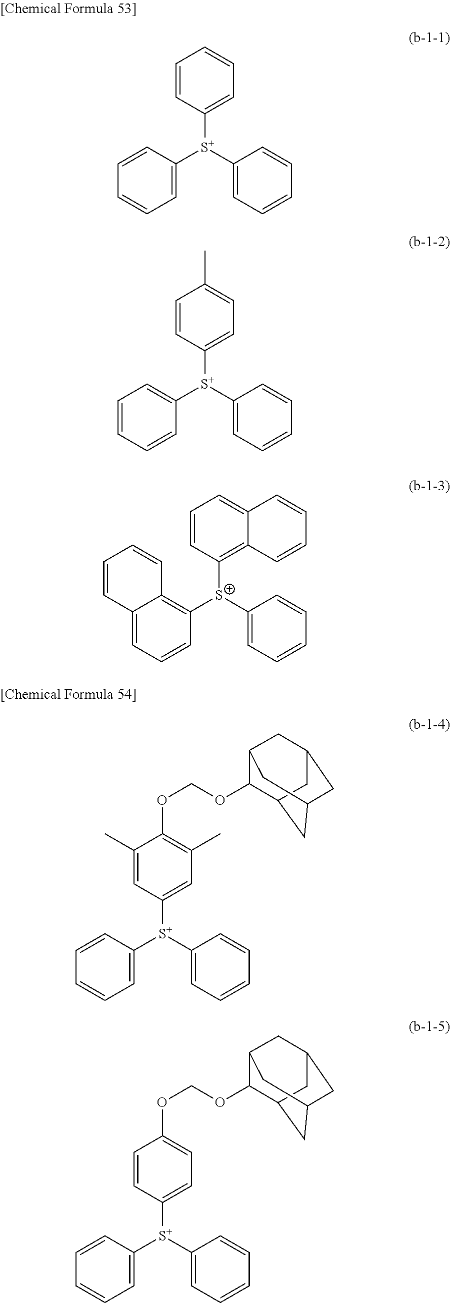

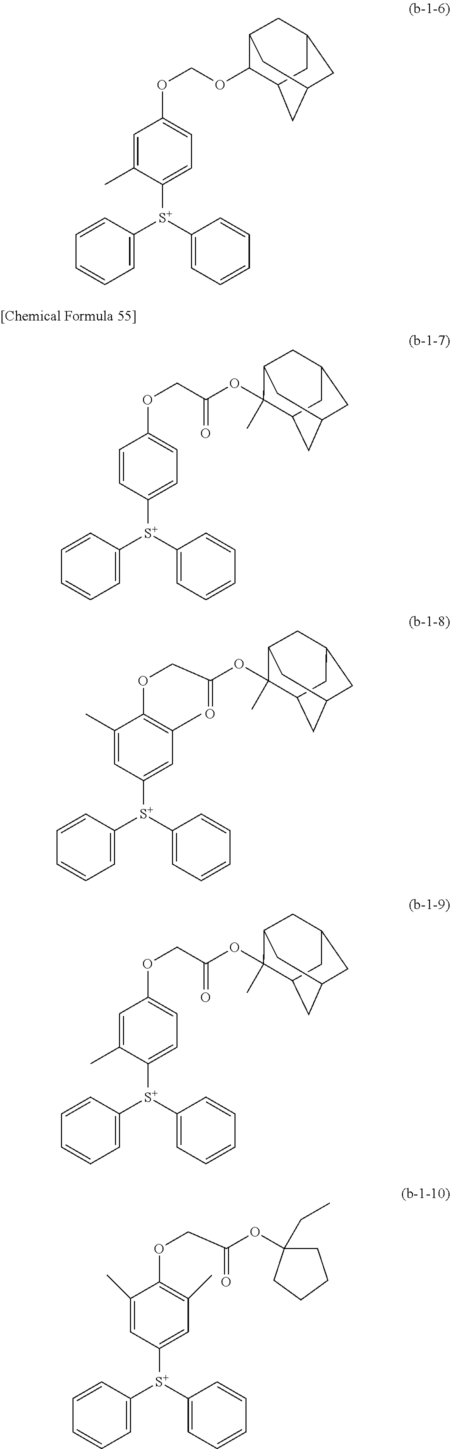

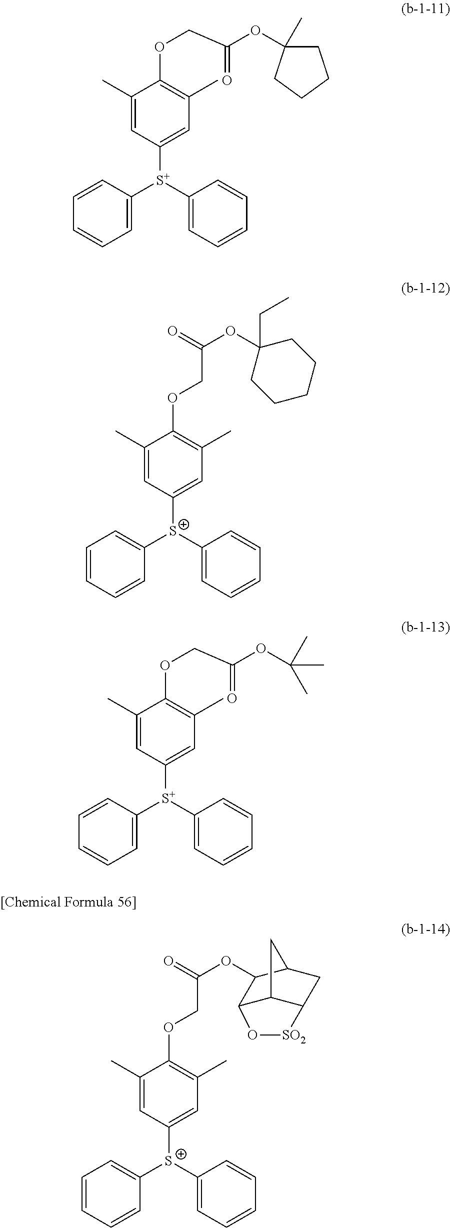

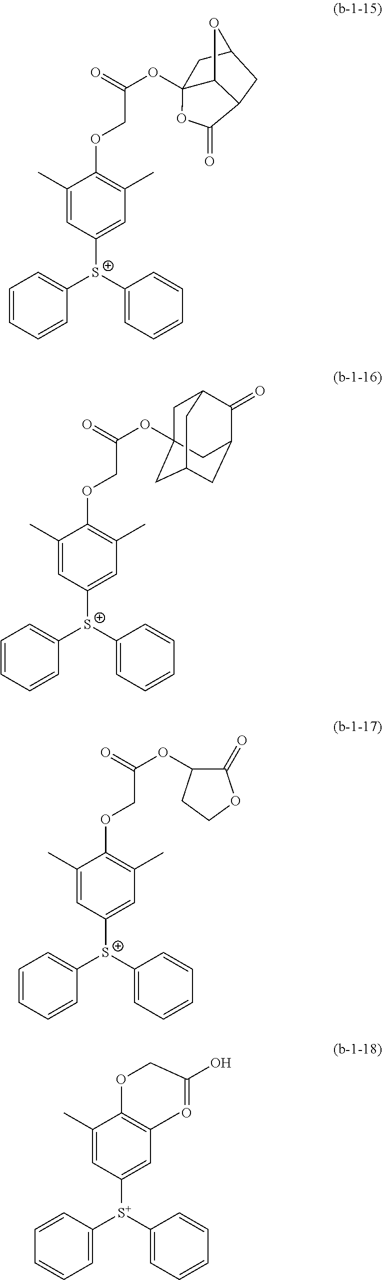

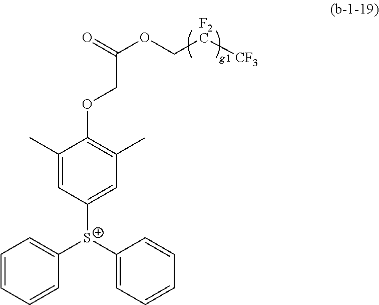

In the formula, g1 represents a recurring number, and is an integer of 1 to 5.

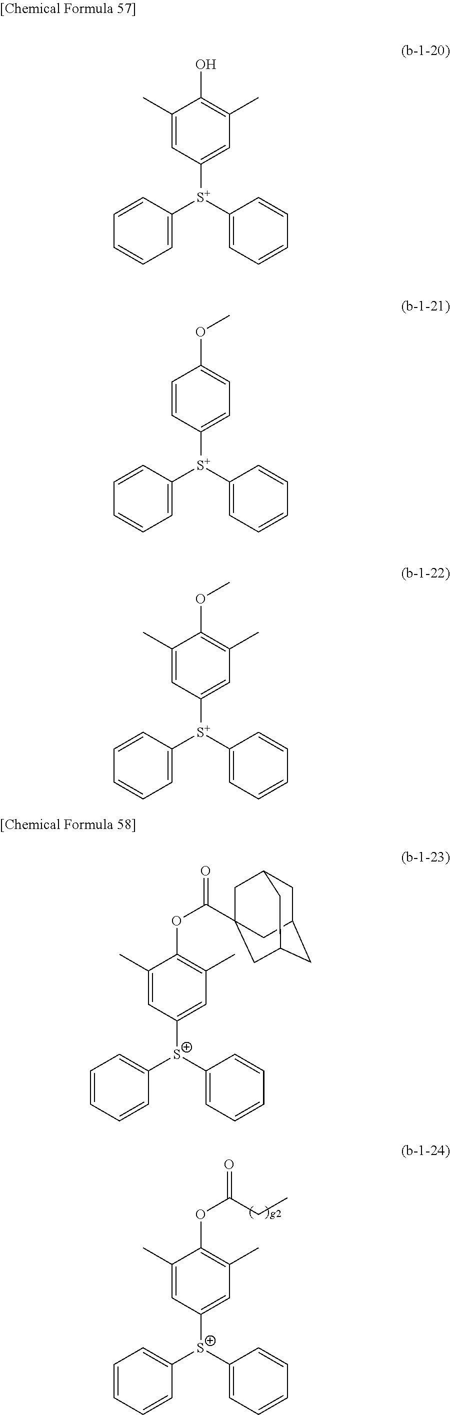

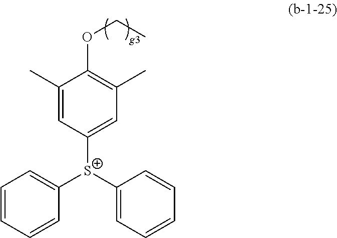

In the formula, g2 and g3 represent recurring numbers, wherein g2 is an integer of 0 to 20, and g3 is an integer of 0 to 20.

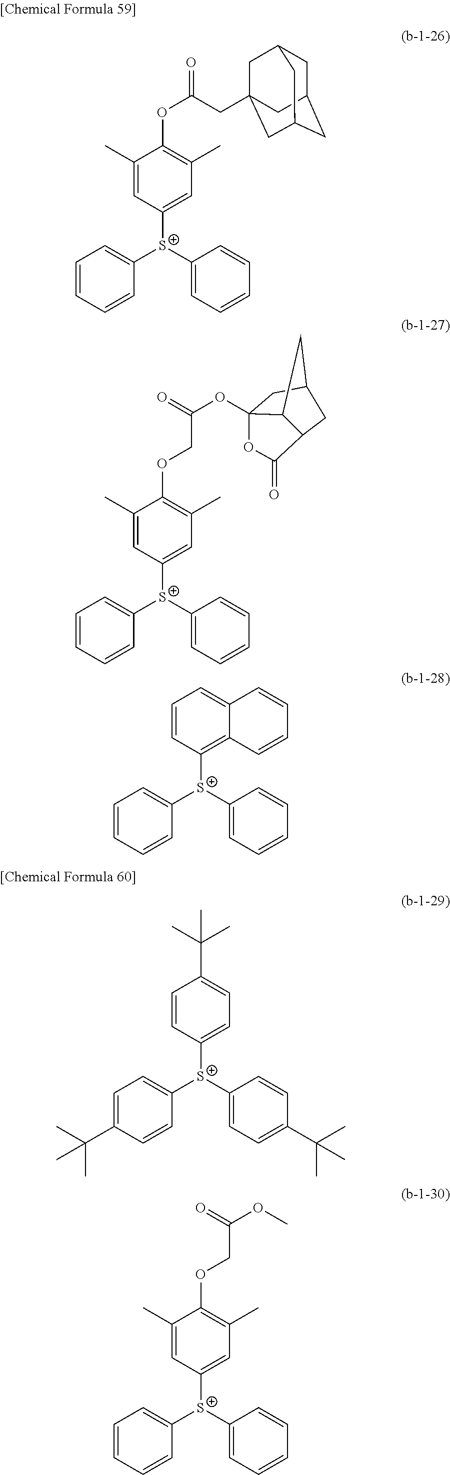

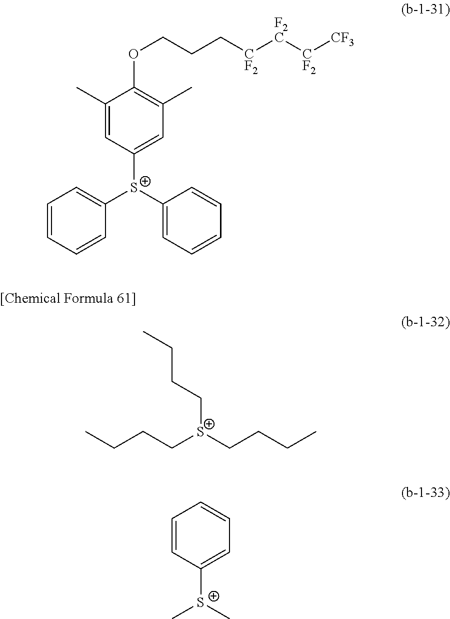

In the above formula (b-1), R^{4″} represents an alkyl group which may have a substituent, a halogenated alkyl group, an aryl group or an alkenyl group.

The alkyl group for R^{4″} may be any of linear, branched or cyclic.

The linear or branched alkyl group preferably has 1 to 10 carbon atoms, more preferably 1 to 8 carbon atoms, and most preferably 1 to 4 carbon atoms.

The cyclic alkyl group preferably has 4 to 15 carbon atoms, more preferably 4 to 10 carbon atoms, and most preferably 6 to 10 carbon atoms.

As an example of the halogenated alkyl group for R^{4″}, a group in which part of or all of the hydrogen atoms of the aforementioned linear, branched or cyclic alkyl group have been substituted with halogen atoms can be given. Examples of the aforementioned halogen atom include a fluorine atom, a chlorine atom, a bromine atom and an iodine atom, and a fluorine atom is preferable.

In the halogenated alkyl group, the percentage of the number of halogen atoms based on the total number of halogen atoms and hydrogen atoms (halogenation ratio (%)) is preferably 10 to 100%, more preferably 50 to 100%, and most preferably 100%. Higher halogenation ratios are preferable, as they result in increased acid strength.

The aryl group for R^{4″} is preferably an aryl group of 6 to 20 carbon atoms.

The alkenyl group for R^{4″} is preferably an alkenyl group of 2 to 10 carbon atoms.

With respect to R^{4″}, the expression “may have a substituent” means that part of or all of the hydrogen atoms within the aforementioned alkyl group, halogenated alkyl group, aryl group or alkenyl group may be substituted with substituents (atoms other than hydrogen atoms, or groups).

R^{4″} may have one substituent, or two or more substituents.

Examples of the substituent include a halogen atom, a hetero atom, an alkyl group, and a group represented by the formula X-Q¹- [in the formula, Q¹ represents a divalent linking group containing an oxygen atom; and X represents a hydrocarbon group of 3 to 30 carbon atoms which may have a substituent].

Examples of halogen atoms and alkyl groups as substituents for R^{4″} include the same halogen atoms and alkyl groups as those described above with respect to the halogenated alkyl group for R^{4″}.

Examples of the hetero atom include an oxygen atom, a nitrogen atom, and a sulfur atom.

In the group represented by formula X-Q¹-, Q¹ represents a divalent linking group containing an oxygen atom.

Q¹ may contain an atom other than oxygen. Examples of atoms other than oxygen include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an amide bond (—C(═O)—NH—), a carbonyl group (—C(═O)—) and a carbonate bond (—O—C(═O)—O—); and combinations of the aforementioned non-hydrocarbon, oxygen atom-containing linking groups with an alkylene group.

Specific examples of the combinations of the aforementioned non-hydrocarbon, oxygen atom-containing linking groups and an alkylene group include —R⁹¹—O—, —R⁹²—O—C(═O)—, —C(═O)—O—R⁹³—O—C(═O)— (in the formulas, each of R⁹¹ to R⁹³ independently represents an alkylene group).

The alkylene group for R⁹¹ to R⁹³ is preferably a linear or branched alkylene group, and preferably has 1 to 12 carbon atoms, more preferably 1 to 5 carbon atoms, and most preferably 1 to 3 carbon atoms.

Specific examples of alkylene groups include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

Q¹ is preferably a divalent linking group containing an ester bond or ether bond, and more preferably a group of —R⁹¹—O—, —R⁹²—O—C(═O)— or —C(═O)—O—R⁹³—O—C(═O)—.

In the group represented by the formula X-Q¹-, the hydrocarbon group for X may be either an aromatic hydrocarbon group or an aliphatic hydrocarbon group.

The aromatic hydrocarbon group is a hydrocarbon group having an aromatic ring. The aromatic hydrocarbon group preferably has 3 to 30 carbon atoms, more preferably 5 to 30 carbon atoms, still more preferably 5 to 20 carbon atoms, still more preferably 6 to 15 carbon atoms, and most preferably 6 to 12 carbon atoms. Here, the number of carbon atoms within a substituent(s) is not included in the number of carbon atoms of the aromatic hydrocarbon group.

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an arylalkyl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 2 carbon atoms, and most preferably 1 carbon atom.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned hetero atom can be used.

In the latter example, as the substituent for the aromatic hydrocarbon group, an alkyl group, an alkoxy group, a halogen atom, a halogenated alkyl group, a hydroxyl group, an oxygen atom (═O) or the like can be used.

The alkyl group as the substituent for the aromatic hydrocarbon group is preferably an alkyl group of 1 to 5 carbon atoms, and a methyl group, an ethyl group, a propyl group, an n-butyl group or a tert-butyl group is particularly desirable.

The alkoxy group as the substituent for the aromatic hydrocarbon group is preferably an alkoxy group having 1 to 5 carbon atoms, more preferably a methoxy group, an ethoxy group, a n-propoxy group, an iso-propoxy group, a n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Example of the halogenated alkyl group as the substituent for the aromatic hydrocarbon group includes a group in which part or all of the hydrogen atoms within the aforementioned alkyl group have been substituted with the aforementioned halogen atoms.

The aliphatic hydrocarbon group for X may be either a saturated aliphatic hydrocarbon group, or an unsaturated aliphatic hydrocarbon group. Further, the aliphatic hydrocarbon group may be linear, branched or cyclic.

In the aliphatic hydrocarbon group for X, a part of the carbon atoms constituting the aliphatic hydrocarbon group may be substituted with a substituent group containing a hetero atom, or a part or all of the hydrogen atoms constituting the aliphatic hydrocarbon group may be substituted with a substituent group containing a hetero atom.

As the “hetero atom” for X, there is no particular limitation as long as it is an atom other than carbon and hydrogen. Examples of hetero atoms include a halogen atom, an oxygen atom, a sulfur atom and a nitrogen atom. Examples of the halogen atom include a fluorine atom, a chlorine atom, an iodine atom and a bromine atom.

The substituent group containing a hetero atom may consist solely of the hetero atom, or may be a group that also contains a group or atom other than a hetero atom.

Specific examples of the substituent group for substituting part of the carbon atoms include —O—, —C(═O)—O—, —C(═O)—, —O—C(═O)—O—, —C(═O)—NH—, —NH— (the H may be replaced with a substituent such as an alkyl group of 1 to 5 carbon atoms or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms include an alkoxy group, a halogen atom, a halogenated alkyl group, a hydroxyl group, an oxygen atom (═O) and a cyano group.

The aforementioned alkoxy group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Examples of the aforementioned halogenated alkyl group include a group in which part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15 carbon atoms, and most preferably 1 to 10 carbon atoms. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15 carbon atoms, and most preferably 3 to 10 carbon atoms. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 10 carbon atoms, more preferably 2 to 5 carbon atoms, still more preferably 2 to 4 carbon atoms, and most preferably 3 carbon atoms. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group. The aliphatic cyclic group preferably has 3 to 30 carbon atoms, more preferably 5 to 30 carbon atoms, still more preferably 5 to 20 carbon atoms, still more preferably 6 to 15 carbon atoms, and most preferably 6 to 12 carbon atoms.

Examples thereof include groups in which one or more of the hydrogen atoms have been removed from a monocycloalkane; and groups in which one or more of the hydrogen atoms have been removed from a polycycloalkane such as a bicycloalkane, a tricycloalkane, or a tetracycloalkane. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L6) and (S1) to (S4) shown below.

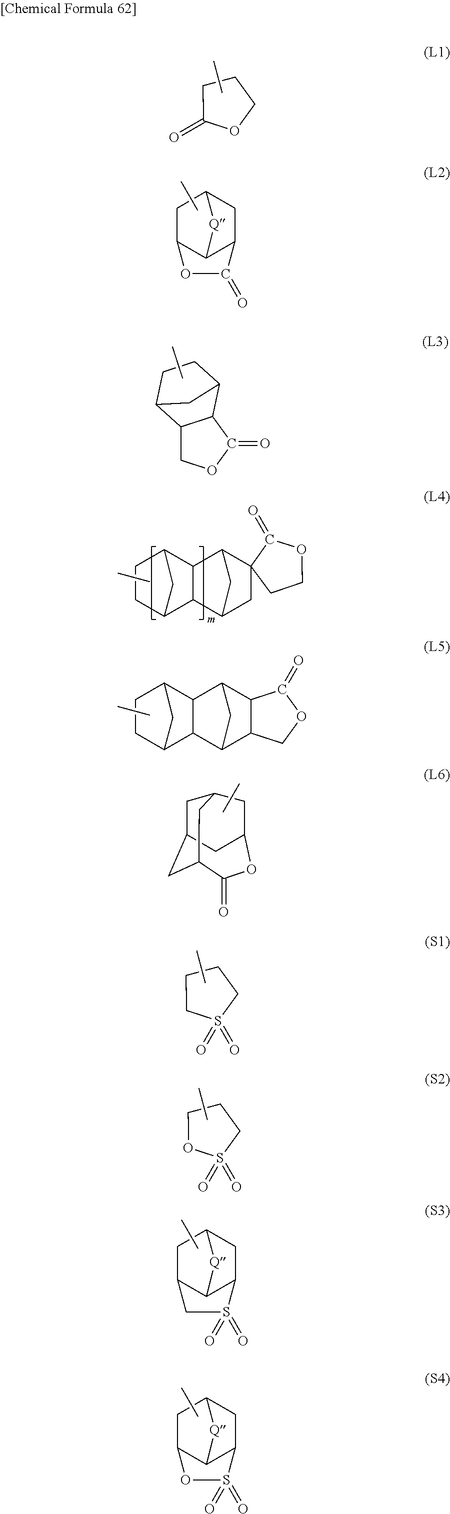

In the formulas, Q″ represents an alkylene group of 1 to 5 carbon atoms, —O—, —S—, —O—R⁹⁴— or —S—R⁹⁵— (wherein each of R⁹⁴ and R⁹⁵ independently represents an alkylene group of 1 to 5 carbon atoms); and m represents 0 or 1.

As the alkylene group for Q″, R⁹⁴ and R⁹⁵, the same alkylene groups as those described above for R⁹¹ to R⁹³ can be used.

In these aliphatic cyclic groups, part of the hydrogen atoms bonded to the carbon atoms constituting the ring structure may be substituted with a substituent. Examples of the substituent include an alkyl group, an alkoxy group, a halogen atom, a halogenated alkyl group, a hydroxyl group and an oxygen atom (═O).

As the alkyl group, an alkyl group of 1 to 5 carbon atoms is preferable, and a methyl group, an ethyl group, a propyl group, an n-butyl group or a tert-butyl group is particularly desirable.

As the alkoxy group and the halogen atom, the same groups as the substituent groups for substituting part or all of the hydrogen atoms can be used.

Among the examples described above, as X, a cyclic group which may have a substituent is preferable. The cyclic group may be either an aromatic hydrocarbon group which may have a substituent, or an aliphatic cyclic group which may have a substituent, although an aliphatic cyclic group which may have a substituent is preferable.

As the aromatic hydrocarbon group, a naphthyl group which may have a substituent, or a phenyl group which may have a substituent is preferable.

As the aliphatic cyclic group which may have a substituent, an aliphatic polycyclic group which may have a substituent is preferable. As the polycyclic aliphatic group, groups in which one or more hydrogen atoms have been removed from the aforementioned polycycloalkane, and groups represented by formulas (L2) to (L5), and (S3) and (S4) above are preferable.

Further, it is particularly desirable that X have a polar moiety, because it results in improved lithographic properties and resist pattern shape.

Specific examples of X having a polar moiety include those in which a part of the carbon atoms constituting the aliphatic hydrocarbon group for X is substituted with a substituent group containing a hetero atom such as —O—, —C(═O)—O—, —C(═O)—, —O—C(═O)—O—, —C(═O)—NH—, —NH— (wherein H may be substituted with a substituent such as an alkyl group of 1 to 5 carbon atoms or an acyl group), —S—, —S(═O)₂— and —S(═O)₂—O—.

Among the various possibilities described above, R^{4″} preferably has X-Q¹- as a substituent. In such a case, R^{4″} is preferably a group represented by the formula X-Q¹-Y¹- [in the formula, Q¹ and X are the same as defined above; and Y¹ represents an alkylene group of 1 to 4 carbon atoms which may have a substituent, or a fluorinated alkylene group of 1 to 4 carbon atoms which may have a substituent].

In the group represented by the formula X-Q¹-Y¹-, as the alkylene group for Y¹, the same alkylene group as those described above for Q¹ in which the number of carbon atoms is 1 to 4 can be used.

Examples of the fluorinated alkylene group for Y¹ include groups in which some or all of the hydrogen atoms of the aforementioned alkylene group have been substituted with fluorine atoms.

Specific examples of Y¹ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—; —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—; —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)—, and —C(CH₃)(CH₂CH₃)—.

Y¹ is preferably a fluorinated alkylene group, and particularly preferably a fluorinated alkylene group in which the carbon atom bonded to the adjacent sulfur atom is fluorinated. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—; —CH₂CF₂—, —CH₂CH₂CF₂—, —CH₂CF₂CF₂—; —CH₂CH₂CH₂CF₂—, —CH₂CH₂CF₂CF₂—, and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups other than hydrogen atoms and fluorine atoms.

Examples of substituents which the alkylene group or fluorinated alkylene group may have include an alkyl group of 1 to 4 carbon atoms, an alkoxy group of 1 to 4 carbon atoms, and a hydroxyl group.

In formula (b-2) above, each of R^{5″} and R^{6″} independently represents an aryl group which may have a substituent, an alkyl group or an alkenyl group.

Further, at least one of R^{5″} and R^{6″} preferably represents an aryl group, and it is particularly desirable that all of R^{5″} and R^{6″} be aryl groups, as such groups yield superior improvements in the lithography properties and resist pattern shape.

As the aryl group for R^{5″} and R^{6″}, the same as the aryl groups for R^{1″} to R^{3″} can be used.

As the alkyl group for R^{5″} and R^{6″}, the same as the alkyl groups for R^{1″} to R^{3″} can be used.

As the alkenyl group for R^{5″} and R^{6″}, the same as the alkenyl groups for R″ to R^{3″} can be used.

It is particularly desirable that both of R^{5″} and R^{6″} represents a phenyl group.

Specific examples of the cation moiety of the compound represented by general formula (b-2) above include diphenyliodonium and bis(4-tert-butylphenyl)iodonium.

As R^{4″} in formula (b-2) above, the same groups as those mentioned above for R^{4″} in formula (b-1) can be used.

Specific examples of suitable onium salt-based acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate.

It is also possible to use onium salts in which the anion moiety of these onium salts is replaced by an alkyl sulfonate such as methanesulfonate, n-propanesulfonate, n-butanesulfonate, n-octanesulfonate, 1-adamantanesulfonate, or 2-norbornanesulfonate; or a sulfonate such as d-camphor-10-sulfonate, benzenesulfonate, perfluorobenzenesulfonate, or p-toluenesulfonate.

Further, onium salts in which the anion moiety of these onium salts has been replaced by an anion moiety represented by any one of chemical formulas (b1) to (b8) shown below can also be used.

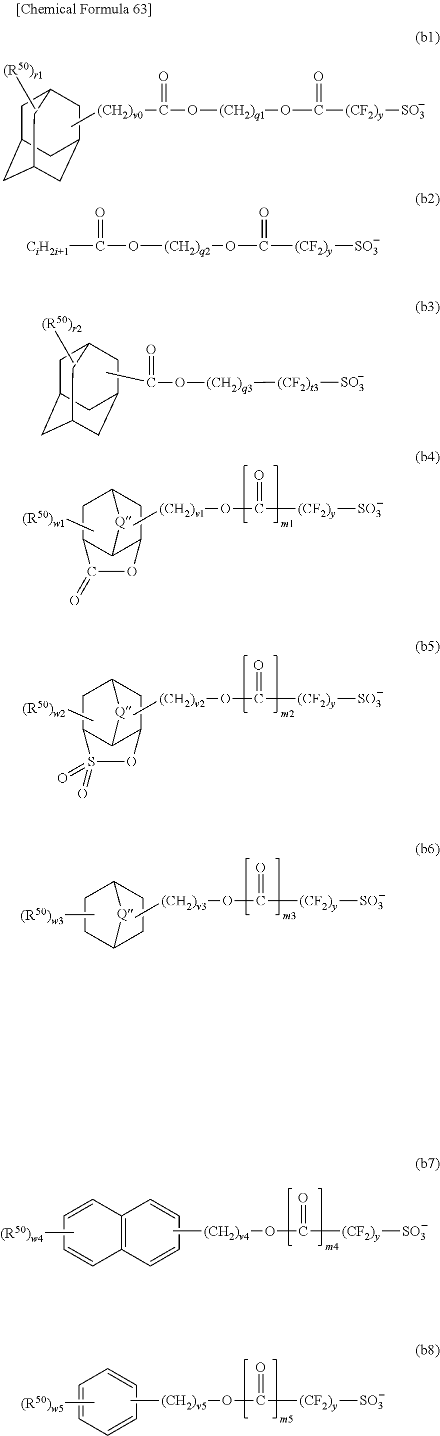

In the formulas, y represents an integer of 1 to 3; each of q1 and q2 independently represents an integer of 1 to 5; q3 represents an integer of 1 to 12; t3 represents an integer of 1 to 3; each of r1 and r2 independently represents an integer of 0 to 3; i represents an integer of 1 to 20; R⁵⁰ represents a substituent; each of m1 to m5 independently represents 0 or 1; each of v0 to v5 independently represents an integer of 0 to 3; each of w1 to w5 independently represents an integer of 0 to 3; and Q″ is the same as defined above.

As the substituent for R⁵⁰, the same groups as those which the aforementioned aliphatic hydrocarbon group or aromatic hydrocarbon group for X may have as a substituent can be used.

If there are two or more R⁵⁰ groups, as indicated by the values r1 and r2, and w1 to w5, then the plurality of R⁵⁰ groups within the compound may be the same or different from each other.

Further, onium salt-based acid generators in which the anion moiety (R^{4″}SO₃⁻) in general formula (b-1) or (b-2) is replaced by an anion moiety represented by general formula (b-3) or (b-4) shown below (and the cation moiety is the same as cation moiety within formula (b-1) or (b-2)) may also be used as the onium salt-based acid generator.

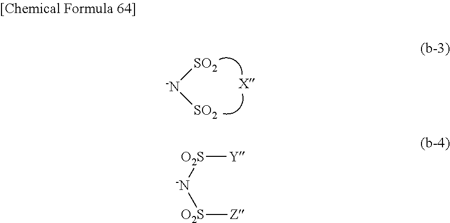

In the formulas, X″ represents an alkylene group of 2 to 6 carbon atoms in which at least one hydrogen atom has been substituted with a fluorine atom; and each of Y″ and Z″ independently represents an alkyl group of 1 to 10 carbon atoms in which at least one hydrogen atom has been substituted with a fluorine atom.

X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

Each of Y″ and Z″ independently represents a linear or branched alkyl group in which at least one hydrogen atom has been substituted with a fluorine atom, and the alkyl group has 1 to 10 carbon atoms, preferably 1 to 7 carbon atoms, and more preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and Z″, it is preferable that the number of hydrogen atoms substituted with fluorine atoms is as large as possible because the acid strength increases and the transparency to high energy radiation of 200 nm or less or electron beam is improved.

The amount of fluorine atoms within the alkylene group or alkyl group, i.e., fluorination ratio, is preferably from 70 to 100%, more preferably from 90 to 100%, and it is particularly desirable that the alkylene group or alkyl group be a perfluoroalkylene or perfluoroalkyl group in which all hydrogen atoms are substituted with fluorine atoms.

Further, an onium salt-based acid generator in which the anion moiety (R^{4″}SO3⁻) in general formula (b-1) or (b-2) has been replaced with R^{a}—COO⁻ [in the formula, R^{a} represents an alkyl group or a fluorinated alkyl group] (and the cation moiety is the same as cation moiety within formula (b-1) or (b-2)) may also be used as the onium salt-based acid generator.

In the formula above, as R^{a}, the same groups as those described above for R^{4″} can be used.

Specific examples of the group represented by the formula “R^{a}—COO⁻” include a trifluoroacetic acid ion, an acetic acid ion, and a 1-adamantanecarboxylic acid ion.

Furthermore, as an onium salt-based acid generator, a sulfonium salt having a cation represented by general formula (b-5) or (b-6) shown below as the cation moiety may also be used.

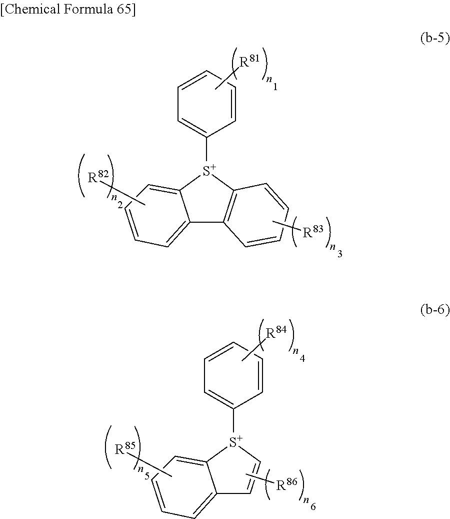

In formulas (b-5) and (b-6) above, each of R⁸¹ to R⁸⁶ independently represents an alkyl group, an acetyl group, an alkoxy group, a carboxyl group, a hydroxyl group or a hydroxyalkyl group; each of n₁ to n₅ independently represents an integer of 0 to 3; and n₆ represents an integer of 0 to 2.

With respect to R⁸¹ to R⁸⁶, the alkyl group is preferably an alkyl group of 1 to 5 carbon atoms, more preferably a linear or branched alkyl group, and most preferably a methyl group, ethyl group, propyl group, isopropyl group, n-butyl group or tert butyl group.

The alkoxy group is preferably an alkoxy group of 1 to 5 carbon atoms, more preferably a linear or branched alkoxy group, and most preferably a methoxy group or ethoxy group.

The hydroxyalkyl group is preferably the aforementioned alkyl group in which one or more hydrogen atoms have been substituted with hydroxy groups, and examples thereof include a hydroxymethyl group, a hydroxyethyl group and a hydroxypropyl group.

If there are two or more of an individual R⁸¹ to R⁸⁶ group, as indicated by the corresponding value of n₁ to n₆, then the two or more of the individual R⁸¹ to R⁸⁶ group may be the same or different from each other.

n₁ is preferably 0 to 2, more preferably 0 or 1, and still more preferably 0.

It is preferable that n₂ and n₃ each independently represent 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

Preferable examples of the cation represented by the above formula (b-5) or (b-6) are shown below.

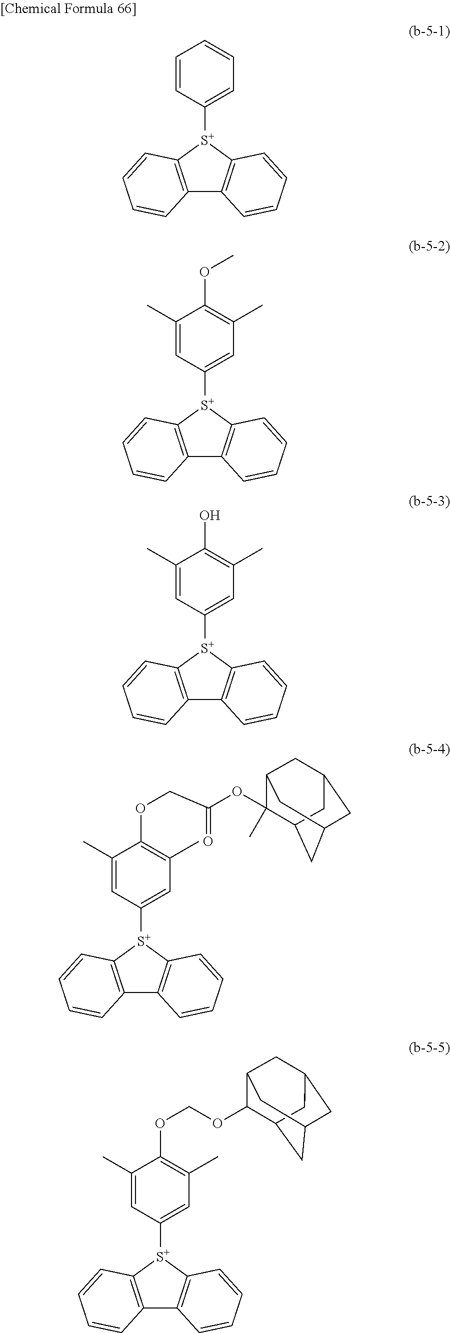

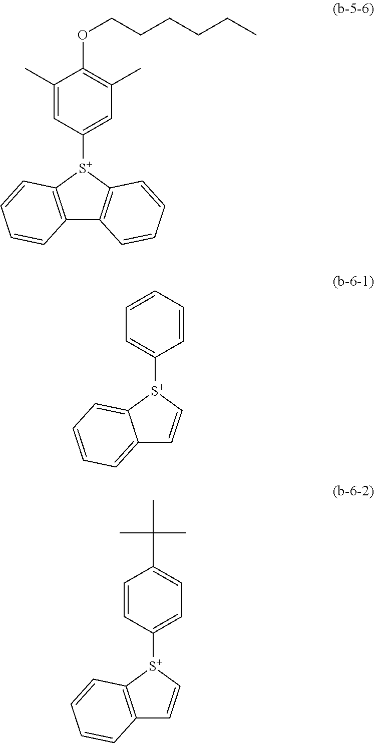

Furthermore, a sulfonium salt having a cation represented by general formula (b-7) or (b-8) shown below as the cation moiety may also be used.

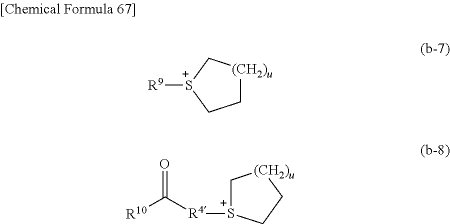

In formulas (b-7) and (b-8), each of R⁹ and R¹⁰ independently represents a phenyl group or naphthyl group which may have a substituent, an alkyl group of 1 to 5 carbon atoms, an alkoxy group or a hydroxyl group. Examples of the substituent are the same as the substituents described above in relation to the substituted aryl group for R^{1″} to R^{3″} (i.e., an alkyl group, an alkoxy group, an alkoxyalkyloxy group, an alkoxycarbonylalkyloxy group, a halogen atom, a hydroxyl group, an oxo group (═O), an aryl group, —C(═O)—O—R^{6′}, —O—C(═O)—R^{7′}, —O—R^{8′}, and a group in which R⁵⁶ in the aforementioned general formula —O—R⁵⁰—C(═O)—O—R⁵⁶ has been substituted with R^{56′}).

R^{4′} represents an alkylene group of 1 to 5 carbon atoms.

u is an integer of 1 to 3, and most preferably 1 or 2.

Preferable examples of the cation represented by the above formula (b-7) or (b-8) are shown below. In the formulas, R^{c} is the same as the substituents described above in relation to the substituted aryl group (i.e., an alkyl group, an alkoxy group, an alkoxyalkyloxy group, an alkoxycarbonylalkyloxy group, a halogen atom, a hydroxyl group, an oxo group (═O), an aryl group, —C(═O)—O—R^{6′}, —O—C(═O)—R^{7′} and —O—R^{8′}).

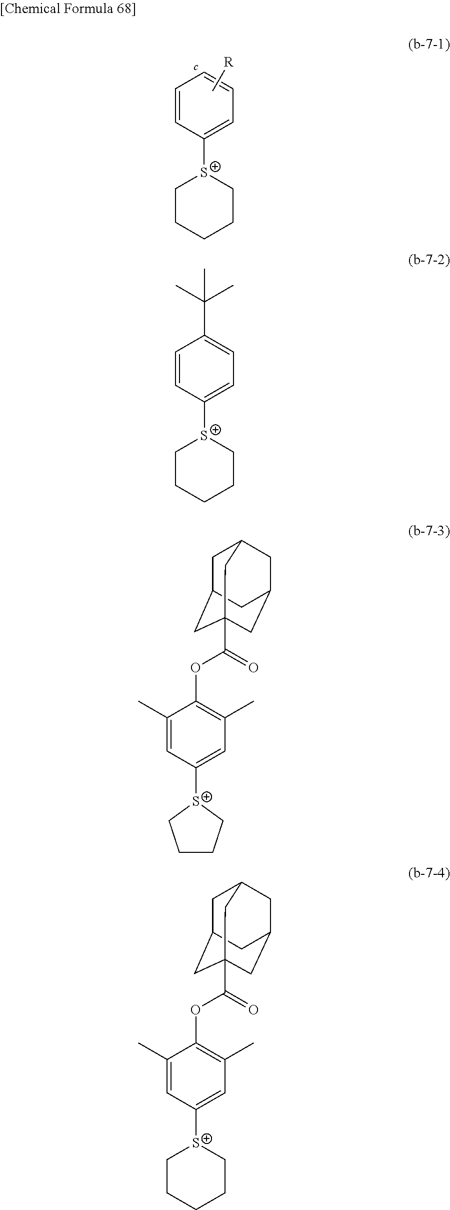

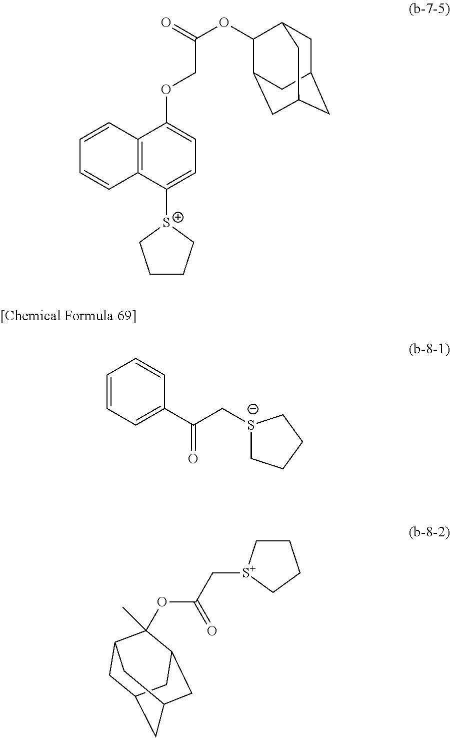

The anion moiety of the sulfonium salt having a cation represented by general formulas (b-5) to (b-8) for the cation moiety is not particularly limited, and the same anion moieties for onium salt-based acid generators which have been proposed may be used. Examples of such anion moieties include fluorinated alkylsulfonic acid ions such as anion moieties (R^{4″}SO₃⁻) for onium salt-based acid generators represented by general formula (b-1) or (b-2) shown above; anion moieties represented by general formula (b-3) or (b-4) shown above; and anion moieties represented by any one of formulas (b1) to (b8) shown above.

In the present description, an oxime sulfonate-based acid generator is a compound having at least one group represented by general formula (B-1) shown below, and has a feature of generating acid upon irradiation (exposure). Such oxime sulfonate-based acid generators are widely used for a chemically amplified resist composition, and can be appropriately selected.

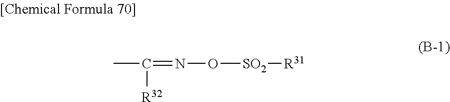

In formula (B-1), each of R³¹ and R³² independently represents an organic group.

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The alkyl group or the aryl group “has a substituent” means that part or all of the hydrogen atoms of the alkyl group or the aryl group is substituted with a substituent.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which part of the hydrogen atoms are substituted with halogen atoms and the “completely halogenated alkyl group” refers to an alkyl group in which all of the hydrogen atoms are substituted with halogen atoms. Examples of the halogen atom include a fluorine atom, a chlorine atom, a bromine atom and an iodine atom, and a fluorine atom is particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, a partially or completely halogenated aryl group is particularly desirable. The “partially halogenated aryl group” refers to an aryl group in which some of the hydrogen atoms are substituted with halogen atoms and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. Examples of the alkyl group and the aryl group for R³² include the same alkyl groups and aryl groups as those described above for R³¹.

As R³², a cyano group, an alkyl group of 1 to 8 carbon atoms having no substituent or a fluorinated alkyl group of 1 to 8 carbon atoms is particularly desirable.

Preferred examples of the oxime sulfonate-based acid generator include compounds represented by general formula (B-2) or (B-3) shown below.

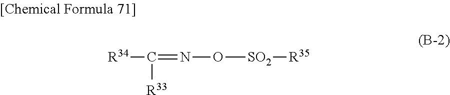

In formula (B-2), R³³ represents a cyano group, an alkyl group having no substituent or a halogenated alkyl group; R³⁴ represents an aryl group; and R³⁵ represents an alkyl group having no substituent or a halogenated alkyl group.

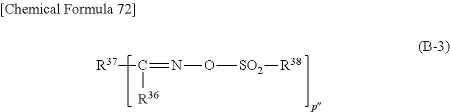

In formula (B-3), R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenanthryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. Further, the halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same one as the alkyl group having no substituent or the halogenated alkyl group for R³⁵ can be used.

p″ is preferably 2.

Specific examples of suitable oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 85) may be preferably used.

Furthermore, as preferable examples, the following can be used.

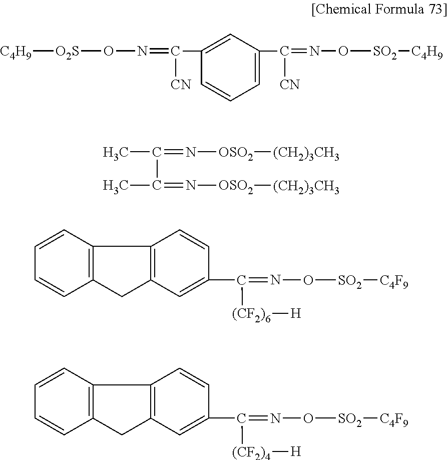

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may also be used favorably.

Furthermore, as examples of poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be given.

As the component (B), one type of these acid generators may be used alone, or two or more types may be used in combination.

The amount of the component (B) within the resist composition of the present invention is preferably within a range from 0 to 40 parts by weight, more preferably from 0 to 30 parts by weight, and still more preferably from 0 to 20 parts by weight, relative to 100 parts by weight of the combined total of the component (A) and the component (C) described later. If the amount of the component (B) is not more than 40 parts by weight, when each component of the resist composition is dissolved in an organic solvent, a uniform solution can be obtained and the storage stability tends to improve, which is desirable.

### <Other Optional Components>

The resist composition of the present invention may include a base component (hereafter, referred to as “component (C)”) that exhibits increased polarity by the action of acid, other than the aforementioned component (A), as long as the effects of the present invention are not impaired.

As described above, the term “base component” refers to an organic compound capable of forming a film.

There are no particular limitations on the component (C), which may be selected appropriately from those used as a base component within conventional chemically amplified resist compositions. The component (C) may be a resin, a low molecular weight compound, or a combination of these materials. As the component (C), one type of material may be used alone, or two or more types may be used in combination.

Resins used as the component (C) may be selected arbitrarily from the multitude of conventional base components (e.g., base resins used within chemically amplified resist compositions for ArF excimer lasers or KrF excimer lasers (and preferably for ArF excimer lasers)) for chemically amplified resist compositions used in the formation of positive resist patterns in the alkali developing process or chemically amplified resist compositions used in the formation of negative resist patterns in the solvent developing process. Examples of resins used as a base component for ArF excimer laser include a resin having the aforementioned structural unit (a1) as an essential structural unit and also having the aforementioned structural units (a2), (a3′), (a4) or the like as an optional component.

The resist composition of the present invention may also include an nitrogen-containing organic compound component (D) (hereafter referred to as the component (D)), other than the components (A) to (C).

As the component (D), there is no particular limitation as long as it functions as an acid diffusion control agent, i.e., a quencher which traps the acid generated from the component (A) and the component (B) upon exposure. A multitude of these components (D) have already been proposed, and any of these known compounds may be used. Examples thereof include amines such as aliphatic amines and aromatic amines. Among these, an aliphatic amine is preferable, and a secondary aliphatic amine or tertiary aliphatic amine is particularly desirable.

An aliphatic amine is an amine having one or more aliphatic groups, and the aliphatic groups preferably have 1 to 20 carbon atoms.

Examples of these aliphatic amines include amines in which at least one hydrogen atom of ammonia (NH₃) has been substituted with an alkyl group or hydroxyalkyl group of no more than 20 carbon atoms (i.e., alkylamines or alkyl alcohol amines), and cyclic amines.

The alkyl group for the above alkyl groups and hydroxyalkyl groups may be any of linear, branched or cyclic.

When the alkyl group is linear or branched, the number of carbon atoms thereof is preferably 2 to 20, and more preferably 2 to 8.

When the alkyl group is cyclic (i.e., a cycloalkyl group), the number of carbon atoms is preferably 3 to 30, more preferably 3 to 20, still more preferably 3 to 15, still more preferably 4 to 12, and most preferably 5 to 10. The alkyl group may be either a monocyclic group or a polycyclic group. Examples thereof include groups in which one or more of the hydrogen atoms have been removed from a monocycloalkane; and groups in which one or more of the hydrogen atoms have been removed from a polycycloalkane such as a bicycloalkane, a tricycloalkane, or a tetracycloalkane. Specific examples of the monocycloalkane include cyclopentane and cyclohexane. Specific examples of the polycycloalkane include adamantane, norbornane, isobornane, tricyclodecane and tetracyclododecane.

Specific examples of the alkylamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine, and tri-n-dodecylamine.

Specific examples of the alkyl alcohol amines include diethanolamine, triethanolamine, diisopropanolamine, triisopropanolamine, di-n-octanolamine, tri-n-octanolamine, stearyldiethanolamine and lauryldiethanolamine.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine and tris[2-{2-(2-hydroxyethoxy)ethoxy}ethyl]amine.

Examples of aromatic amines include aniline, pyridine, 4-dimethylaminopyridine, pyrrole, indole, pyrazole, imidazole and derivatives thereof, as well as diphenylamine, triphenylamine and tribenzylamine.

These compounds can be used either alone, or in combinations of two or more different compounds.

The component (D) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

Furthermore, in the resist composition of the present invention, in order to prevent any deterioration in sensitivity, and improve the resist pattern shape and the post exposure stability of the latent image formed by the pattern-wise exposure of the resist layer, at least one compound (E) (hereafter referred to as “component (E)”) selected from the group consisting of organic carboxylic acids and phosphorus oxo acids and derivatives thereof may also be added as an optional component.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid, and among these, phosphonic acid is particularly desirable.

Examples of phosphorus oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid.

As the component (E), one type may be used alone, or two or more types may be used in combination.

The component (E) is typically used in an amount within a range from 0.01 to 5.0 parts by weight, relative to 100 parts by weight of the component (A).

If desired, other miscible additives can also be added to the resist composition of the present invention. Examples of such miscible additives include additive resins for improving the performance of the resist film, surfactants for improving the applicability, dissolution inhibitors, plasticizers, stabilizers, colorants, halation prevention agents, and dyes.

The resist composition of the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone, cyclohexanone, methyl-n-pentyl ketone, methyl isopentyl ketone, and 2-heptanone;

polyhydric alcohols such as ethylene glycol, diethylene glycol, propylene glycol and dipropylene glycol;

compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable);

cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and

aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents may be used individually, or as a mixed solvent containing two or more different solvents.

Among these, propylene glycol monomethyl ether acetate (PGMEA), propylene glycol monomethyl ether (PGME) and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2. For example, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3. Alternatively, when PGME and cyclohexanone are mixed as the polar solvents, the PGMEA:(PGME+cyclohexanone) weight ratio is preferably from 1:9 to 9:1, more preferably from 2:8 to 8:2, and still more preferably 3:7 to 7:3.

Further, as the component (S), a mixed solvent of γ-butyrolactone is also preferable, which is obtained by mixing with PGMEA, EL or the aforementioned mixed solvent of PGMEA and a polar solvent. The mixing ratio (former:latter) of such a mixed solvent is preferably from 70:30 to 95:5.

The amount of the component (S) used is not particularly limited, and is appropriately adjusted to a concentration which enables coating of a coating solution to a substrate, depending on the thickness of the coating film. In general, the component (S) is used in an amount such that the solid content of the resist composition becomes within the range from 1 to 20% by weight, and preferably from 2 to 15% by weight.

The resist composition and the component (A1) included in this resist composition according to the present invention are novel which have been unknown until now.

Acid is generated from the structural unit (a0) when the component (A1) is subjected to exposure. For this reason, the component (A1) can be used as an acid generator in chemically amplified resist compositions. Further, the component (A1) also functions as a base component for the resist composition, because it is a resin, and may even form a film (resist film) on its own.

Furthermore, by including the structural unit (a1) as well as the structural unit (a0), the component (A1) may constitute a chemically amplified resist composition on its own. That is, when the component (A1) is subjected to exposure, the acid generated from the structural unit (a0) decomposes an acid decomposable group within the structural unit (a1) in the component (A1). As a result, the polarity of the entire component (A1) increases. Therefore, even with a film constituted solely of the component (A), a resist pattern can be formed by conducting selective exposure and development.

Furthermore, the resist composition of the present invention exhibits superior lithography properties such as sensitivity and resolution, and is capable of forming a resist pattern having a favorable shape with reduced line edge roughness (LER). It is thought that the LER reduction is due to the inclusion of the structural unit (a3) within the component (A1) which increases the softening point of resist films.

Although an improvement in the softening point of resist films involved a reduction in sensitivity in the past, the softening point of resist films can be improved while achieving high sensitivity at the same time in the present invention. It is assumed that in the present invention, inclusion of slufoneamide improves the heat resistance while improving the solubility in a developing solution, thereby increasing the sensitivity.

### <<Method of Forming a Resist Pattern>>

The method of forming a resist pattern according to the present invention includes: forming a resist film on a substrate using a resist composition of the present invention; conducting exposure of the resist film; and developing the resist film to form a resist pattern.

The method for forming a resist pattern according to the present invention can be performed, for example, as follows.

Firstly, a resist composition of the present invention is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Subsequently, the thus formed resist film is exposed using, for example, an exposure apparatus such as an ArF exposure apparatus, an electron beam lithography apparatus or an EUV exposure apparatus through a mask pattern (a mask where a predetermined pattern has been formed), or is selectively exposed by patterning via direct irradiation with an electron beam without using a mask pattern. Then, this resist film is subjected to a post exposure bake (PEB) treatment at a temperature of 80 to 150° C. for 40 to 120 seconds, preferably 60 to 90 seconds.

Subsequently, the resist film is subjected to a developing treatment.

The developing treatment is conducted using an alkali developing solution in the case of alkali-developing process, and a developing solution containing an organic solvent (organic developing solution) in the case of solvent developing process.

After the developing treatment, a rinsing treatment is preferably conducted. With respect to the rinsing treatment, a water rinse using pure water is preferred in the case of alkali-developing process, and a rinsing liquid containing an organic solvent is preferably used in the case of solvent developing process.

In the case of solvent developing process, a treatment to remove the developing solution or rinsing liquid remaining on the pattern using a supercritical fluid may be conducted following the developing treatment or rinsing treatment.

Drying is carried out following the developing treatment or rinsing treatment. If desired, a bake treatment (post bake) may be conducted following the developing treatment. In this manner, a resist pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with at least one type of film selected from the group consisting of inorganic and organic films on the surface thereof may also be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is a method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film is formed (triple-layer resist method).

The wavelength to be used for exposure is not particularly limited and the exposure can be conducted using radiations such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is highly useful for KrF excimer laser, ArF excimer laser, EB and EUV.

The exposure of the resist film can be either a general exposure (dry exposure) conducted in air or an inert gas such as nitrogen, or immersion exposure (immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long as it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environmental issues and versatility.

Examples of the alkali developing solutions to be used in the alkali-developing process include a 0.1 to 10% by weight aqueous solution of tetramethylammonium hydroxide (TMAH).

The organic solvent included in the organic developing solution used for the developing treatment in the solvent developing process may be any organic solvent which can dissolve the component (A) (namely, the component (A) prior to exposure), and can be selected appropriately from amongst the known organic solvents. More specifically, polar solvents such as ketone-based solvents, ester-based solvents, alcohol-based solvents, amide-based solvents or ether-based solvents; and hydrocarbon-based solvents can be used.

If required, known additives can be added to the organic developing solution. Examples of the additives include surfactants. Although there are no particular limitations on the surfactants, for example, at least one type of surfactants selected from the group consisting of ionic or nonionic, fluorine-based solvents and silicon-based surfactants can be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment can be conducted using a known developing method. Examples of these methods include a method in which the substrate is immersed in the developing solution for a certain period of time (dipping method), a method in which the developing solution is accumulated by surface tension to remain still at the surface of the substrate for a certain period of time (puddle method), a method in which the developing solution is sprayed onto the surface of the substrate (spraying method), and a method in which the substrate rotating at a constant speed is scanned with a developing-solution ejecting nozzle at a constant speed while continuously ejecting the developing solution (dynamic dispensing method).

As an organic solvent included in the rinsing liquid which is used for the rinsing treatment following the developing treatment in the solvent developing process, for example, an organic solvent which hardly dissolves the resist pattern can be appropriately selected for use from amongst the organic solvents listed above as the organic solvents included in the organic developing solution. In general, at least one type of solvent selected from amongst hydrocarbon-based solvents, ketone-based solvents, ester-based solvents, alcohol-based solvents, amide-based solvents and ether-based solvents is used. Of these, it is preferable to use at least one type of solvent selected from amongst hydrocarbon-based solvents, ketone-based solvents, ester-based solvents, alcohol-based solvents and amide-based solvents; it is more preferable to use at least one type of solvent selected from amongst alcohol-based solvents and ester-based solvents; and an alcohol solvent is particularly desirable.

The rinsing treatment (washing treatment) using a rinsing liquid can be conducted using a known rinsing method. Examples of these methods include a method in which the rinsing liquid is continuously applied onto the substrate rotating at a constant speed (rotational coating method), a method in which the substrate is immersed in the rinsing liquid for a certain period of time (dipping method), and a method in which the rinsing liquid is sprayed onto the surface of the substrate (spraying method).

### <<Polymeric Compound>>

The polymeric compound of the present invention includes a structural unit (a0) that generates acid upon exposure; a structural unit (a1) derived from an acrylate ester, in which a hydrogen atom bonded to the carbon atom on the α-position may be substituted with a substituent, and also includes an acid decomposable group that exhibits increased polarity by the action of acid; and a structural unit (a3) represented by general formula (a3-0) shown below.

The same explanations as those provided for the component (A1) in the resist composition of the present invention can be applied to the polymeric compound of the present invention.

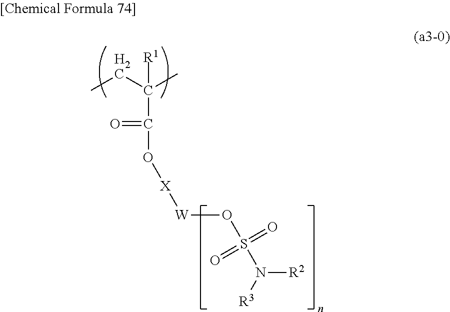

In the formula, R¹ represents a hydrogen atom, an alkyl group of 1 to 5 carbon atoms or a halogenated alkyl group of 1 to 5 carbon atoms; X represents a single bond or a divalent linking group; W represents a cyclic saturated hydrocarbon group that may include an oxygen atom at an arbitrary position; each of R² and R³ independently represents a hydrogen atom or an alkyl group that may include an oxygen atom at an arbitrary position, or R² and R³ may be mutually bonded to form a ring together with the nitrogen atom in the formula; and n represents an integer of 1 to 3.

### EXAMPLES

As follows is a more detailed description of the present invention based on a series of examples, although the scope of the present invention is in no way limited by these examples.

In the following examples, a compound represented by a chemical formula (m1-1) is designated as “compound (m1-1)”, and the same applies for compounds represented by other formulas.

In the NMR analysis, the internal standard for ¹H-NMR and ¹³C-NMR was tetramethylsilane (TMS). The internal standard for ¹⁹F-NMR was hexafluorobenzene (provided that the peak of hexafluorobenzene was regarded as −160 ppm).

The compounds used as the monomers in the following polymer synthesis examples are shown below.

Of these compounds, a compound (m2-1) was synthesized based on the description in WO 2010-001913.

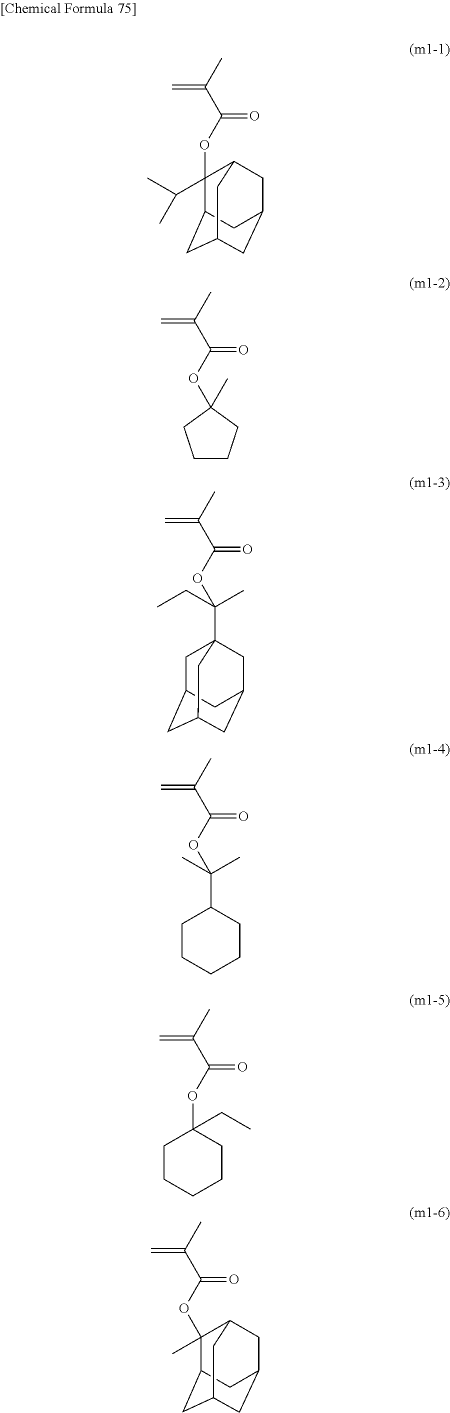

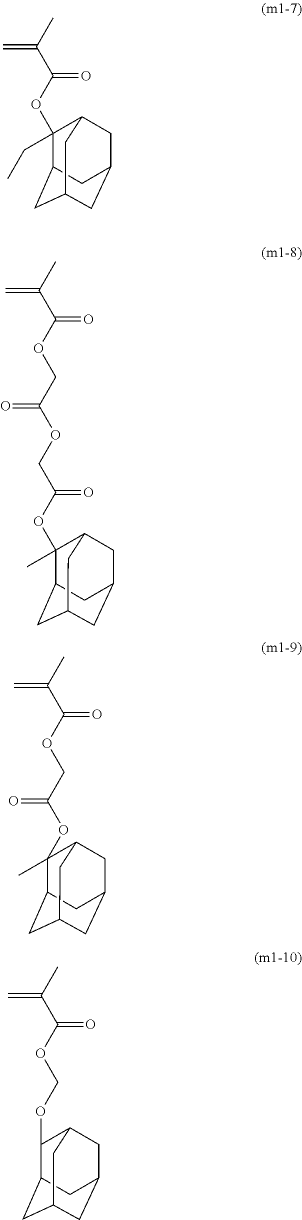

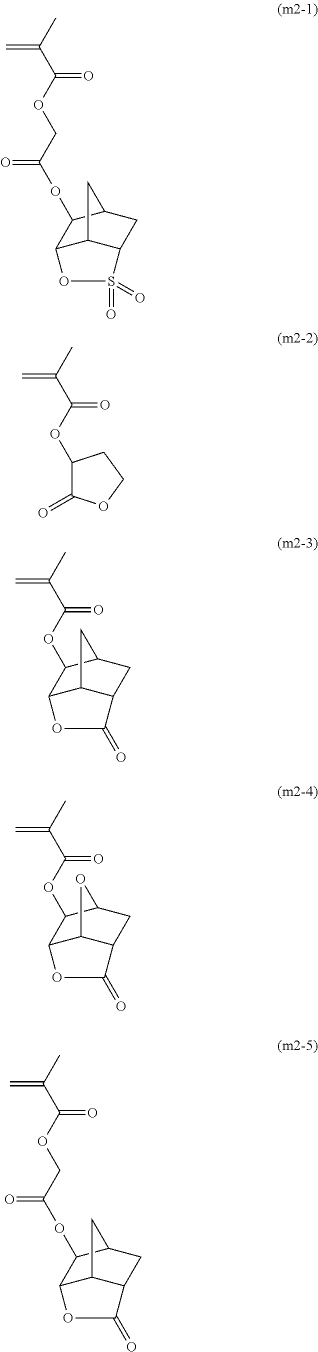

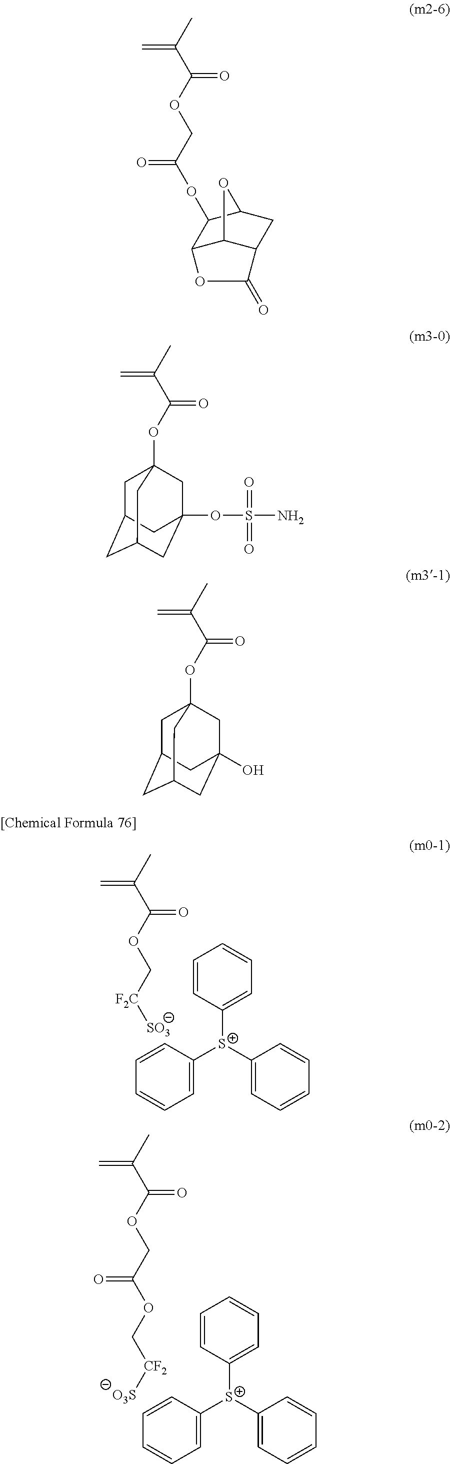

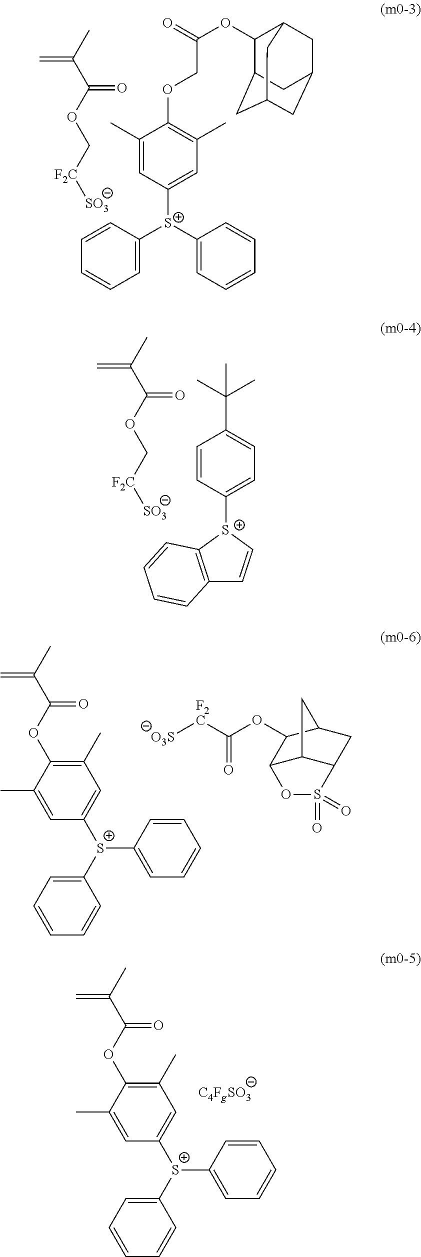

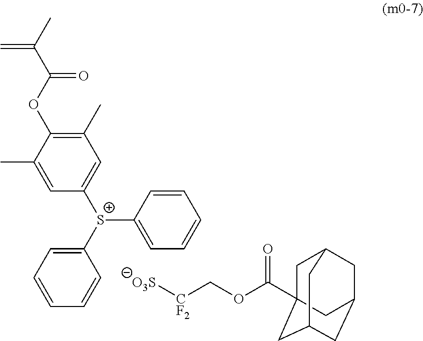

### Polymer Synthesis Example 1

### Synthesis of Polymeric Compound 1

9.50 g (20.55 mmol) of a compound (m2-1), 1.85 g (7.05 mmol) of a compound (m1-1), 3.37 g (10.70 mmol) of a compound (m3-0) and 3.48 g (7.06 mmol) of a compound (m0-1) were charged into a separable flask equipped with a thermometer, a reflux tube and a nitrogen feeding pipe, and were dissolved in 28.53 g of a mixed solvent of methyl ethyl ketone (MEK) and cyclohexanone (CH) (MEK/CH=50/50 in terms of weight ratio). Then, 13.46 mmol of dimethyl 2,2′-azobis(isobutyrate) (product name: V-601) as a polymerization initiator was added and dissolved in the resulting solution. The resultant was dropwise added, in a nitrogen atmosphere over 4 hours, to a solution heated to 80° C. which was prepared by dissolving 7.40 g (28.21 mmol) of a compound (m1-1) in 15.75 g of the MEK/CH mixed solvent (=50/50 in terms of weight ratio). Following dropwise addition, the resulting reaction solution was heated while stirring for 1 hour, and then cooled to room temperature. The obtained reaction solution was dropwise added to an excess amount of an n-heptane/isopropanol mixture (=90/10 in terms of weight ratio) to precipitate a polymer. Thereafter, the precipitated white powder was separated by filtration, followed by washing with methanol and drying, thereby obtaining 10.0 g of a polymeric compound 1 as an objective compound.

With respect to this polymeric compound, the weight average molecular weight (Mw) and the dispersity (Mw/Mn) were determined by the polystyrene equivalent value as measured by gel permeation chromatography (GPC). As a result, it was found that the weight average molecular weight was 5,600, and the dispersity was 1.62.

Further, as a result of an analysis by carbon 13 nuclear magnetic resonance spectroscopy (600 MHz, ¹³C-NMR), it was found that the composition of the copolymer (ratio (molar ratio) of the respective structural units within the structural formula) was 1/m/n/o=37.5/35.7/14.4/12.4.

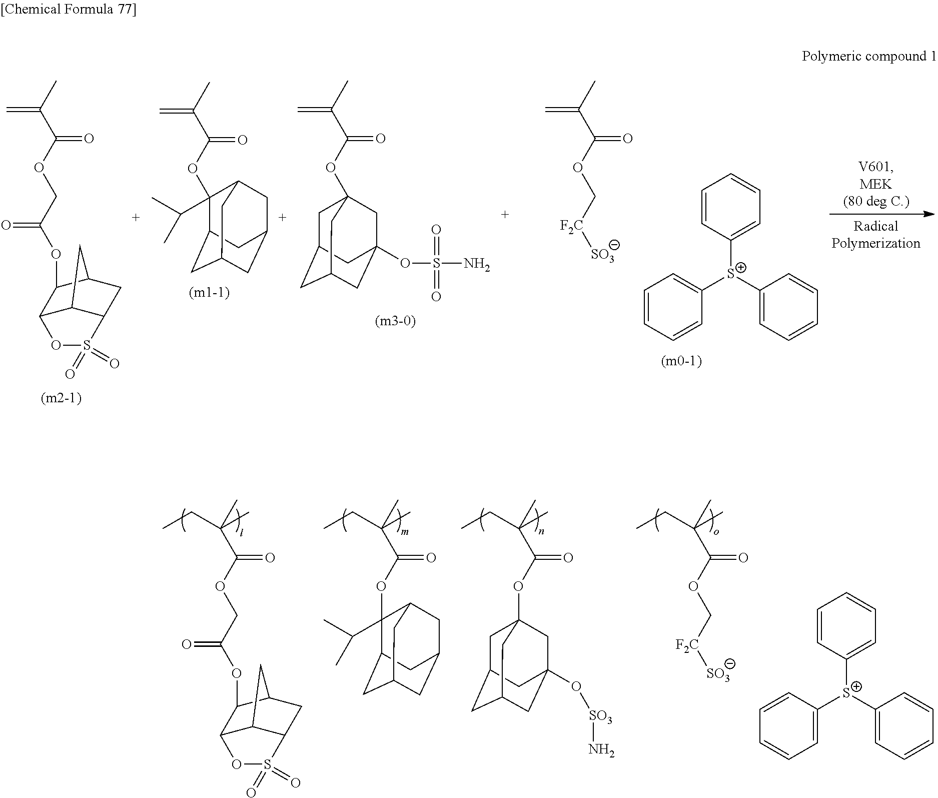

### Polymer Synthesis Examples 2 to 18

### Synthesis of Polymeric Compounds 2 to 18

Polymeric compounds 2 to 18 were obtained by the same procedure as in Polymer Synthesis Example 1 described above with the exception that the type and amount of monomers used were changed.

For each polymeric compound, the composition of the copolymer (ratio (molar ratio) of the respective structural units within the structural formula) determined by carbon 13 nuclear magnetic resonance spectroscopy (600 MHz, ¹³C-NMR), and the weight average molecular weight (Mw) and the dispersity (Mw/Mn) in terms of the polystyrene equivalent value measured by gel permeation chromatography (GPC) were shown in Tables 1 to 6.

TABLE 1

| POLY- | | | COPOLY- | | |
|---|---|---|---|---|---|
| MERIC | | | MER | | |
| COM- | MONOMER | | COMPO- | | Mw/ |
| POUND | COMPOUND | STRUCTURAL FORMULA | SITION | Mw | Mn |
| 2 | m2-2/m2-1/ m1-1/m1-2/ m3-0/m0-1 | 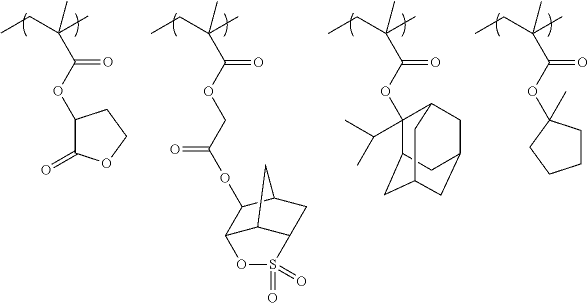 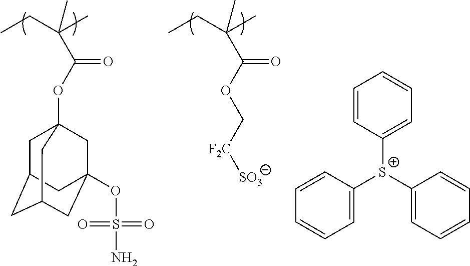 | 30.1/18.9/ 14.3/13.4/ 11.2/12.1 | 6,300 | 1.58 |
| 3 | m2-1/m1-3/ m1-4/m3-0/ m0-1 | 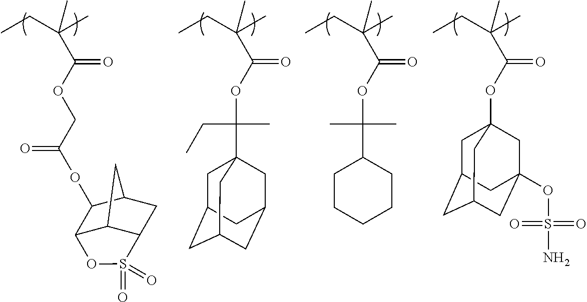 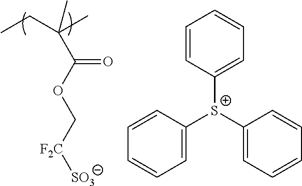 | 33.8/41.5/ 5.2/6.9/ 12.6 | 5,400 | 1.53 |
| 4 | m2-1/m1-1/ m1-5/m3-0/ m0-1 | 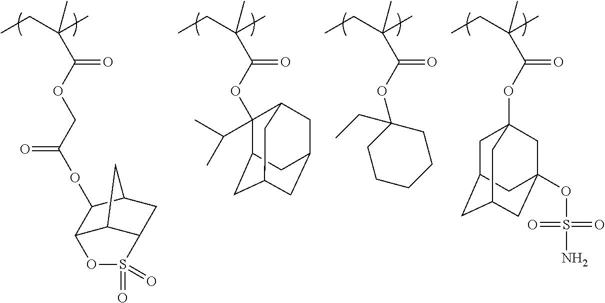 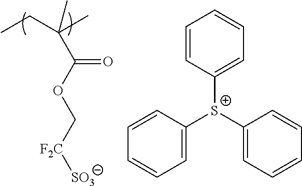 | 37.3/33.3/ 6.0/11.1/ 12.3 | 5,200 | 1.55 |

TABLE 2

| POLY- | | | COPOLY- | | |
|---|---|---|---|---|---|
| MERIC | | | MER | | |
| COM- | MONOMER | | COMPO- | | Mw/ |
| POUND | COMPOUND | STRUCTURAL FORMULA | SITION | Mw | Mn |
| 5 | m2-2/m1-5/ m3-0/m0-1 | 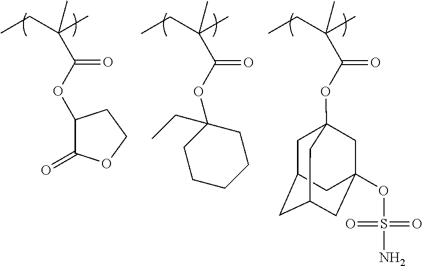 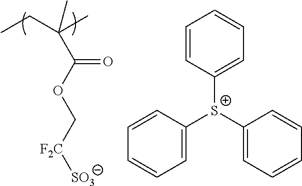 | 34.2/36.2/ 16.9/12.7 | 5,800 | 1.56 |
| 6 | m2-2/m1-5/ m3′-1/m3-0/ m0-1 | 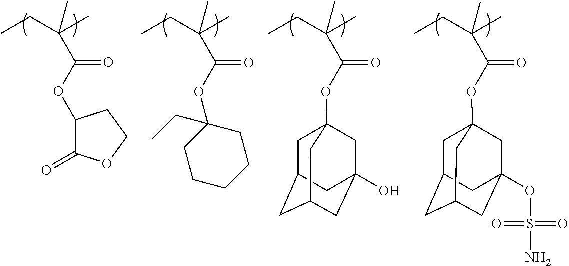 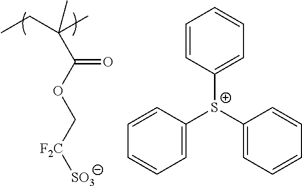 | 34.6/35.7/ 8.6/8.7/ 12.4 | 5,200 | 1.54 |
| 7 | m2-1/m1-1/ m3-0/m0-2 | 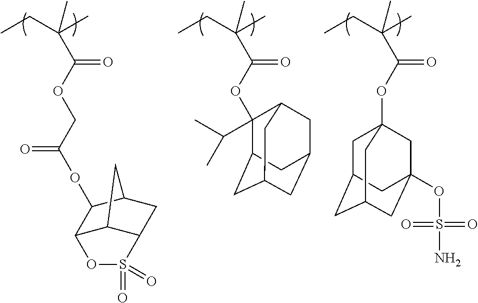 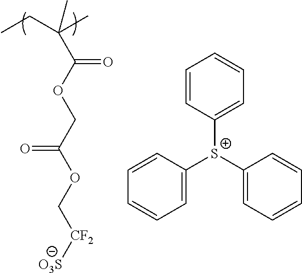 | 36.4/36.1/ 14.8/12.7 | 5,900 | 1.57 |

TABLE 3

| POLY- | | | COPOLY- | | |
|---|---|---|---|---|---|
| MERIC | | | MER | | |
| COM- | MONOMER | | COMPO- | | Mw/ |
| POUND | COMPOUND | STRUCTURAL FORMULA | SITION | Mw | Mn |
| 8 | m2-1/m1-1/ m3-0/m0-3 | 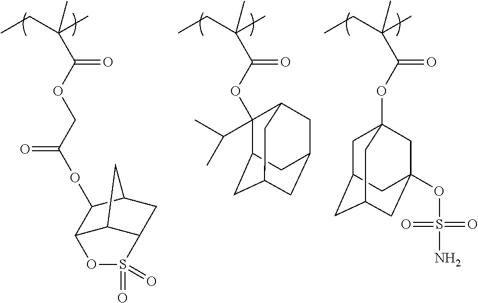 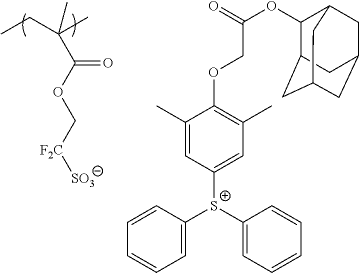 | 34.6/36.1/ 14.8/12.7 | 5,900 | 1.57 |
| 9 | m2-1/m1-1/ m3-0/m0-4 | 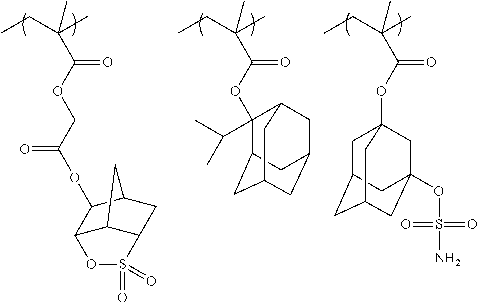 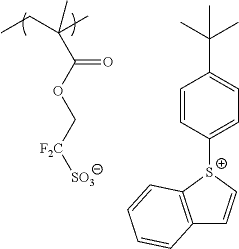 | 37.2/35.6/ 14.6/12.6 | 5,100 | 1.56 |

TABLE 4

| POLYMERIC | MONOMER | | COPOLYMER | | |
|---|---|---|---|---|---|
| COMPOUND | COMPOUND | STRUCTURAL FORMULA | COMPOSITION | Mw | Mw/Mn |
| 10 | m2-1/m1-1/ m3-0/m0-5 | 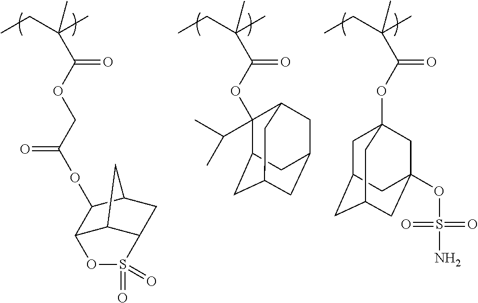 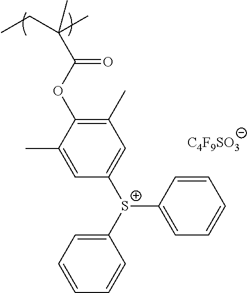 | 36.5/37.2/14.1/12.2 | 5,600 | 1.57 |
| 11 | m2-1/m1-1/ m3-0/m0-6 | 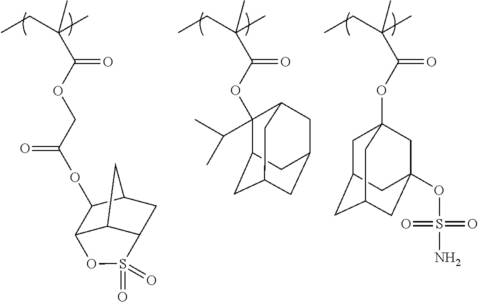 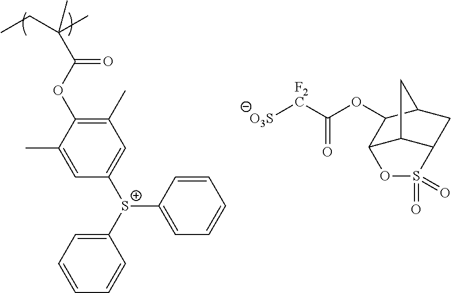 | 37.0/36.3/14.4/12.3 | 5,200 | 1.53 |
| 12 | m2-1/m1-1/ m3-0/m0-7 | 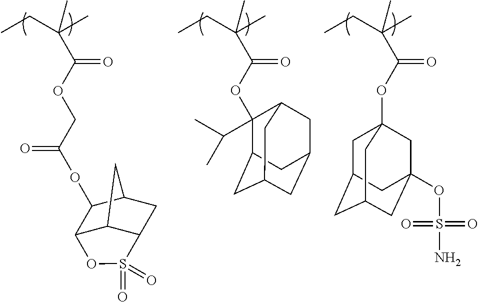 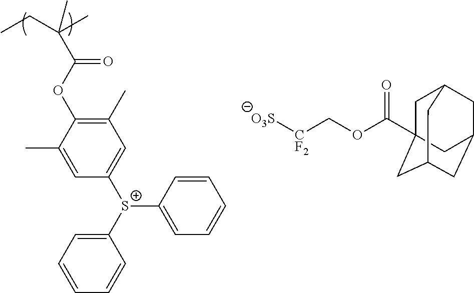 | 6.8/36.4/14.3/12.5 | 5,400 | 1.58 |

TABLE 5

| POLY- | MONO- | | COPOLY- | | |
|---|---|---|---|---|---|
| MERIC | MER | | MER | | |
| COM- | COM- | | COMPO- | | Mw/ |
| POUND | POUND | STRUCTURAL FORMULA | SITION | Mw | Mn |
| 13 (for com- parison) | m2-1/ m1-1/ m3′-1/ m0-1 | 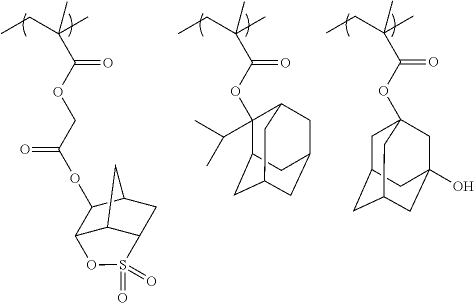 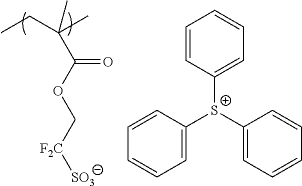 | 36.4/36.1/ 14.8/12.7 | 5,500 | 1.55 |
| 14 (for com- parison) | m2-1/ m1-1/ m0-1 | 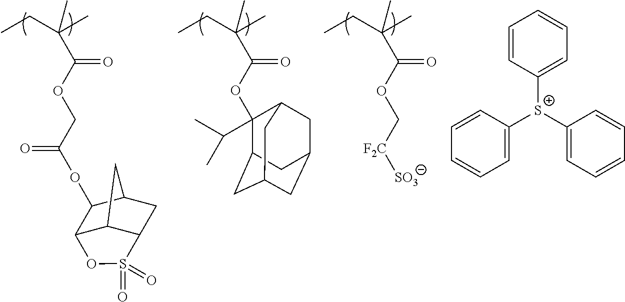 | 43.2/44.1/ 12.7 | 6,200 | 1.61 |
| 15 (for com- parison) | m2-2/ m2-1/ m1-1/ m1-2/ m3′-1/ m0-1 | 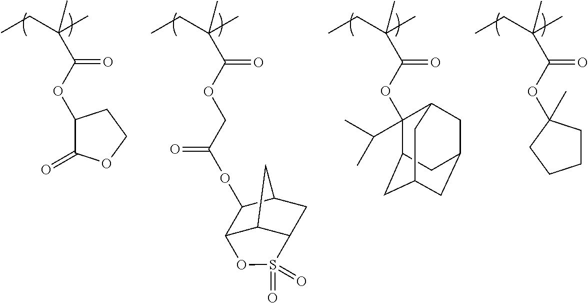 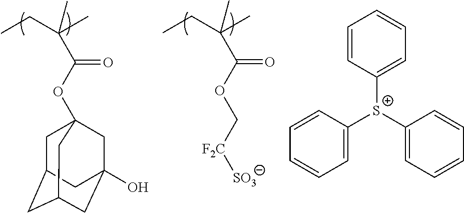 | 30.2/18.4/ 14.6/13.2/ 11.5/12.1 | 5,300 | 1.64 |

TABLE 6

| POLY- | | | COPOLY- | | |
|---|---|---|---|---|---|
| MERIC | | | MER | | |
| COM- | MONOMER | | COMPO- | | Mw/ |
| POUND | COMPOUND | STRUCTURAL FORMULA | SITION | Mw | Mn |
| 16 (for com- parison) | m2-1/m1-3/ m1-4/m3′-1/ m0-1 | 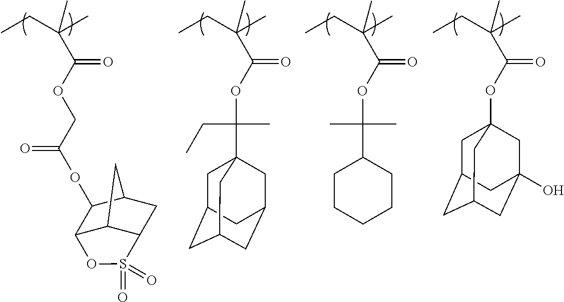 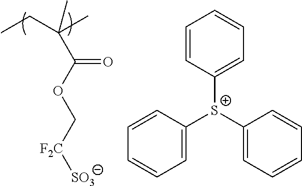 | 34.4/40.9/ 5.3/6.8/12.6 | 6,100 | 1.59 |
| 17 (for com- parison) | m2-1/m1-1/ m1-5/m3′-1/ m0-1 | 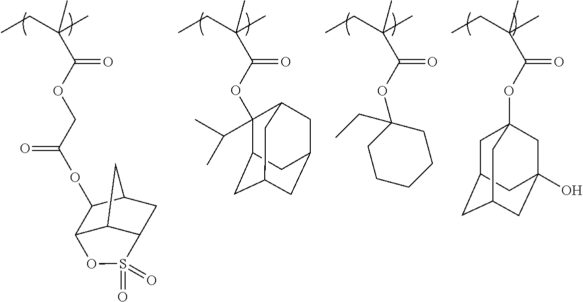 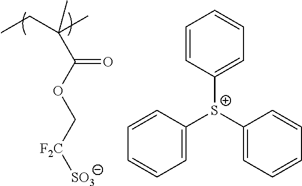 | 37.5/32.8/ 6.1/11.2/ 12.4 | 5,900 | 1.60 |
| 18 (for com- parison) | m2-2/m1-5/ m3′-1/m0-1 | 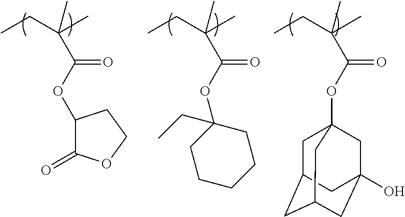 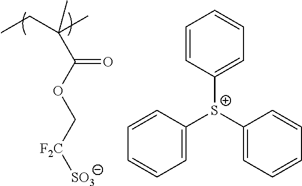 | 34.5/35.8/ 16.8/12.9 | 5,800 | 1.57 |

### Examples 1 to 12, Comparative Examples 1 to 6

100 parts by weight of each polymeric compound shown in Table 7, 1,910 parts by weight of PGMEA, 1,270 parts by weight of PGME and 1,060 parts by weight of cyclohexanone were mixed and dissolved, thereby preparing a resist composition.

Using the obtained resist compositions, the following evaluations were performed. The results are also shown in Table 7.

### [Resist Pattern Formation (1)]

An organic antireflection film composition (product name: DUV-42P, manufactured by Brewer Science Ltd.) was applied onto an 8-inch silicon wafer using a spinner, and the composition was then baked and dried at 180° C. for 60 seconds on a hotplate, thereby forming an organic antireflection film having a film thickness of 65 nm. Then, the prepared resist composition was applied onto the antireflection film using a spinner, and was then prebaked (PAB) and dried on a hotplate at 90° C. for 60 seconds, thereby forming a resist film having a film thickness of 100 nm.

Subsequently, the resist film was selectively irradiated with a KrF excimer laser (248 nm), through a photomask targeting a pattern with a hole diameter of 170 nm and a pitch of 1,200 nm, using a KrF exposure apparatus NSR-S302B (manufactured by Nikon Corporation; NA (numerical aperture)=0.68, σ=0.75). Thereafter, the resist film was subjected to a post exposure bake (PEB) treatment at 90° C. for 60 seconds, followed by development for 60 seconds at 23° C. in a 2.38% by weight aqueous solution of tetramethylammonium hydroxide (TMAH). Then, the resist film was rinsed for 30 seconds with pure water, followed by a bake treatment (post bake) at 100° C. for 60 seconds.

As a result, in each of the examples, a resist pattern in which holes having a hole diameter of 170 nm were arranged with a pitch of 1,200 nm was formed on the resist film.

The optimum exposure dose Eop (mJ/cm²) for formation of the above resist pattern was determined.

### [Measurement of Thermal Flow (TF) Temperature]

The same operation as in [Resist pattern formation (1)] described above was conducted with the exception that no post bake treatment was conducted. As a result, as described above, a resist pattern in which holes having a hole diameter of 170 nm were arranged with a pitch of 1,200 nm was formed.

The formed resist pattern was subjected to a post bake treatment for 60 seconds at respective temperatures of 160° C., 165° C., 170° C., 175° C., 180° C., 185° C., and 190° C. Each hole diameter was measured following the post bake treatment at respective temperatures. From the results obtained by the measurement, a graph was plotted for each resist composition, taking the post bake temperature (° C.) on the horizontal axis and hole diameter following post bake treatment on the vertical axis. From this graph, the TF temperature (° C.) was determined as a temperature when the hole diameter shrank by 10% from the target size (i.e., a temperature when the hole diameter became 153 nm).

### [E₀ Measurement]

Using a spinner, the prepared resist composition was uniformly applied onto an 8-inch silicon substrate that had been treated with hexamethyldisilazane (HMDS) at 90° C. for 36 seconds, followed by a bake treatment (PAB) at 100° C. for 60 seconds, thus forming a resist film with a film thickness of 60 nm.

The thus obtained resist film was then subjected to direct patterning (exposure) with an electron beam lithography apparatus HL-800D (VSB) (manufactured by Hitachi, Ltd.) at an acceleration voltage of 70 keV. Thereafter, the resist film was subjected to a post exposure bake (PEB) treatment at 90° C. for 60 seconds, followed by development for 60 seconds at 23° C. in a 2.38% by weight aqueous TMAH solution. Then, the resist film was rinsed for 30 seconds with pure water, and then spun dry. The exposure dose at which the resist film disappeared was measured as the E₀ sensitivity.

TABLE 7

| | | | | 170 nm Hole Eop | E₀ |
|---|---|---|---|---|---|
| | Component (A) | Monomer composition | TF (° C.) | (mJ/cm²) | (μC/cm²) |
| Ex. 1 | Polymeric compound 1 | m2-1/m1-1/m3-0/m0-1 | 184.7 | 56.6 | 36 |
| Comp. Ex. 1 | Polymeric compound 13 | m2-1/m1-1/m3′-1/m0-1 | 177.1 | 85.0 | 58 |
| Comp. Ex. 2 | Polymeric compound 14 | m2-1/m1-1/m0-1 | 164.8 | 54.1 | 34 |
| Ex. 2 | Polymeric compound 2 | m2-2/m2-1/m1-1/m1-2/m3-0/m0-1 | 182.3 | 62.7 | 40 |
| Comp. Ex. 3 | Polymeric compound 15 | m2-2/m2-1/m1-1/m1-2/m3′-1/m0-1 | 174.5 | 87.3 | 60 |
| Ex. 3 | Polymeric compound 3 | m2-1/m1-3/m1-4/m3-0/m0-1 | 184.7 | 52.6 | 33 |
| Comp. Ex. 4 | Polymeric compound 16 | m2-1/m1-3/m1-4/m3′-1/m0-1 | 176.1 | 75.2 | 51 |
| Ex. 4 | Polymeric compound 4 | m2-1/m1-1/m1-5/m3-0/m0-1 | 183.9 | 54.1 | 34 |
| Comp. Ex. 5 | Polymeric compound 17 | m2-1/m1-1/m1-5/m3′-1/m0-1 | 175.7 | 79.7 | 54 |
| Ex. 5 | Polymeric compound 5 | m2-2/m1-5/m3-0/m0-1 | 181.8 | 59.4 | 38 |
| Ex. 6 | Polymeric compound 6 | m2-2/m1-5/m3′-1/m3-0/m0-1 | 180.2 | 60.4 | 38 |
| Comp. Ex. 6 | Polymeric compound 18 | m2-2/m1-5/m3′-1/m0-1 | 174.4 | 83.9 | 57 |
| Ex. 7 | Polymeric compound 7 | m2-1/m1-1/m3-0/m0-2 | 180.8 | 51.1 | 32 |
| Ex. 8 | Polymeric compound 8 | m2-1/m1-1/m3-0/m0-3 | 187.7 | 58.3 | 37 |
| Ex. 9 | Polymeric compound 9 | m2-1/m1-1/m3-0/m0-4 | 185.2 | 66.5 | 42 |
| Ex. 10 | Polymeric compound 10 | m2-1/m1-1/m3-0/m0-5 | 183.8 | 49.2 | 31 |
| Ex. 11 | Polymeric compound 11 | m2-1/m1-1/m3-0/m0-6 | 184.4 | 52.7 | 34 |
| Ex. 12 | Polymeric compound 12 | m2-1/m1-1/m3-0/m0-7 | 184.8 | 51.8 | 33 |

### Examples 13 to 24, Comparative Examples 7 to 11

100 parts by weight of each polymeric compound shown in Table 8, 0.2 parts by weight of tri-n-octylamine, 0.08 parts by weight of salicylic acid, 2,460 parts by weight of PGMEA, 1,640 parts by weight of PGME and 1,360 parts by weight of cyclohexanone were mixed and dissolved, thereby preparing a resist composition.

Using the obtained resist compositions, the following evaluations were performed. The results are also shown in Table 8.

### [Resist Pattern Formation (2)]

Using a spinner, each of the positive resist compositions was uniformly applied onto a substrate having an organic lower-layer film on a silicon wafer, and prebaked (post applied bake (PAB)) at 110° C. for 90 seconds, thereby forming a resist film having a film thickness of 40 nm.

The thus obtained resist film was then subjected to direct patterning (exposure) with an electron beam lithography apparatus ELS-7500 (manufactured by Elionix Inc.) at an acceleration voltage of 50 keV, targeting a pattern with a space width of 45 nm and a pitch of 100 nm. Thereafter, the resist film was subjected to a post exposure bake (PEB) treatment at 100° C. for 60 seconds, followed by development for 60 seconds at 23° C. in a 2.38% by weight aqueous TMAH solution. Then, the resist film was rinsed for 60 seconds with pure water, and then spun dry.

As a result, in each of the examples, a space and line resist pattern (hereafter, referred to as SL pattern) with a space width of 45 nm and a pitch of 100 nm was formed.

### [Evaluation of Line Edge Roughness (LER)]

With respect to the SL pattern formed in the above section [Resist pattern formation (2)], the value of 3σ was determined as a yardstick of LER. The value of “3σ” indicates the value of 3 times the standard deviation (σ) (i.e., 3 s) (unit: nm) derived from the results which were obtained as follows. The line width at 400 points in the lengthwise direction of the line were measured using a measuring scanning electron microscope (SEM) (product name: S-9220, manufactured by Hitachi, Ltd.; acceleration voltage: 800V). The smaller this 3s value is, the lower the level of roughness of the side walls of a line pattern, indicating that a SL pattern with a uniform width was obtained.

TABLE 8

| | Component (A) | Monomer composition | LER (nm) |
|---|---|---|---|
| Ex. 13 | Polymeric | m2-1/m1-1/m3-0/m0-1 | 4.5 |
| | compound 1 | | |
| Comp. | Polymeric | m2-1/m1-1/m3′-1/m0-1 | 5.2 |
| Ex. 7 | compound 13 | | |
| Ex. 14 | Polymeric | m2-2/m2-1/m1-1/m1-2/m3-0/m0-1 | 4.2 |
| | compound 2 | | |
| Comp. | Polymeric | m2-2/m2-1/m1-1/m1-2/m3′-1/m0-1 | 5.1 |
| Ex. 8 | compound 15 | | |
| Ex. 15 | Polymeric | m2-1/m1-3/m1-4/m3-0/m0-1 | 4.5 |
| | compound 3 | | |
| Comp. | Polymeric | m2-1/m1-3/m1-4/m3′-1/m0-1 | 5.4 |
| Ex. 9 | compound 16 | | |
| Ex. 16 | Polymeric | m2-1/m1-1/m1-5/m3-0/m0-1 | 4.6 |
| | compound 4 | | |
| Comp. | Polymeric | m2-1/m1-1/m1-5/m3′-1/m0-1 | 5.5 |
| Ex. 10 | compound 17 | | |
| Ex. 17 | Polymeric | m2-2/m1-5/m3-0/m0-1 | 4.4 |
| | compound 5 | | |
| Ex. 18 | Polymeric | m2-2/m1-5/m3′-1/m3-0/m0-1 | 4.8 |
| | compound 6 | | |
| Comp. | Polymeric | m2-2/m1-5/m3′-1/m0-1 | 5.2 |
| Ex. 11 | compound 18 | | |
| Ex. 19 | Polymeric | m2-1/m1-1/m3-0/m0-2 | 4.1 |
| | compound 7 | | |
| Ex. 20 | Polymeric | m2-1/m1-1/m3-0/m0-3 | 4.5 |
| | compound 8 | | |
| Ex. 21 | Polymeric | m2-1/m1-1/m3-0/m0-4 | 4.3 |
| | compound 9 | | |
| Ex. 22 | Polymeric | m2-1/m1-1/m3-0/m0-5 | 4.8 |
| | compound 10 | | |
| Ex. 23 | Polymeric | m2-1/m1-1/m3-0/m0-6 | 4.5 |
| | compound 11 | | |
| Ex. 24 | Polymeric | m2-1/m1-1/m3-0/m0-7 | 4.6 |
| | compound 12 | | |

From the results shown in Tables 7 and 8, it was possible to confirm the following.

The polymeric compound 1 used in Example 1 had a monomer composition in which (m3-0) was added to the monomer composition of the polymeric compound 14 used in Comparative Example 2, and the polymeric compound 13 used in Comparative Example 1 had a monomer composition in which (m3′-1) was added to the monomer composition of the polymeric compound 14. When the results from these examples were compared, the 170 nm Hole Eop and E₀ values declined considerably in Comparative Example 1 indicating poor sensitivity, although the TF temperature improved compared to Comparative Example 2. On the other hand, the TF temperature improved in Example 1 compared to Comparative Example 2, while the 170 nm Hole Eop and E₀ values were almost equivalent to those in Comparative Example 2 indicating favorable sensitivity. When comparison was made between the results of Example 2 and Comparative Example 3, Example 3 and Comparative Example 4, Example 4 and Comparative Example 5, and Examples 5 to 6 and Comparative Example 6, the same trend seen between the results of Example 1 and Comparative Example 1 was observed.

Further, when the results using the polymeric compound 1 (Example 13) and the results using the polymeric compound 14 (Comparative Example 7) were compared, it was possible to form a resist pattern with a lower level of LER in Example 13, as compared to Comparative Example 7. When comparison was made between the results of Example 14 and Comparative Example 8, Example 15 and Comparative Example 9, Example 16 and Comparative Example 10, and Examples 17 to 18 and Comparative Example 11, the same trend seen between the results of Example 13 and Comparative Example 7 was observed. Among the above-mentioned Examples 1 to 12 and Comparative Examples 1 to 6, the LER values in each example almost corresponded with the TF temperature in examples where the same polymeric compound was added.

### Polymer Synthesis Examples 19 to 30

### Synthesis of Polymeric Compounds 19 to 30

Polymeric compounds 19 to 30 were obtained by the same procedure as in Polymer Synthesis Example 1 described above with the exception that the type and amount of monomers used were changed.

For each polymeric compound, as in Table 1, the monomer composition, copolymer composition, Mw and Mw/Mn were shown in Table 9. Illustration of structural formula was omitted.

TABLE 9

| | Monomer composition | Composition | Mw | Mw/Mn |
|---|---|---|---|---|
| Polymeric compound 19 | m2-3/m2-1/m1-1/m1-2/m3-0/m0-1 | 30.2/18.8/14.1/13.6/11.1/12.2 | 6,200 | 1.60 |
| Polymeric compound 20 | m2-4/m2-1/m1-1/m1-2/m3-0/m0-1 | 30.5/18.7/14.4/13.2/11.3/11.9 | 5,800 | 1.58 |
| Polymeric compound 21 | m2-2/m2-5/m1-1/m1-2/m3-0/m0-1 | 30.3/19.0/14.2/13.4/11.1/12.0 | 5,900 | 1.61 |
| Polymeric compound 22 | m2-2/m2-6/m1-1/m1-2/m3-0/m0-1 | 30.8/18.6/14.1/13.5/11.0/12.0 | 5,900 | 1.59 |
| Polymeric compound 23 | m2-1/m1-7/m1-5/m3-0/m0-1 | 37.0/32.7/6.3/11.4/12.6 | 6,000 | 1.57 |
| Polymeric compound 24 | m2-1/m1-8/m1-1/m3-0/m0-1 | 26.2/8.7/44.1/8.6/12.4 | 6,400 | 1.55 |
| Polymeric compound 25 | m2-1/m1-9/m1-1/m3-0/m0-1 | 26.7/8.9/43.4/8.9/12.1 | 5,700 | 1.54 |
| Polymeric compound 26 | m2-2/m1-1/m3-0/m0-1 | 34.1/35.9/16.6/13.4 | 5,700 | 1.58 |
| Polymeric compound 27 | m2-2/m1-10/m3-0/m0-1 | 35.0/35.2/17.0/12.8 | 6,000 | 1.60 |
| Polymeric compound 28 | m2-2/m1-6/m3-0/m0-1 | 34.9/35.9/16.6/12.6 | 6,200 | 1.63 |
| Polymeric compound 29 | m1-6/m3-0/m0-1 | 44.3/43.2/12.5 | 5,900 | 1.58 |
| Polymeric compound 30 | m2-2/m1-6/m3′-1/m0-1 | 34.6/35.7/16.3/13.4 | 6,000 | 1.60 |

### Examples 25 to 35, Comparative Example 12

With respect to the above-mentioned polymeric compounds 19 to 30, the following evaluations were performed.

Resist compositions having the same composition as that of Example 1 were prepared, with the exception that the polymeric compound 1 was changed to each polymeric compound shown in Table 9, and the TF, 170 nm Hole Eop and E₀ values were measured in the same manner as in Example 1. Further, with the exception that the polymeric compound 1 was changed to each polymeric compound shown in Table 9, resist compositions having the same composition as that of Example 13 were prepared separately, and the LER values were evaluated in the same manner as in Example 13. However, the PAB treatment was conducted at 120° C. and the PEB treatment was carried out at 110° C. in Examples 28 and 29 and Comparative Example 12. The results are shown in Table 10.

TABLE 10

| | | | TF | 170 nm Hole | E₀ | LER |
|---|---|---|---|---|---|---|
| | Component (A) | Monomer composition | (° C.) | Eop (mJ/cm²) | (μC/cm²) | (nm) |
| Ex. 25 | Polymeric compound 19 | m2-3/m2-1/m1-1/m1-2/m3-0/m0-1 | 185.3 | 64.5 | 42 | 4.3 |
| Ex. 26 | Polymeric compound 20 | m2-4/m2-1/m1-1/m1-2/m3-0/m0-1 | 184.5 | 64.2 | 42 | 4.1 |
| Ex. 27 | Polymeric compound 21 | m2-2/m2-5/m1-1/m1-2/m3-0/m0-1 | 184.9 | 63.3 | 41 | 4.2 |
| Ex. 28 | Polymeric compound 22 | m2-2/m2-6/m1-1/m1-2/m3-0/m0-1 | 183.7 | 63.1 | 41 | 4.3 |
| Ex. 29 | Polymeric compound 23 | m2-1/m1-7/m1-5/m3-0/m0-1 | 184.1 | 58.8 | 38 | 4.5 |
| Ex. 30 | Polymeric compound 24 | m2-1/m1-8/m1-1/m3-0/m0-1 | 181.4 | 56.9 | 37 | 4.6 |
| Ex. 31 | Polymeric compound 25 | m2-1/m1-9/m1-1/m3-0/m0-1 | 180.3 | 55.4 | 36 | 4.4 |
| Ex. 32 | Polymeric compound 26 | m2-2/m1-1/m3-0/m0-1 | 182.4 | 60.2 | 39 | 4.7 |
| Ex. 33 | Polymeric compound 27 | m2-2/m1-10/m3-0/m0-1 | 182.2 | 61 | 40 | 4.7 |
| Ex. 34 | Polymeric compound 28 | m2-2/m1-6/m3-0/m0-1 | 182.9 | 65.8 | 43 | 4.8 |
| Ex. 35 | Polymeric compound 29 | m1-6/m3-0/m0-1 | 184.8 | 64.1 | 42 | 4.9 |
| Comp. Ex. | Polymeric compound 30 | m2-2/m1-6/m3′-1/m0-1 | 178.5 | 76.5 | 50 | 5.3 |
| 12 | | | | | | |

From the results shown in Table 10, it was confirmed, by comparing the results of Examples 34, 35, and those of Comparative Example 12, that both the sensitivity and the LER were superior. Furthermore, it was verified that the sensitivity and the LER in Examples 25 to 33 were also equivalent to or better than those in Examples 34 and 35.

From the results shown above, it was confirmed that a resist pattern with high sensitivity and low LER can be formed using the resist composition of the present invention.

While preferred embodiments of the present invention have been described and illustrated above, it should be understood that these are exemplary of the present invention and are not to be considered as limiting. Additions, omissions, substitutions, and other modifications can be made without departing from the spirit or scope of the present invention. Accordingly, the present invention is not to be considered as being limited by the foregoing description, and is only limited by the scope of the appended claims.

What is claimed is:

1. A resist composition comprising:
a base component (A) that generates acid upon exposure and also exhibits increased polarity by action of acid,
wherein the base component (A) includes a polymeric compound (A1) having a structural unit (a0) that generates acid upon exposure;
a structural unit (a1) derived from an acrylate ester, in which a hydrogen atom bonded to a carbon atom on the α-position may be substituted with a substituent, and also includes an acid decomposable group that exhibits increased polarity by action of acid; and
a structural unit (a3) represented by general formula (a3-0) shown below: 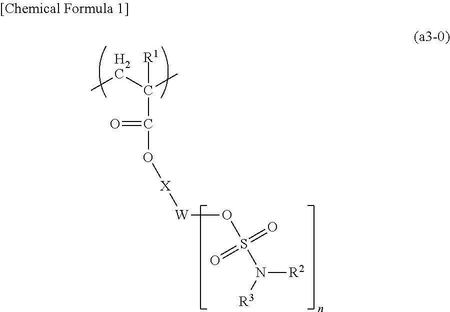
wherein R¹ represents a hydrogen atom, an alkyl group of 1 to 5 carbon atoms or a halogenated alkyl group of 1 to 5 carbon atoms; X represents a single bond or a divalent linking group; W represents a cyclic saturated hydrocarbon group that may include an oxygen atom at an arbitrary position; each of R² and R³ independently represents a hydrogen atom or an alkyl group that may include an oxygen atom at an arbitrary position, or R² and R³ may be mutually bonded to form a ring together with the nitrogen atom in the formula; and n represents an integer of 1 to 3.

2. The resist composition according to claim 1, wherein the structural unit (a0) includes a group represented by general formula (I) or (II) shown below: 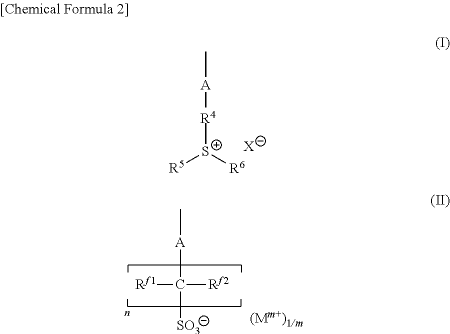
wherein A represents a single bond or a divalent linking group; R⁴ represents an arylene group which may have a substituent; each of R⁵ and R⁶ independently represents an organic group, wherein R⁵ and R⁶ may be mutually bonded to form a ring together with the sulfur atom in the formula; X⁻ represents a counter anion; each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group; n represents an integer of 1 to 8; M^{m+} represents a counter cation; and m represents an integer of 1 to 3.

3. The resist composition according to claim 2, wherein the structural unit (a0) is a structural unit represented by general formula (a0-1) or (a0-2) shown below: 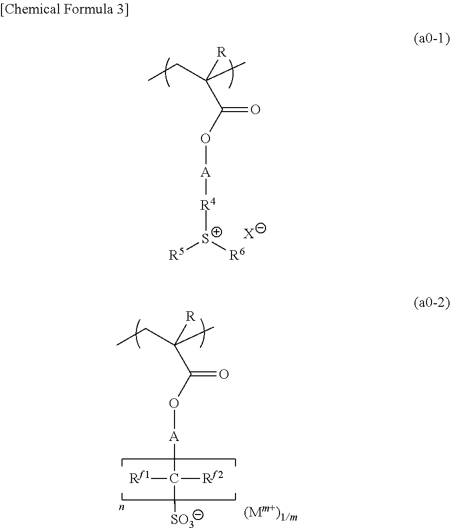
wherein R represents a hydrogen atom, an alkyl group of 1 to 5 carbon atoms or a halogenated alkyl group of 1 to 5 carbon atoms; A represents a single bond or a divalent linking group; R⁴ represents an arylene group which may have a substituent; each of R⁵ and R⁶ independently represents an organic group, wherein R⁵ and R⁶ may be mutually bonded to form a ring with the sulfur atom in the formula; X⁻ represents a counter anion; each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group; n represents an integer of 1 to 8; M^{m+} represents a counter cation; and m represents an integer of 1 to 3.

4. A method of forming a resist pattern, comprising:
applying a resist composition of any one of claims 1 to 3 to a substrate to form a resist film on the substrate;
conducting exposure of the resist film; and
developing the resist film to form a resist pattern.

5. A polymeric compound comprising:
a structural unit (a0) that generates acid upon exposure;
a structural unit (a1) derived from an acrylate ester, in which a hydrogen atom bonded to a carbon atom on the α-position may be substituted with a substituent, and also includes an acid decomposable group that exhibits increased polarity by action of acid; and
a structural unit (a3) represented by general formula (a3-0) shown below: 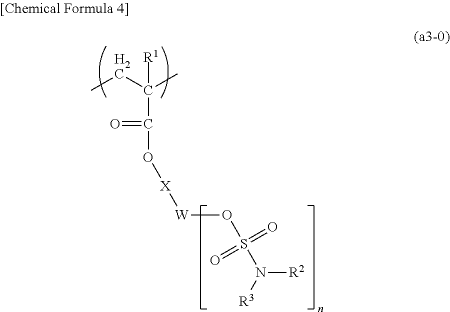
wherein R¹ represents a hydrogen atom, an alkyl group of 1 to 5 carbon atoms or a halogenated alkyl group of 1 to 5 carbon atoms; X represents a single bond or a divalent linking group; W represents a cyclic saturated hydrocarbon group that may include an oxygen atom at an arbitrary position; each of R² and R³ independently represents a hydrogen atom or an alkyl group that may include an oxygen atom at an arbitrary position, or R² and R³ may be mutually bonded to form a ring together with the nitrogen atom in the formula; and n represents an integer of 1 to 3.

6. The polymeric compound according to claim 5, wherein the structural unit (a0) includes a group represented by general formula (I) or (II) shown below: 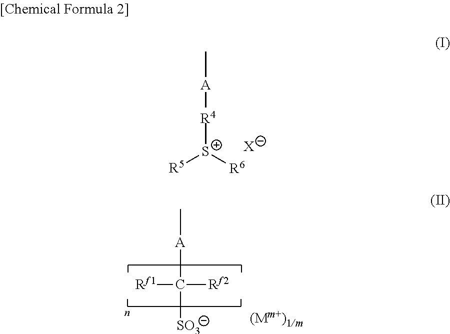
wherein A represents a single bond or a divalent linking group; R⁴ represents an arylene group which may have a substituent; each of R⁵ and R⁶ independently represents an organic group, wherein R⁵ and R⁶ may be mutually bonded to form a ring together with the sulfur atom in the formula; X⁻ represents a counter anion; each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group; n represents an integer of 1 to 8; M^{m+} represents a counter cation; and m represents an integer of 1 to 3.

7. The polymeric compound according to claim 6, wherein the structural unit (a0) is a structural unit represented by general formula (a0-1) or (a0-2) shown below: 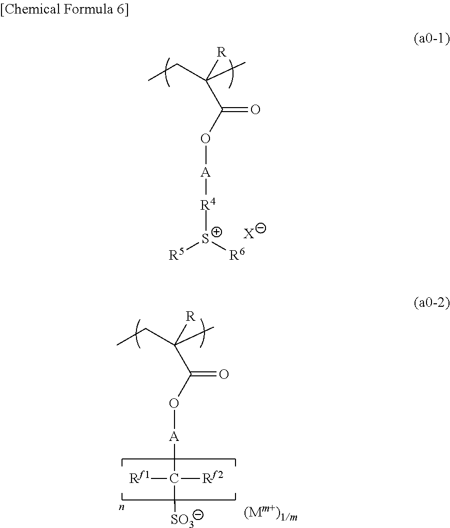
wherein R represents a hydrogen atom, an alkyl group of 1 to 5 carbon atoms or a halogenated alkyl group of 1 to 5 carbon atoms; A represents a single bond or a divalent linking group; R⁴ represents an arylene group which may have a substituent; each of R⁵ and R⁶ independently represents an organic group, wherein R⁵ and R⁶ may be mutually bonded to form a ring with the sulfur atom in the formula; X⁻ represents a counter anion; each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group; n represents an integer of 1 to 8; M^{m+} represents a counter cation; and m represents an integer of 1 to 3.
